(19) United States
(12) Patent Application Publication
(10) Pub. No.: US 2013/0341180 A1
(43) Pub. Date: Dec. 26, 2013

(54) SPUTTERING TARGET AND METHOD FOR USING THE SAME

(71) Applicant: Semiconductor Energy Laboratory Co., Ltd., Atsugi-shi (JP)

(72) Inventor: Shunpei YAMAZAKI, Setagaya (JP)

(21) Appl. No.: 13/917,085

(22) Filed: Jun. 13, 2013

(30) Foreign Application Priority Data
Jun. 22, 2012 (JP) 2012-141451

(51) Int. Cl. C23C 14/34

(52) U.S. Cl. CPC C23C 14/3414
USPC 204/192.1; 204/298.13

(57) ABSTRACT

To form an oxide film with a high degree of crystallinity, which includes a plurality of metal elements. Further, to provide a sputtering target which enables the oxide film to be formed and a method for using the sputtering target. The sputtering target includes a polycrystalline oxide containing a plurality of crystal grains whose average grain size is less than or equal to 3 μm. The plurality of crystal grains each have a cleavage plane. When the sputtering target includes a plurality of crystal grains whose average grain size is less than or equal to 3 μm, by making an ion collide with the sputtering target, a sputtered particle can be separated from the cleavage plane of the crystal grain.

### TECHNICAL FIELD

The present invention relates to a sputtering target, a method for manufacturing the sputtering target, and a method for using the sputtering target. In addition, the present invention relates to an oxide semiconductor film deposited by a sputtering method, using the sputtering target, and a semiconductor device including the oxide semiconductor film.

In this specification, a semiconductor device generally refers to a device which can function by utilizing semiconductor characteristics; an electro-optical device, a semiconductor circuit, and an electronic device are all included in the category of the semiconductor device.

### BACKGROUND ART

A technique by which a transistor is formed using a semiconductor thin film formed over a substrate having an insulating surface has been attracting attention. The transistor is applied to a wide range of electronic devices such as an integrated circuit (IC) or an image display device (display device). A silicon film is widely known as a semiconductor thin film applicable to the transistor. As another material, an oxide semiconductor film has been attracting attention.

For example, a transistor including an amorphous oxide semiconductor film that contains indium (In), gallium (Ga), and zinc (Zn) and has an electron carrier concentration less than 10¹⁸/cm³ is disclosed. As a method for forming the amorphous oxide semiconductor film, a sputtering method is considered the most suitable (see Patent Document 1).

An oxide semiconductor containing a plurality of metal elements has a high controllability of carrier density, but there have been a problem in that the oxide semiconductor film easily becomes amorphous and its physical properties are unstable.

On the other hand, there is a report that a transistor including a crystalline oxide semiconductor film has more excellent electric characteristics and higher reliability than a transistor including an amorphous oxide semiconductor film (see Non-Patent Document 1).

### REFERENCE

### Patent Document

[Patent Document 1] Japanese Published Patent Application No. 2006-165528

### Non-Patent Document

[Non-Patent Document 1] Shunpei Yamazaki, Jun Koyama, Yoshitaka Yamamoto, and Kenji Okamoto, “Research, Development, and Application of Crystalline Oxide Semiconductor”, SID 2012 DIGEST, pp. 183-186

### DISCLOSURE OF INVENTION

An object is to provide a method for forming a thin oxide film which contains a plurality of metal elements and has a high degree of crystallinity.

Another object is to provide a sputtering target which enables the oxide film to be formed.

Another object is to provide a method for using the sputtering target.

Another object is to provide a transistor which includes an oxide film and has stable electric characteristics.

Another object is to provide a highly reliable semiconductor device including the transistor.

One embodiment of the present invention is a sputtering target including a polycrystalline oxide containing a plurality of crystal grains whose average grain size is less than or equal to 3 μm.

Further, the plurality of crystal grains each have a cleavage plane. The cleavage plane indicates a plane where bonding of atoms constituting the crystal grain is weak (i.e., a plane where cleavage occurs or a plane which is easily cleaved).

When an ion collides with the sputtering target including a plurality of crystal grains whose average grain size is less than or equal to 3 μm, a particle that is to be a sputtered particle can be separated from a cleavage plane of the crystal grain.

Note that the grain size of the crystal grain can be measured by electron backscatter diffraction (EBSD). The grain size of the crystal grain described here is calculated from a cross-sectional area, assuming that a cross section of one crystal grain is a perfect circle. The cross section of the crystal grain can be measured from a crystal grain map obtained by EBSD. Specifically, when the cross-sectional area of the crystal grain is denoted by S and the radius of the cross section of the crystal grain is denoted by r, the radius r is calculated from a relation, S=πr² to obtain the grain size which can be represented by 2r (twice the radius r).

The relative density of the sputtering target is preferably greater than or equal to 90%, greater than or equal to 95%, or greater than or equal to 99%. Note that the relative density of the sputtering target refers to a ratio between the density of the sputtering target and the density of a substance which is free of porosity and has the same composition as the sputtering target.

The sputtered particle which is formed by partly separating the crystal grain in the above manner has high crystallinity. By depositing the sputtered particles, an oxide film with a high degree of crystallinity can be formed.

Note that the sputtered particle is separated from the cleavage plane and thus has a flat plate-like shape (also referred to as a pellet shape). As obvious in terms of stability, the flat plate-like sputtered particle is attached to a deposition surface with a high probability that the cleavage plane and the deposition surface are parallel to each other. Thus, a crystal part of an oxide film to be formed is aligned along one crystal axis. For example, in the case where a cleavage plane of a crystal grain is parallel to an a-b plane, a crystal part of an oxide film has c-axis alignment. That is, a normal vector of the deposition surface and the c-axis of the crystal part included in the oxide film are parallel to each other. However, an a-axis is freely rotated on the c-axis; therefore, the directions of a-axes of a plurality of crystal parts included in the oxide film are not the same. In this specification, the trigonal and rhombohedral crystal systems are included in the hexagonal crystal system. In this specification, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

Although sputtered particles are ideally single crystals, crystallinity of part of the sputtered particles may be lowered due to the impact of ion collision and the like. Thus, in some cases, an oxide film that is to be deposited includes a region with low crystallinity between crystal parts.

Here, a cleavage plane of a crystal of an In—Ga—Zn oxide (In:Ga:Zn=1:1:1 [atomic ratio]) is described.

Classical molecular dynamics calculation was performed using Materials Explorer 5.0 manufactured by Fujitsu Limited. Note that the temperature, the time step size, and the number of steps were set to be 300 K, 0.01 fs, and ten million times, respectively. In addition, a crystal of an In—Ga—Zn oxide including 2688 atoms was used. In calculation, an argon atom to which an energy of 300 eV was applied was made to collide with the crystal of In—Ga—Zn oxide from a direction perpendicular to an a-b plane of Further, in calculation, a fixed layer is provided so as to fix the spatial coordinate of atoms. Furthermore, a layer whose temperature is set at a constant temperature (300 K) is provided as a temperature control layer.

After 100 ps of collision of the argon atom, the crystal of the In—Ga—Zn oxide was cleaved along the a-b plane into a first plane including Ga and Zn (a plane where Ga and Zn are mixed) and a second plane including Ga and Zn.

That is, it can be seen that, when an ion collides with a surface of a sputtering target which is an In—Ga—Zn oxide crystal, a crystal grain in the In—Ga—Zn oxide crystal is cleaved along a plane parallel to the a-b plane thereof, and flat-plate-like sputtered particles whose top and bottom surfaces are parallel to the a-b plane are separated from the sputtering target.

Note that the plurality of crystal grains are preferably hexagonal crystals. In the case where the plurality of crystal grains are hexagonal crystals, the sputtered particle separated from a cleavage plane has a hexagonal cylinder shape whose top and bottom surfaces are approximately equilateral hexagons each having an interior angle of 120°.

FIG. 1A is a schematic view illustrating a situation in which an ion 1001 collides with a sputtering target 1000, whereby a sputtered particle 1002 is separated. Note that the sputtered particle 1002 may have a hexagonal cylinder shape whose hexagonal plane is parallel to an a-b plane. In such a case, a direction perpendicular to the hexagonal plane is a c-axis direction (see FIG. 1B). The diameter of a plane of the sputtered particle 1002, which is parallel to the a-b plane, is about greater than or equal to 2 nm and less than or equal to 30 nm, although it differs depending on kinds of oxides. A case where the ion 1001 is an oxygen cation is described below.

A side surface, a top surface, or a bottom surface of the sputtered particle 1002 which is separated is positively charged. Alternatively, oxygen is bonded to the side surface, and such a bonding portion with oxygen has a positive charge. This is because the sputtered particle 1002 is exposed to plasma at the time of separation or after separation, or because the sputtered particle 1002 is bonded to an oxygen cation. In a state where the side surface, the top surface, or the bottom surface of the sputtered particle 1002 is positively charged, a plurality of sputtered particles 1002 repel with each other when the sputtered particles 1002 reach a deposition surface 1003, and the sputtered particle 1002 is deposited selectively on a region where an oxide has not been deposited. Accordingly, an oxide film is formed to have a uniform thickness (see FIG. 1C).

Alternatively, one embodiment of the present invention is a sputtering target including a polycrystalline oxide containing a plurality of crystal grains, in which the proportion of crystal grains having a grain size greater than or equal to 0.4 μm and less than or equal to 1 μm is 8% or higher.

In the case where in the plurality of crystal grains, the proportion of crystal grains having a grain size greater than or equal to 0.4 μm and less than or equal to 1 μm is 8% or higher, the sputtered particle is easily separated from a cleavage plane when an ion collides with a sputtering target. Thus, an oxide film with a high degree of crystallinity can be formed.

Further, in the case where in the plurality of crystal grains, the proportion of crystal grains having a grain size greater than or equal to 0.4 μm and less than or equal to 1 μm is 8% or higher, each of the crystal grains is reduced in size, and thus distortion in crystal is caused. Accordingly, separation easily occurs on a cleavage plane.

As such a polycrystalline oxide, an oxide containing In, M (M is any of Ga, Sn, Hf, Al, La, Ce, Pr, Nd, Sm, Eu, Gd, Tb, Dy, Ho, Er, Tm, Yb, or Lu), and Zn may be used, for example.

Moreover, the atomic ratio of In to M and Zn contained in the polycrystalline oxide is preferably close to the stoichiometric composition. When the atomic ratio of In to M and Zn contained in the polycrystalline oxide becomes close to the stoichiometric composition, the crystallinity of the polycrystalline oxide can be increased. Note that as described with “close”, the atomic ratio and the stoichiometric composition may deviate within the range of ±10%.

The crystal grains included in the polycrystalline oxide containing In, M, and Zn each have a cleavage plane between a first plane containing M and Zn and a second plane containing M and Zn.

The sputtering target that is a polycrystalline oxide is formed in the following manner, for example. First, an InO_{X} powder, a MO_{Y} powder, and a ZnO_{Z} powder are mixed in a predetermined molar ratio, and the mixed oxide powder is baked to obtain a reactant. Then, the reactant is ground to form an In-M-Zn oxide powder. After that, the oxide powder is made to spread over a mold for molding and subjected to pressure treatment, and then baking is performed, so that a plate-like oxide is formed. The oxide powder is made to spread again over the plate-like oxide in the mold for molding and subjected to pressure treatment, and then baking is performed, so that the plate-like oxide is made thick. By performing the step of making the plate-like oxide thick n (n is a natural number) times, the thickness of the plate-like oxide becomes greater than or equal to 2 mm and less than or equal to 20 mm, so that the sputtering target is obtained. Note that X, Y, and Z are each a given positive number.

The InO_{X} powder, the MO_{Y} powder, and the ZnO_{Z} powder are mixed in a predetermined molar ratio, and the mixed oxide powder is baked to obtain a polycrystalline In-M-Zn oxide. The polycrystalline In-M-Zn oxide has a cleavage plane parallel to an a-b plane; thus, an oxide powder which is obtained by grinding the mixed oxide powder includes a large amount of plate-like crystal grains each having a top surface and a bottom surface parallel to an a-b plane. When these plate-like crystal grains are made to spread over the mold and vibration is externally applied at the time of molding, the crystal grains are arranged with flat planes facing upward. Accordingly, the a-b planes of the crystal grains are parallel to each other. After that, the obtained oxide powder is made to spread for molding and subjected to pressure treatment and baking, whereby the proportion of the crystal grains whose a-b planes are parallel to each other is increased; thus, a polycrystalline In-M-Zn oxide with highly oriented c-axes is obtained. By performing grinding, molding, baking, and pressure treatment repeatedly as described above, polycrystalline In-M-Zn oxide whose c-axes are oriented can be gradually obtained.

The predetermined molar ratio of the InO_{X} powder to the MO_{Y} powder and the ZnO_{Z} powder is for example, 2:1:3, 2:2:1, 8:4:3, 3:1:1, 1:1:1, 1:3:2, 1:3:4, 1:6:2, 1:6:4, 1:6:8, 4:2:3, 1:1:2, 3:1:4, or 3:1:2. Note that the predetermined molar ratio may be changed as appropriate depending on sputtering targets to be formed.

Note that the sputtering target may be subjected to heat treatment at a temperature higher than or equal to 1000° C. and lower than or equal to 1500° C. for a period longer than or equal to 1 hour and shorter than or equal to 24 hours.

In the sputtering target formed in the above manner, c-axes can be highly oriented, and the proportion of crystal grains with a small size can be increased.

Another embodiment of the present invention is a method for using a sputtering target including a polycrystalline oxide containing a plurality of crystal grains each of which has a cleave plane. In the method for using a sputtering target, an ion is made to collide with the sputtering target, so that a sputtered particle is separated from the cleave plane.

Another embodiment of the present invention is an oxide film formed by using the sputtering target.

An example of a method for improving the degree of crystallinity of an oxide film is described below.

By reducing impurities that enter the oxide film, a crystal state is prevented from being disordered by the impurities and an oxide film with high crystallinity can be formed. For example, the concentration of impurities (e.g., hydrogen, water, carbon dioxide, or nitrogen) which exist in a film formation chamber may be reduced. Furthermore, the concentration of impurities in a deposition gas may be reduced. Specifically, a deposition gas whose dew point is −80° C. or lower, preferably −100° C. or lower is used.

When a surface where the oxide film is to be formed has minute unevenness, the degree of crystallinity of the oxide film is lowered. Thus, the planarity of the surface where the oxide film is to be formed is improved, whereby an oxide film with a high degree of crystallinity can be formed.

Further, by increasing the heating temperature during the film formation, migration of a sputtered particle occurs after the sputtered particle reach the deposition surface; therefore, an oxide film with a high degree of crystallinity can be formed. Specifically, the heating temperature during film formation is higher than or equal to 100° C. and lower than or equal to 740° C., preferably higher than or equal to 200° C. and lower than or equal to 500° C. By increasing the heating temperature during the film formation, when the flat-plate-like sputtered particle reaches the deposition surface, migration occurs on the deposition surface, so that a cleavage plane of the flat-plate-like sputtered particle is attached to the deposition surface.

Moreover, by increasing the proportion of oxygen included in the film formation gas and optimizing the power used for film formation, plasma damage at the film formation can be alleviated; accordingly, an oxide film with a high degree of crystallinity can be formed. The percentage of oxygen in the film formation gas is set to be higher than or equal to 30 vol. %, preferably higher than or equal to 50 vol. %, further preferably higher than or equal to 80 vol. %, still further preferably higher than or equal to 100 vol. %.

In addition, heat treatment is performed after the film formation to reduce the impurity concentration in the oxide film, whereby an oxide film with a high degree of crystallinity can be obtained. The heat treatment is highly effective in reducing the impurity concentration when performed in an inert atmosphere or a reduced-pressure atmosphere. For the heat treatment, heat treatment in an oxidation atmosphere is preferably performed after the heat treatment in an inert atmosphere or a reduced-pressure atmosphere is performed. This is due to oxygen vacancies generated in the oxide film as well as a reduction in the impurity concentration in the oxide film, in some cases, by the heat treatment performed in an inert atmosphere or a reduced-pressure atmosphere. By performing the heat treatment in an oxidation atmosphere, oxygen vacancies in the oxide film can be reduced.

In the above manner, an oxide film with a high degree of crystallinity can be formed.

The oxide film with a high degree of crystallinity is preferably a CAAC-OS (c-axis aligned crystalline oxide semiconductor) film.

The CAAC-OS film is one of oxide semiconductor films including a plurality of crystal parts, and most of crystal parts each fits inside a cube whose one side is less than 100 nm. Thus, there is a case where a crystal part included in the CAAC-OS film fits inside a cube whose one side is less than 10 nm, less than 5 nm, or less than 3 nm The CAAC-OS film is described in detail below.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 30.8°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor film of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

In a transistor using the CAAC-OS film, change in electric characteristics of the transistor due to irradiation with visible light or ultraviolet light is small. Thus, the transistor has high reliability.

Examples of a crystal structure of the crystal part in the CAAC-OS film are described in detail with reference to FIGS. 2A to 2E, FIGS. 3A to 3C, FIGS. 4A to 4C, and FIGS. 5A and 5B. In FIGS. 2A to 2E, FIGS. 3A to 3C, FIGS. 4A to 4C, and FIGS. 5A and 5B, the vertical direction corresponds to the c-axis direction and a plane perpendicular to the c-axis direction corresponds to the a-b plane, unless otherwise specified. When the expressions “an upper half” and “a lower half” are simply used, they refer to an upper half above the a-b plane and a lower half below the a-b plane (an upper half and a lower half with respect to the a-b plane). In FIGS. 2A to 2E, O surrounded by a circle represents tetracoordinate O and O surrounded by a double circle represents tricoordinate O.

FIG. 2A illustrates a structure including one hexacoordinate In atom and six tetracoordinate oxygen (hereinafter referred to as tetracoordinate O) atoms proximate to the In atom. Here, a structure including one metal atom and oxygen atoms proximate thereto is referred to as a small group. The structure in FIG. 2A is actually an octahedral structure, but is shown as a planar structure for easy understanding. Note that three tetracoordinate O atoms exist in each of the upper half and the lower half in FIG. 2A. In the small group illustrated in FIG. 2A, electric charge is O.

FIG. 2B illustrates a structure including one pentacoordinate Ga atom, three tricoordinate oxygen (hereinafter referred to as tricoordinate O) atoms proximate to the Ga atom, and two tetracoordinate O atoms proximate to the Ga atom. All the tricoordinate O atoms exist on the a-b plane. One tetracoordinate O atom exists in each of the upper half and the lower half in FIG. 2B. An In atom can also have the structure illustrated in FIG. 2B because the In atom can have five ligands. In the small group illustrated in FIG. 2B, electric charge is 0.

FIG. 2C illustrates a structure including one tetracoordinate Zn atom and four tetracoordinate O atoms proximate to the Zn atom. In FIG. 2C, one tetracoordinate O atom exists in the upper half and three tetracoordinate O atoms exist in the lower half. In the small group illustrated in FIG. 2C, electric charge is 0.

FIG. 2D illustrates a structure including one hexacoordinate Sn atom and six tetracoordinate O atoms proximate to the Sn atom. In FIG. 2D, three tetracoordinate O atoms exist in each of the upper half and the lower half. In the small group illustrated in FIG. 2D, electric charge is +1.

FIG. 2E illustrates a small group including two Zn atoms. In FIG. 2E, one tetracoordinate O atom exists in each of the upper half and the lower half. In the small group illustrated in FIG. 2E, electric charge is −1.

Here, a plurality of small groups form a medium group, and a plurality of medium groups form a large group.

Now, a rule of bonding between the small groups will be described. The three O atoms in the upper half with respect to the hexacoordinate In atom in FIG. 2A each have three proximate In atoms in the downward direction, and the three O atoms in the lower half each have three proximate In atoms in the upward direction. The one O atom in the upper half with respect to the pentacoordinate Ga atom in FIG. 2B has one proximate Ga atom in the downward direction, and the one O atom in the lower half has one proximate Ga atom in the upward direction. The one O atom in the upper half with respect to the tetracoordinate Zn atom in FIG. 2C has one proximate Zn atom in the downward direction, and the three O atoms in the lower half each have three proximate Zn atoms in the upward direction. In this manner, the number of the tetracoordinate O atoms above the metal atom is equal to the number of the metal atoms proximate to and below each of the tetracoordinate O atoms. Similarly, the number of the tetracoordinate O atoms below the metal atom is equal to the number of the proximity metal atoms above the tetracoordinate O atoms. Since the coordination number of the tetracoordinate O atom is 4, the sum of the number of the metal atoms proximate to and below the O atom and the number of the metal atoms proximate to and above the O atom is 4. Accordingly, when the sum of the number of tetracoordinate O above a metal atom and the number of tetracoordinate O below another metal atom is 4, the two kinds of small groups including the metal atoms can be bonded. For example, in the case where the hexacoordinate metal (In or Sn) atom is bonded through three tetracoordinate O atoms in the lower half, it is bonded to the pentacoordinate metal (Ga or In) atom or the tetracoordinate metal (Zn) atom.

A metal atom whose coordination number is 4, 5, or 6 is bonded to another metal atom through a tetracoordinate O atom in the c-axis direction. In addition to the above, a medium group can be formed in a different manner by combining a plurality of small groups so that the total electric charge of the layered structure is 0.

FIG. 3A illustrates a model of a medium group included in a layered structure of In—Sn—Zn oxide. FIG. 3B illustrates a large group including three medium groups. FIG. 3C illustrates an atomic arrangement where the layered structure in FIG. 3B is observed from the c-axis direction.

In FIG. 3A, for easy understanding, a tricoordinate O atom is omitted and the number of tetracoordinate O atoms is shown. For example, three tetracoordinate O atoms existing in each of an upper half and a lower half with respect to a Sn atom are denoted by circled 3. Similarly, one tetracoordinate O atom existing in each of an upper half and a lower half with respect to an In atom is denoted by circled 1. Further similarly, one tetracoordinate O atom existing in a lower half (or an upper half) with respect to a Zn atom is denoted by circled 1, and three tetracoordinate O atoms existing in upper half (or a lower half) with respect to the Zn atom is denoted by circled 3.

In the medium group included in the layered structure of the In—Sn—Zn oxide in FIG. 3A, in the order starting from the top, a Sn atom proximate to three tetracoordinate O atoms in each of an upper half and a lower half is bonded to an In atom proximate to one tetracoordinate O atom in each of an upper half and a lower half, the In atom is bonded to a Zn atom proximate to three tetracoordinate O atoms in an upper half, the Zn atom is bonded to an In atom proximate to three tetracoordinate O atoms in each of an upper half and a lower half through one tetracoordinate O atom in a lower half with respect to the Zn atom, the In atom is bonded to a small group that includes two Zn atoms and is proximate to one tetracoordinate O atom in an upper half, and the small group is bonded to a Sn atom proximate to three tetracoordinate O atoms in each of an upper half and a lower half through one tetracoordinate O atom in a lower half with respect to the small group. A plurality of such medium groups are bonded, so that a large group is formed.

Here, electric charge for one bond of a tricoordinate O atom and electric charge for one bond of a tetracoordinate O atom can be assumed to be −0.667 and −0.5, respectively. For example, electric charge of a (hexacoordinate or pentacoordinate) In atom, electric charge of a (tetracoordinate) Zn atom, and electric charge of a (pentacoordinate or hexacoordinate) Sn atom are +3, +2, and +4, respectively. Accordingly, electric charge in a small group including a Sn atom is +1. Consequently, a structure having an electric charge of −1, which cancels an electric charge of +1, is needed to form a layer structure of a small group including a Sn atom. As a structure having electric charge of −1, the small group including two Zn atoms as illustrated in the structure in FIG. 2E can be given. For example, with one small group including two Zn atoms, electric charge of one small group including a Sn atom can be cancelled, so that the total electric charge of the layered structure can be 0.

When the large group shown in FIG. 3B is repeated, an In—Sn—Zn oxide crystal (In₂SnZn₃O₈) can be obtained. Note that a layered structure of the obtained crystal of the In—Sn—Zn oxide can be expressed as a composition formula, In₂SnZnO₆(ZnO)ₘ (m is a natural number).

The above-described rule also applies to the following oxides: an In—Sn—Ga—Zn-based oxide, an In—Ga—Zn-based oxide, an In—Al—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide, and the like.

As an example, FIG. 4A illustrates a model of a medium group included in a layered structure of an In—Ga—Zn oxide.

In the medium group included in the layered structure of an In—Ga—Zn oxide in FIG. 4A, in the order starting from the top, an In atom proximate to three tetracoordinate O atoms in each of an upper half and a lower half is bonded to a Zn atom proximate to one tetracoordinate O atom in an upper half, the Zn atom is bonded to a Ga atom proximate to one tetracoordinate O atom in each of an upper half and a lower half through three tetracoordinate O atoms in a lower half with respect to the Zn atom, and the Ga atom is bonded to an In atom proximate to three tetracoordinate O atoms in each of an upper half and a lower half through one tetracoordinate O atom in a lower half with respect to the Ga atom. A plurality of such medium groups are bonded, so that a large group is formed.

FIG. 4B illustrates a large group including three medium groups. FIG. 4C illustrates an atomic arrangement where the layered structure in FIG. 4B is observed from the c-axis direction.

Here, since electric charge of a (hexacoordinate or pentacoordinate) In atom, electric charge of a (tetracoordinate) Zn atom, and electric charge of a (pentacoordinate) Ga atom are +3, +2, +3, respectively, electric charge of a small group including any of an In atom, a Zn atom, and a Ga atom is 0. As a result, the total electric charge of a medium group having a combination of such small groups is always 0.

In order to form the layered structure of the In—Ga—Zn oxide, a large group can be formed using not only the medium group illustrated in FIG. 4A but also a medium group in which the arrangement of the In atom, the Ga atom, and the Zn atom is different from that in FIG. 4A.

When the large group illustrated in FIG. 4B is repeated, a crystal of In—Ga—Zn oxide can be obtained. Note that the layered structure of an In—Ga—Zn oxide which is obtained can be expressed as a composition formula, InGaO₃ (ZnO)ₙ (n is a natural number).

In the case where n=1 (InGaZnO₄), a crystal structure illustrated in FIG. 5A can be obtained, for example. In the crystal structure in FIG. 5A, since a Ga atom and an In atom each have five ligands as described in FIG. 2B, Ga can be replaced with In in the structure.

In the case where n=2 (InGaZn₂O₅), a crystal structure illustrated in FIG. 5B can be obtained, for example. Note that in the crystal structure in FIG. 5B, since a Ga atom and an In atom each have five ligands as described in FIG. 2B, Ga can be replaced with In.

Described below is the reason why the In—Ga—Zn oxide has a high proportion of crystals with surface structures of planes parallel to an a-b plane.

When a crystal has an equilibrium form, the area of a surface along a plane having a small surface energy becomes large. Also, cleavage of a crystal is likely to occur in a plane having a small surface energy. Calculation results of the surface energy of each plane are described below.

Here, the surface energy refers to an energy obtained by subtracting the energy of a crystal structure from the energy of a surface structure and then dividing the value by a surface area.

First principle calculation software, CASTEP, which is based on the density functional theory was used for the calculation, an ultrasoft type was used for pseudopotential, and the cut-off energy was 400 eV.

FIGS. 6 to 9 each illustrate a crystal structure and a surface structure used for the calculation. Note that in the surface structures in FIGS. 6 to 9, a spatial portion indicates a vacuum. That is, a plane in contact with the spatial portion is a surface. Note that although there are both an upper surface and a lower surface, a lower space is omitted for easy understanding.

The surface energy of a surface structure (1) in FIG. 6 is an average value of a surface energy of a (001) plane including In and O and a surface energy of a (001) plane including Ga and O. The surface energy of a surface structure (2) is an average value of a surface energy of a (001) plane including Ga and O and a surface energy of a (001) plane including Zn and O. The surface energy of a surface structure (3) is an average value of a surface energy of a (001) plane including Zn and O and a surface energy of a (001) plane including In and O. The surface energy of the (001) plane including In and O, the surface energy of the (001) plane including Ga and O, and the surface energy of the (001) plane including Zn and O were calculated simultaneously by calculating the obtained surface energies of the surface structure (1), the surface structure (2), and the surface structure (3). In this specification, planes parallel to an a-b plane are described as a (001) plane for simplicity. Note that in some cases, other planes (e.g., a (100) plane and a (10-1) plane) are described in a similar manner.

A surface structure (4) illustrated in FIG. 7 is a (001) plane in which Ga and Zn are mixed, which exists both at an upper surface and a lower surface.

Note that a structure illustrated in FIG. 8 and a structure illustrated in FIG. 9 are a (100) plane and a (10-1) plane, respectively. Note that the (100) plane and the (10-1) plane each include plural kinds of surface energies. Since there are all kinds of elements in the outermost surfaces of the (100) plane and the (10-1) plane, an average value of typical two surface energies was regarded as a surface energy of each plane. In addition, a surface structure (6) and a surface structure (7) illustrate different surfaces and are simply described as a (10-1) plane_a and a (10-1) plane_b, respectively, for simplicity.

The surface energy of the surface structure (1) was 1.54 J/m².

The surface energy of the surface structure (2) was 1.24 J/m².

The surface energy of the surface structure (3) was 1.57 J/m².

When the surface energies of the surface structure (1), the surface structure (2), and the surface structure (3) were simultaneously calculated, the surface energy of the (001) plane including In and O was 1.88 J/m².

When the surface energies of the surface structure (1), the surface structure (2), and the surface structure (3) were simultaneously calculated, the surface energy of the (001) plane including Ga and O was 1.21 J/m².

When the surface energies of the surface structure (1), the surface structure (2), and the surface structure (3) were simultaneously calculated, the surface energy of the (001) plane including Zn and O was 1.26 J/m².

The surface energy of the surface structure (4) was 0.35 J/m².

The surface energy of the surface structure (5) was 1.64 J/m².

The surface energy of the surface structure (6) was 1.72 J/m².

The surface energy of the surface structure (7) was 1.79 J/m².

The above calculation results show that the surface energy of the surface structure (4) is the smallest. In other words, the smallest surface energy is obtained in the case where the (001) plane including Zn and Ga is a surface.

Accordingly, the crystal of In—Ga—Zn oxide has a high proportion of surface structures of planes parallel to the a-b plane.

Another embodiment of the present invention is a transistor including the above-described oxide film in a channel region.

Further, another embodiment of the present invention is a semiconductor device including the transistor.

A sputtering target including a polycrystalline oxide containing a plurality of crystal grains whose average grain size is less than or equal to 3 μm can be provided.

Further, an oxide film with a high degree of crystallinity can be formed by making an ion collide with the sputtering target and separating part of the crystal grain from a cleavage plane.

Further, with an oxide film with a high degree of crystallinity, a transistor with stable electric characteristics can be provided.

Further, a highly reliable semiconductor device including the transistor can be provided.

### BRIEF DESCRIPTION OF DRAWINGS

FIGS. 1A to 1C are schematic views illustrating sputtered particles separated from a sputtering target and a situation in which the sputtered particles reach a deposition surface.

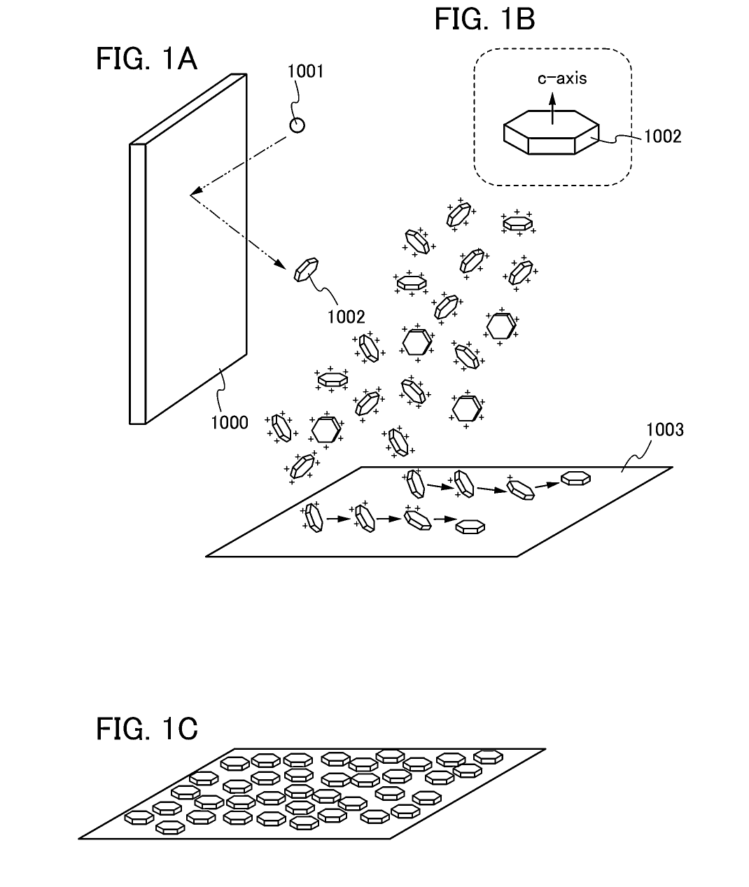

FIGS. 2A to 2E are diagrams each illustrating a crystal structure of an oxide semiconductor according to one embodiment of the present invention.

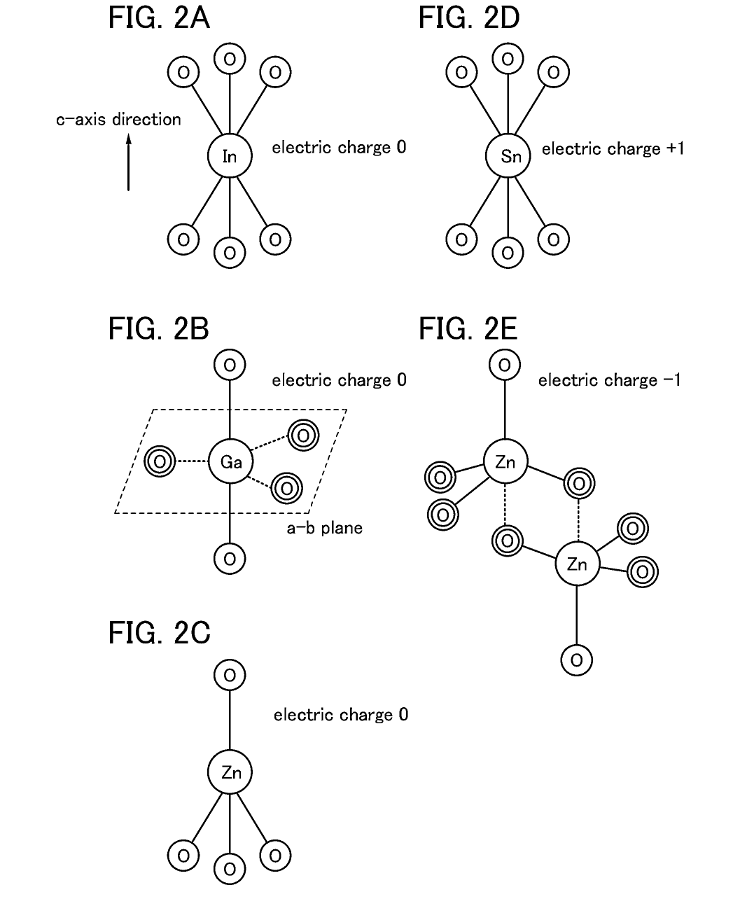

FIGS. 3A to 3C are diagrams illustrating a crystal structure of an oxide semiconductor according to one embodiment of the present invention.

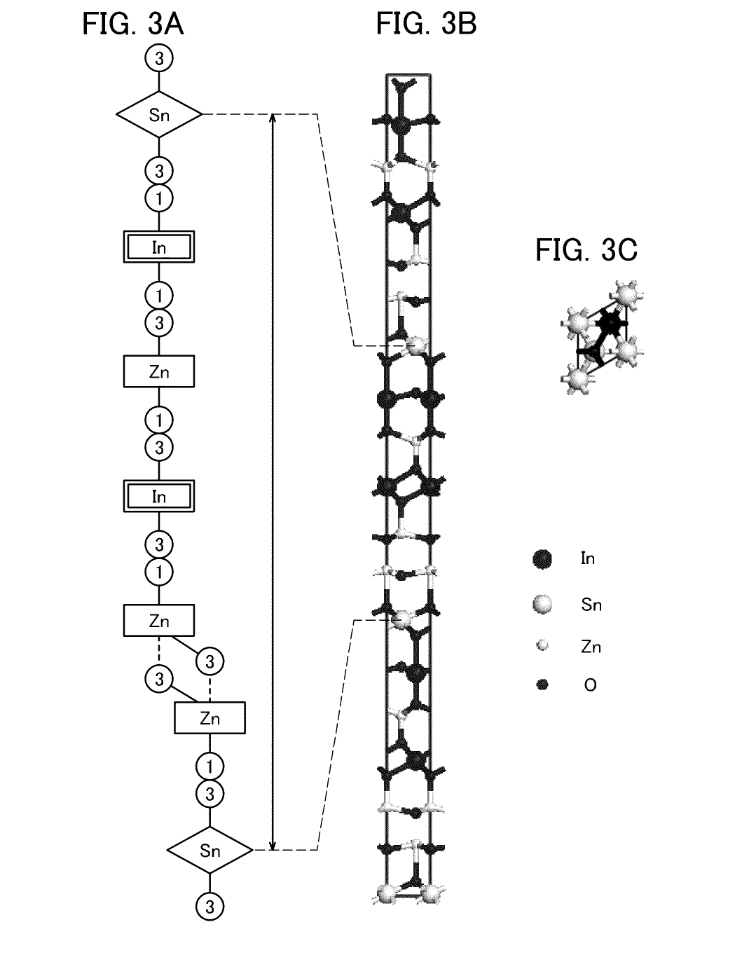

FIGS. 4A to 4C are diagrams illustrating a crystal structure of an oxide semiconductor according to one embodiment of the present invention.

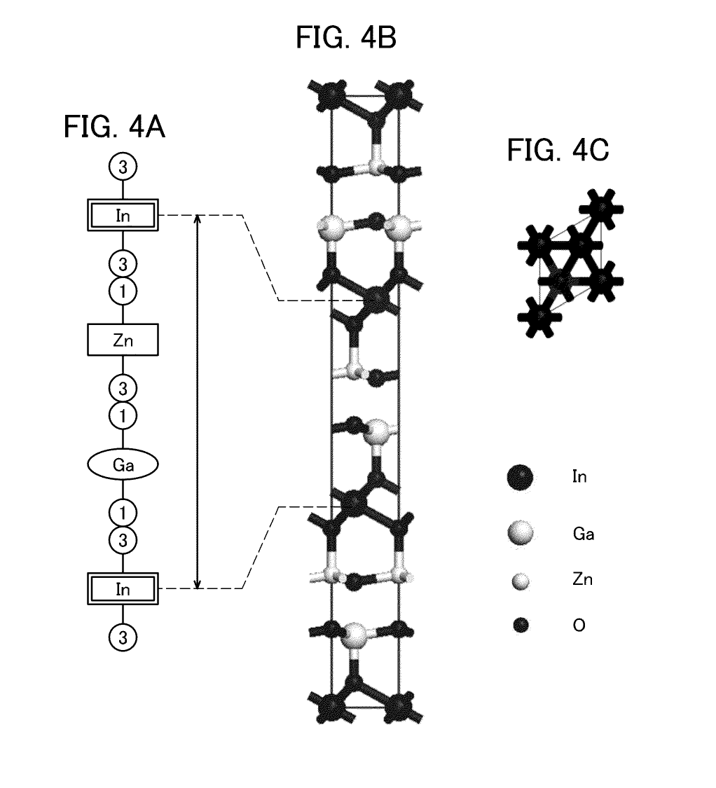

FIGS. 5A and 5B are diagrams each illustrating a crystal structure of an oxide semiconductor according to one embodiment of the present invention.

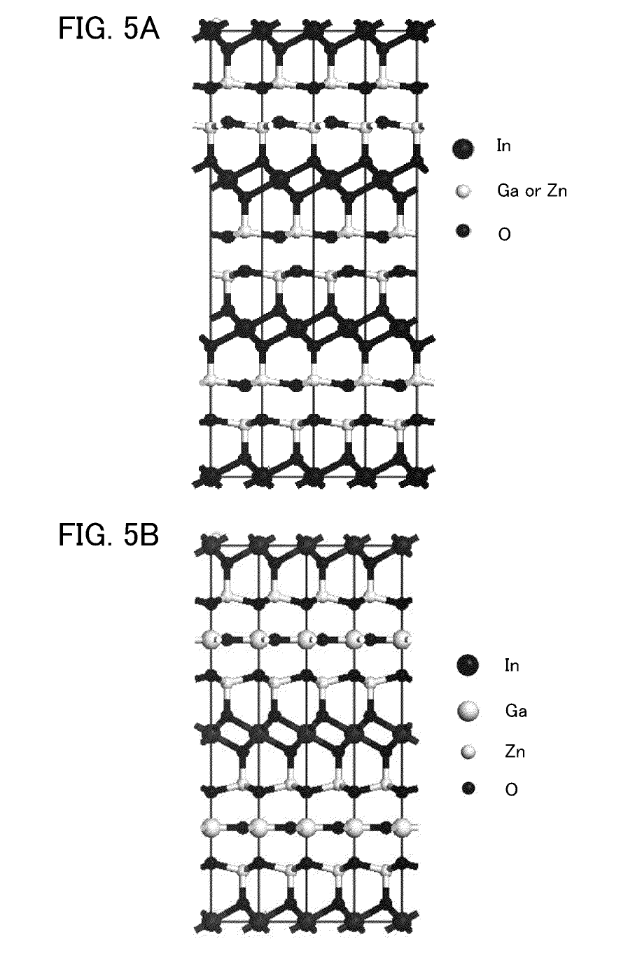

FIG. 6 illustrates a crystal structure and surface structures.

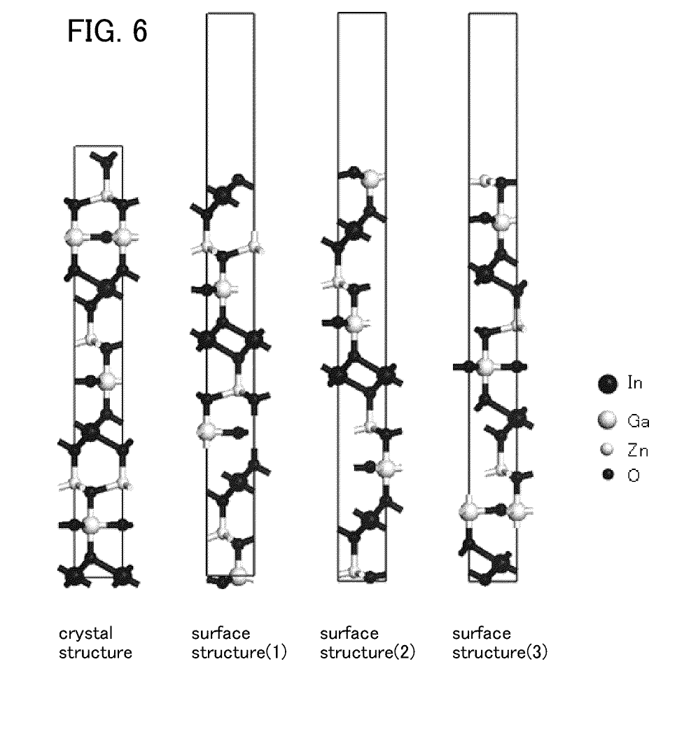

FIG. 7 illustrates a crystal structure and a surface structure.

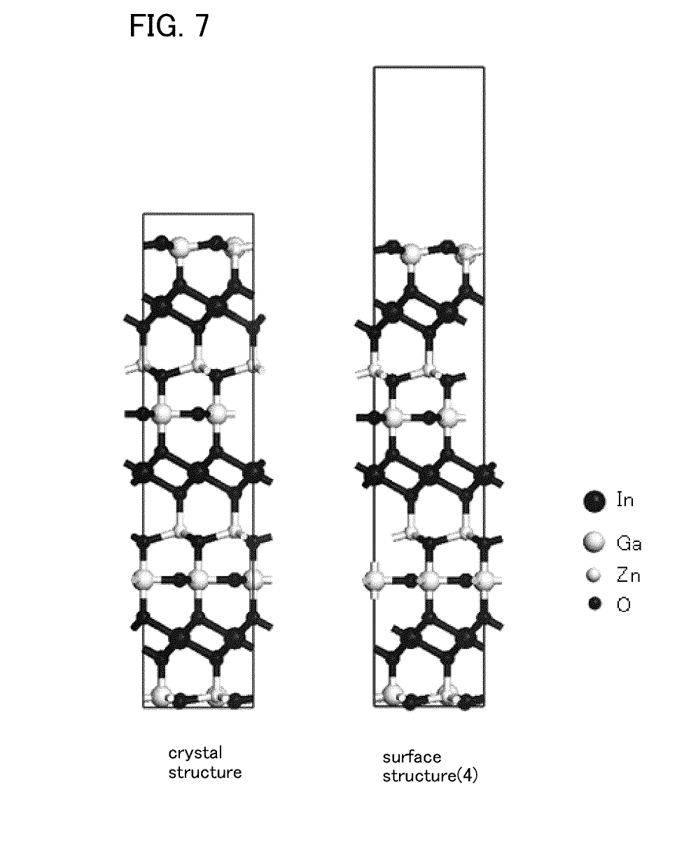

FIG. 8 illustrates a crystal structure and a surface structure.

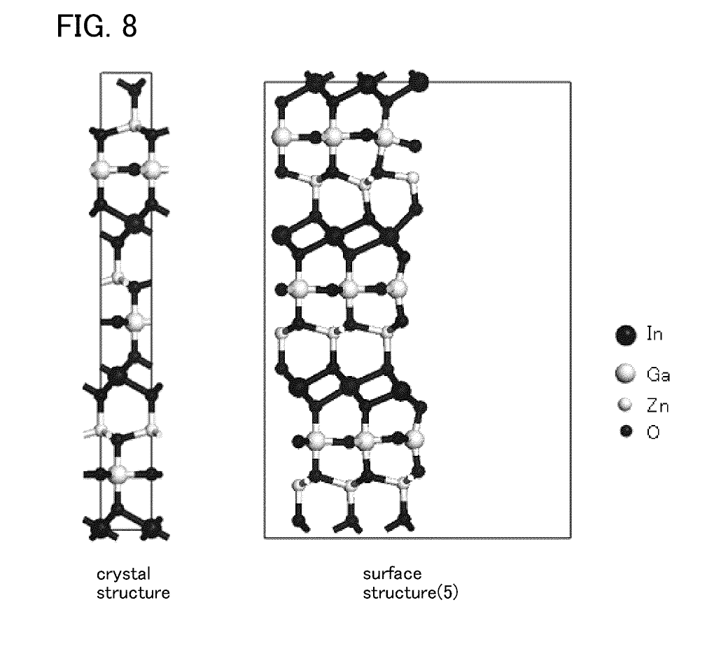

FIG. 9 illustrates a crystal structure and surface structures.

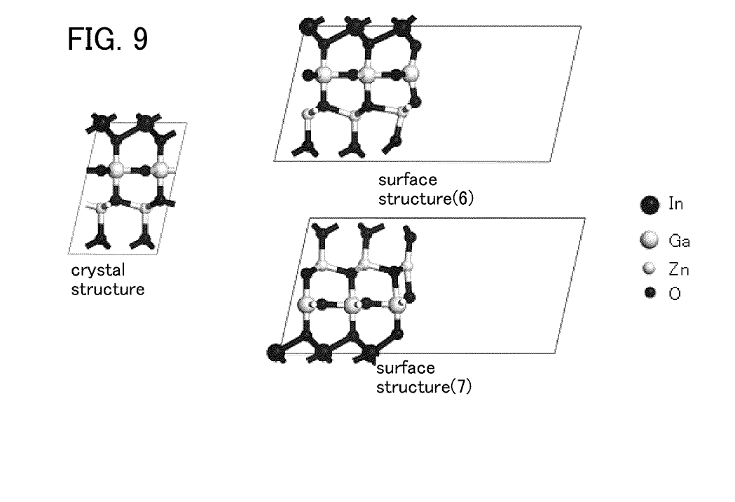

FIGS. 10A and 10B are flow charts showing an example of a method for manufacturing a sputtering target.

FIG. 11 is a top view illustrating an example of a structure of a film formation apparatus.

FIGS. 12A to 12C illustrate an example of a structure of a film formation apparatus.

FIGS. 13A to 13C are a top view and cross-sectional views illustrating an example of a transistor.

FIGS. 14A to 14C are a top view and cross-sectional views illustrating an example of a transistor.

FIGS. 15A to 15C are a top view and cross-sectional views illustrating an example of a transistor.

FIGS. 16A to 16C are a top view and cross-sectional views illustrating an example of a transistor.

FIGS. 17A to 17C are a top view and cross-sectional views illustrating an example of a transistor.

FIGS. 18A to 18C are a top view and cross-sectional views illustrating an example of a transistor.

FIG. 19A is a circuit diagram of a semiconductor device according to one embodiment of the present invention, and FIG. 19B is a cross-sectional view thereof.

FIGS. 20A and 20B are circuit diagrams of semiconductor devices according to one embodiment of the present invention.

FIG. 21A is a circuit diagram of a semiconductor device according to one embodiment of the present invention, and FIG. 21B is a cross-sectional view thereof.

FIG. 22 is a circuit diagram of a semiconductor device according to one embodiment of the present invention.

FIGS. 23A to 23C are circuit diagrams and a cross-sectional view illustrating a semiconductor device according to one embodiment of the present invention, and FIG. 23D is a graph showing electrical characteristics thereof.

FIG. 24A is a circuit diagram of a semiconductor device according to one embodiment of the present invention, FIG. 24B is a graph showing electric characteristics thereof, and FIG. 24C is a cross-sectional view thereof.

FIGS. 25A to 25C are block diagrams illustrating a structure of a CPU according to one embodiment of the present invention.

FIG. 26 is a circuit diagram showing part of a pixel in a display device using an EL element, according to one embodiment of the present invention.

FIGS. 27A and 27B are a top view and a cross-sectional view illustrating a display device using an EL element, according to one embodiment of the present invention, and FIG. 27C is a cross-sectional view illustrating a light-emitting layer.

FIGS. 28A and 28B are each a cross-sectional view of a display device using an EL element, according to one embodiment of the present invention.

FIG. 29 is a circuit diagram of a pixel of a display device using a liquid crystal element, according to one embodiment of the present invention.

FIGS. 30A to 30C are each a cross-sectional view of a display device using a liquid crystal element, according to one embodiment of the present invention.

FIGS. 31A to 31D each illustrate an electronic device according to one embodiment of the present invention.

FIG. 32 is a backscattered electron image of Sample 1.

FIG. 33A shows a crystal grain map of Sample 1, and FIG. 33B is a histogram of grain sizes thereof.

FIG. 34A shows a crystal grain map of Sample 2, and FIG. 34B is a histogram of grain sizes thereof.

FIG. 35A is a crystal grain map of Sample 3, and FIG. 35B is a histogram of grain sizes thereof.

FIG. 36A is a graph showing crystal alignment of an oxide film 1 and an oxide film 2, and FIG. 36B is a graph showing crystal alignment of an oxide film 3 and an oxide film 4.

FIGS. 37A and 37B are a bright-field image and a HAADF-STEM image of an oxide film 5 obtained with an STEM.

FIGS. 38A and 38B are a bright-field image and a HAADF-STEM image of an oxide film 6 obtained with an STEM.

### BEST MODE FOR CARRYING OUT THE INVENTION

Hereinafter, embodiments of the present invention will be described in detail with reference to the accompanying drawings. However, the present invention is not limited to the description below, and it is easily understood by those skilled in the art that modes and details thereof can be modified in various ways. Therefore, the present invention is not construed as being limited to description of the embodiments. In describing structures of the present invention with reference to the drawings, the same reference numerals are used in common for the same portions in different drawings. Note that the same hatch pattern is applied to similar parts, and the similar parts are not especially denoted by reference numerals in some cases.

Note that the ordinal numbers such as “first” and “second” in this specification are used for convenience and do not denote the order of steps or the stacking order of layers. In addition, the ordinal numbers in this specification do not denote particular names which specify the present invention.

### Embodiment 1

In this embodiment, a sputtering target of one embodiment of the present invention will be described.

The sputtering target includes a polycrystalline oxide containing a plurality of crystal grains whose average grain size is less than or equal to 3 μm, preferably less than or equal to 2.5 μm, further preferably less than or equal to 2 μm.

Alternatively, the sputtering target includes a polycrystalline oxide containing a plurality of crystal grains, in which the proportion of crystal grains whose grain size is greater than or equal to 0.4 μm and less than or equal to 1 μm is 8% or higher, preferably 15% or higher, further preferably 25% or higher.

Further, the plurality of crystal grains included in the sputtering target have cleavage planes. The cleavage plane is a plane parallel to an a-b plane, for example.

The relative density of the sputtering target is higher than or equal to 90%, higher than or equal to 95%, or higher than or equal to 99%.

Owing to small grain sizes of the plurality of crystal grains, when an ion collides with the sputtering target, a sputtered particle is separated from the cleavage plane. The separated sputtered particle has a flat plate-like shape whose top and bottom surfaces are parallel to the cleavage plane. Further, owing to small grain sizes of the plurality of crystal grains, distortion in crystal is caused and a sputtered particle becomes easily separated from the cleavage plane.

Note that when the plurality of crystal grains included in the sputtering target are hexagonal crystals, flat plate-like sputtered particles each have the shape of a hexagonal cylinder whose top and bottom surfaces are approximately equilateral hexagons each having internal angles of 120°.

Although sputtered particles are ideally single crystals, part of the sputtered particles may be amorphous due to the impact of ion collision and the like.

As such a polycrystalline oxide included in the sputtering target, an oxide containing In, M (M is Ga, Sn, Hf, Al, La, Ce, Pr, Nd, Sm, Eu, Gd, Tb, Dy, Ho, Er, Tm, Yb, or Lu), and Zn is used. The oxide containing In, M, and Zn is also referred to as In-M-Zn oxide.

Moreover, the atomic ratio of In to M and Zn contained in the In-M-Zn oxide is preferably close to the stoichiometric composition. When the atomic ratio of In to M and Zn contained in the In-M-Zn oxide becomes close to the stoichiometric composition, the crystallinity of the polycrystalline oxide can be increased.

In the In-M-Zn oxide, a cleavage plane is, in many cases, a plane parallel to an a-b plane in which M and Zn are mixed.

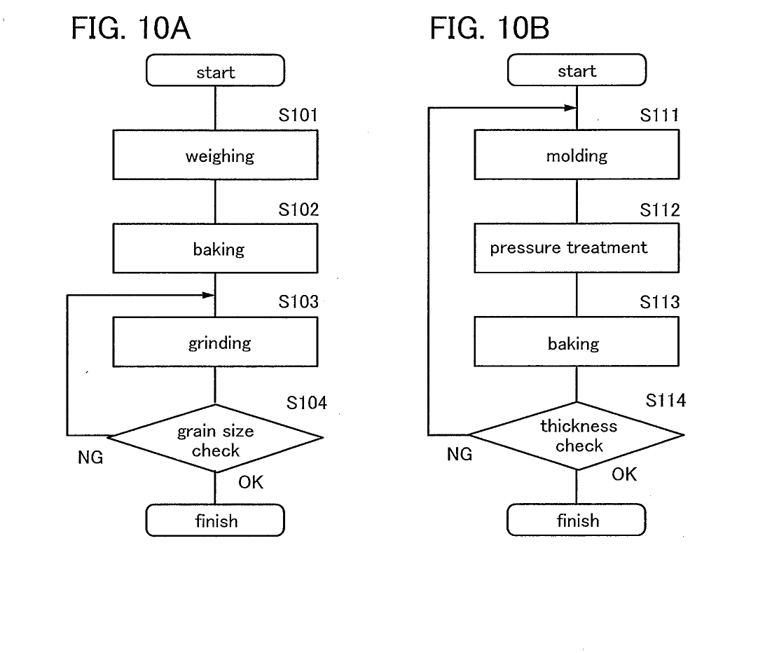

A method for forming the above sputtering target is described with reference to FIGS. 10A and 10B.

FIG. 10A shows formation of an oxide powder containing a plurality of metal elements to be a sputtering target. First, the oxide powder is weighed in a step S101.

Here, description is given on the case where an oxide powder containing In, M, and Zn (also referred to as an In-M-Zn oxide powder) is obtained as the oxide powder containing a plurality of metal elements. Specifically, an InO_{X} oxide powder, an MO_{Y} oxide powder, and a ZnO_{Z} oxide powder are prepared as a raw material. Note that X, Y, and Z are each a given positive number; for example, X, Y, and Z are 1.5, 1.5, and 1, respectively. It is needless to say that the above oxide powders are an example, and oxide powders can be selected as appropriate in order to obtain a desired composition. Note that M refers to Ga, Sn, Hf, Al, La, Ce, Pr, Nd, Sm, Eu, Gd, Tb, Dy, Ho, Er, Tm, Yb, or Lu. Although the case where three kinds of oxide powders are used is shown as an example in this embodiment, one embodiment of the present invention is not limited thereto. For example, this embodiment may be applied to the case where four or more kinds of oxide powders are used or the case where one or two kinds of oxide powders are used.

Next, the InO_{X} powder, the MO_{Y} powder, and the ZnO_{Z} powder are mixed in a predetermined molar ratio.

For example, the predetermined molar ratio of the InO_{X} oxide powder, the MO_{Y} oxide powder, and the ZnO_{Z} oxide powder is 2:1:3, 2:2:1, 8:4:3, 3:1:1, 1:1:1, 1:3:2, 1:3:4, 1:6:2, 1:6:4, 1:6:8, 4:2:3, 1:1:2, 3:1:4, or 3:1:2. With such a molar ratio, a sputtering target including a polycrystalline oxide with high crystallinity can be obtained easily later.

Next, in a step S102, an In-M-Zn oxide is obtained by performing first baking on the InO_{X} oxide powder, the MO_{Y} oxide powder, and the ZnO_{Z} oxide powder which are mixed in a predetermined molar ratio.

Note that the first baking is performed in an inert atmosphere, an oxidation atmosphere, or a reduced-pressure atmosphere at a temperature higher than or equal to 400° C. and lower than or equal to 1700° C., preferably higher than or equal to 900° C. and lower than or equal to 1500° C. The first baking is performed for longer than or equal to 3 minutes and shorter than or equal to 24 hours, preferably longer than or equal to 30 minutes and shorter than or equal to 17 hours, further preferably longer than or equal to 30 minutes and shorter than or equal to 5 hours, for example. When the first baking is performed under the above conditions, secondary reactions other than the main reaction can be suppressed, and the impurity concentration in the In-M-Zn oxide can be reduced. Accordingly, the crystallinity of the In-M-Zn oxide can be increased.

The first baking may be performed plural times at different temperatures and/or in different atmospheres. For example, the In-M-Zn oxide may be first held at a first temperature in a first atmosphere and then at a second temperature in a second atmosphere. Specifically, it is preferable that the first atmosphere be an inert atmosphere or a reduced-pressure atmosphere and the second atmosphere be an oxidation atmosphere. This is because oxygen vacancies may be generated in the In-M-Zn oxide when impurities contained in the In-M-Zn oxide are reduced in the first atmosphere. Therefore, it is preferable that oxygen vacancies in the obtained In-M-Zn oxide be reduced in the second atmosphere. The impurity concentration and oxygen vacancies in the In-M-Zn oxide are reduced, whereby the crystallinity of the In-M-Zn oxide can be increased.

Next, the In-M-Zn oxide powder is obtained by grinding the In-M-Zn oxide in a step S103.

The In-M-Zn oxide has a high proportion of crystals with surface structures of planes parallel to the a-b plane. Therefore, the obtained In-M-Zn oxide powder includes many flat plate-like crystal grains whose top and bottom surfaces are parallel to the a-b plane. Moreover, the crystal of the In-M-Zn oxide is in many cases a hexagonal crystal; therefore, in many cases, the above flat plate-like crystal grains each have the shape of a hexagonal cylinder whose top and bottom surfaces are approximately equilateral hexagons each having internal angles of 120°.

Next, the grain size of the obtained In-M-Zn oxide powder is checked in a step S104. Here, the average grain size of the In-M-Zn oxide powder is checked to be less than or equal to 3 μm, preferably less than or equal to 2.5 μm, further preferably less than or equal to 2 μm. Note that the step S104 may be omitted and only the In-M-Zn oxide powder whose grain size is less than or equal to 3 μm, preferably less than or equal to 2.5 μm, further preferably less than or equal to 2 μm may be sifted using a grain size filter. The average grain size of the In-M-Zn oxide powder can be certainly less than or equal to 3 μm, preferably less than or equal to 2.5 μm, further preferably less than or equal to 2 μm by sifting the In-M-Zn oxide powder to have the grain size which is less than or equal to 3 μm, preferably less than or equal to 2.5 μm, further preferably less than or equal to 2 μm.

In the case where the average grain size of the In-M-Zn oxide powder exceeds a predetermined size in the step S104, the procedure returns to the step S103 and the In-M-Zn oxide powder is ground again.

In the above manner, the In-M-Zn oxide powder whose average grain size is less than or equal to 3 μm, preferably less than or equal to 2.5 μm, further preferably less than or equal to 2 μm can be obtained. Note that the average grain size of the obtained In-M-Zn oxide powder is less than or equal to 3 μm, preferably less than or equal to 2.5 μm, further preferably less than or equal to 2 μm, which enables the grain size of a crystal grain included in a sputtering target that is to be formed later to be reduced.

Next, FIG. 10B shows formation of a sputtering target with use of the In-M-Zn oxide powder obtained in the flow chart shown in FIG. 10A.

In a step S111, the In-M-Zn oxide powder is made to spread over a mold and molded. Here, molding refers to making the In-M-Zn oxide powder spread over a mold to obtain a uniform thickness. Specifically, the In-M-Zn oxide powder is introduced to the mold, and then vibration is externally applied so that the In-M-Zn oxide powder is molded. Alternatively, the In-M-Zn oxide powder is introduced to the mold, and then molding is performed using a roller or the like so as to obtain a uniform thickness. Note that in the step S111, slurry in which the In-M-Zn oxide powder is mixed with water, a dispersant, and a binder may be molded. In that case, a filter is spread over the mold, and the slurry is poured into the mold and then molded by sucking the mold from the bottom through a filter. After that, drying treatment is performed on a molded body after the mold is sucked. The drying treatment is preferably natural drying because the molded body is less likely to be cracked. After that, the molded body is subjected to heat treatment at a temperature higher than or equal to 300° C. and lower than or equal to 700° C., so that residual moisture or the like which cannot be taken out by natural drying is removed. Note that as the filter, a filter in which a porous resin film is attached over a woven fabric or a felt may be used.

When the In-M-Zn oxide powder including many flat-plate-like crystal grains whose top and bottom surfaces are parallel to the a-b plane is made to spread over the mold and molded, the crystal grains are arranged with the planes which are parallel to the a-b plane thereof facing upward. Therefore, the proportion of the surface structures of planes parallel to the a-b plane can be increased in such a manner that the obtained In-M-Zn oxide powder is made to spread over the mold and molded. Note that the mold may be formed of a metal or an oxide and the upper shape thereof is rectangular or rounded.

Next, first pressure treatment is performed on the In-M-Zn oxide powder in a step S112. Then, second baking is performed on the In-M-Zn oxide powder which has been subjected to the first pressure treatment, whereby plate-like In-M-Zn oxide is obtained in a step S113. The second baking may be performed under conditions similar to those of the first baking. The crystallinity of the In-M-Zn oxide can be increased by performing the second baking.

Note that the first pressure treatment may be performed in any manner as long as the In-M-Zn oxide powder can be pressed. For example, a weight which is formed of the same kind of material as the mold can be used. Alternatively, the In-M-Zn oxide powder may be pressed under high pressure using compressed air. Besides, the first pressure treatment can be performed using a known technique. Note that the first pressure treatment may be performed at the same time as the second baking.

Planarization treatment may be performed after the first pressure treatment. As the planarization treatment, chemical mechanical polishing (CMP) treatment or the like can be employed.

The plate-like In-M-Zn oxide thus obtained becomes a polycrystalline oxide with high crystallinity.

Next, the thickness of the obtained plate-like In-M-Zn oxide is checked in a step S114. When the thickness of the plate-like In-M-Zn oxide is less than a desired thickness, the procedure returns to the step S111 and the In-M-Zn oxide powder is made to spread over the plate-like In-M-Zn oxide and molded. When the plate-like In-M-Zn oxide has a desired thickness in the step S114, the plate-like In-M-Zn oxide is used as a sputtering target. The description of steps following the step S111 when the thickness of the plate-like In-M-Zn oxide is less than a desired thickness is given below.

After the step S111, in the step S112, second pressure treatment is performed on the plate-like In-M-Zn oxide and the In-M-Zn oxide powder over the plate-like In-M-Zn oxide. Then, in the step S113, third baking is performed, whereby a plate-like In-M-Zn oxide whose thickness is increased by the thickness of the In-M-Zn oxide powder is obtained. A plate-like In-M-Zn oxide with an increased thickness is obtained through crystal growth with use of the plate-like In-M-Zn oxide as a seed crystal; therefore, the plate-like In-M-Zn oxide is a polycrystalline oxide with high crystallinity.

Note that the third baking may be performed under conditions similar to those of the second baking. The second pressure treatment may be performed under conditions similar to those of the first pressure treatment. Note that the second pressure treatment may be performed at the same time as the third baking.

The thickness of the obtained plate-like In-M-Zn oxide is checked again in the step S114.

Through the above steps, the thickness of the plate-like In-M-Zn oxide can be gradually increased while the crystal alignment is improved.

By repeating these steps of increasing the thickness of a plate-like In-M-Zn oxide n (n is a natural number) times, the plate-like In-M-Zn oxide having a desired thickness, for example, greater than or equal to 2 mm and less than or equal to 20 mm, preferably greater than or equal to 3 mm and less than or equal to 20 mm can be obtained. The plate-like In-M-Zn oxide is used as a sputtering target.

After that, planarization treatment may be performed.

Note that fourth baking may be performed on the obtained sputtering target. The fourth baking may be performed under conditions similar to those of the first baking. A sputtering target including a polycrystalline oxide with much higher crystallinity can be obtained by performing the fourth baking.

In the above manner, the sputtering target which includes a polycrystalline oxide containing a plurality of crystal grains having cleavage planes parallel to the a-b plane and a small average grain size can be formed.

Note that the sputtering target formed in such a manner can have high density. When the density of the sputtering target is increased, the density of a film to be formed can also be increased. Specifically, the relative density of the sputtering target can be set to be higher than or equal to 90%, higher than or equal to 95%, or higher than or equal to 99%.

This embodiment can be implemented in appropriate combination with any other embodiments and example.

### Embodiment 2

In this embodiment, a method for using the sputtering target described in Embodiment 1 will be described. In particular, a method for forming an oxide film with a high degree of crystallinity by using the sputtering target described in Embodiment 1 will be described.

The sputtering target is used by collision of an ion with a surface of the sputtering target.

As an ion, an oxygen cation is used. Further, in addition to the oxygen cation, an argon cation may be used. Instead of the argon cation, a cation of another rare gas may be used.

With use of the oxygen cation as the ion, plasma damage at the film formation can be alleviated. Thus, when the ion collides with the surface of the sputtering target, a lowering in crystallinity of the sputtering target can be suppressed or a change of the sputtering target into an amorphous state can be suppressed.

When the ion collides with the surface of the sputtering target, a crystal grain included in the sputtering target is separated along a cleavage plane, so that a sputtered particle is generated.

The sputtered particle has a flat-plate-like shape with top and bottom surfaces parallel to the cleavage plane and high crystallinity. The preferable shape of the sputtered particle is a hexagonal cylinder. Description below is made on the assumption that the sputtered particle has a hexagonal cylinder shape.

A side surface, a top surface, or a bottom surface of the sputtered particle which has been separated is positively charged because the sputtered particle has properties in which the side surface, the top surface, or the bottom surface is likely to be positively charged.

There is no particular limitation on a timing of when the sputtered particle is positively charged, but there is a specific case where the sputtered particle receives electric charge at the time of collision of the ion, thereby being positively charged. Alternatively, there is a case where, when plasma is generated, the sputtered particle is exposed to the plasma, thereby being positively charged. Further alternatively, there is a case where the oxygen cation is bonded to the side surface, the top surface, or the bottom surface of the sputtered particle, whereby the sputtered particle is positively charged.

When the side surface, the top surface, or the bottom surface of the sputtered particle is positively charged, the sputtered particle repels with other sputtered particles at the time of reaching a deposition surface and is deposited selectively on a region where an oxide has not been deposited. Thus, an oxide film with a uniform thickness can be formed.

As a sputtering apparatus, a parallel-plate-type sputtering apparatus, an ion beam sputtering apparatus, a facing-target-type sputtering apparatus, or the like may be used. In the case of using the facing-target-type sputtering apparatus, a position of a deposition surface is away from plasma; thus, damage in deposition is less generated. As a result, an oxide film with a high degree of crystallinity can be formed.

Note that it is preferable that the sputtering target be used in an environment where the concentration of impurities (hydrogen, water, carbon dioxide, nitrogen, or the like) is low. Further, in the case where a deposition gas is used, the impurity concentration in the deposition gas is preferably reduced. Specifically, a deposition gas whose dew point is −80° C. or lower, preferably −100° C. or lower may be used. The proportion of oxygen in the deposition gas is preferably 30 vol % or higher, preferably 100 vol %.

By using the sputtering target as described above, an oxide film with a high degree of crystallinity can be formed. For example, a CAAC-OS film with a high degree of crystallinity can be formed.

This embodiment can be implemented in appropriate combination with any of the other embodiments and example.

### Embodiment 3

In this embodiment, a film formation apparatus with which the oxide film with a high degree of crystallinity described in Embodiment 2 is formed will be described.

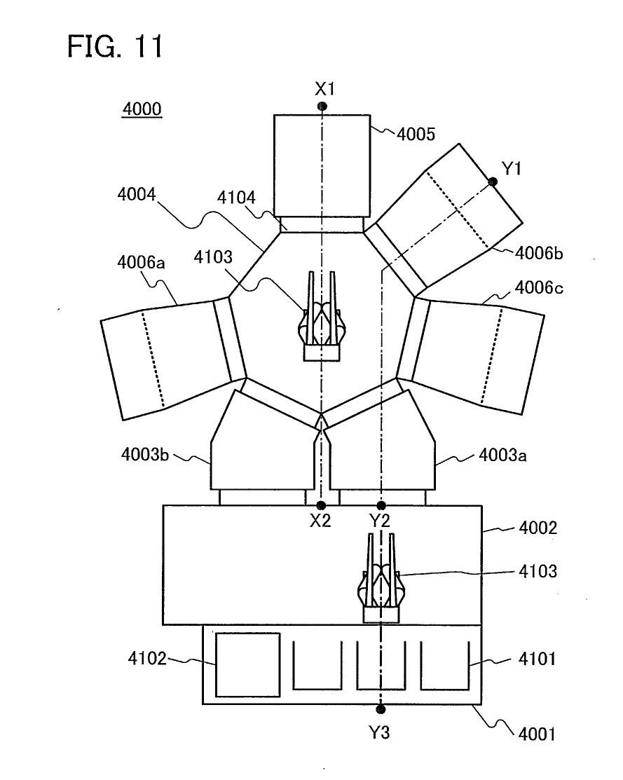

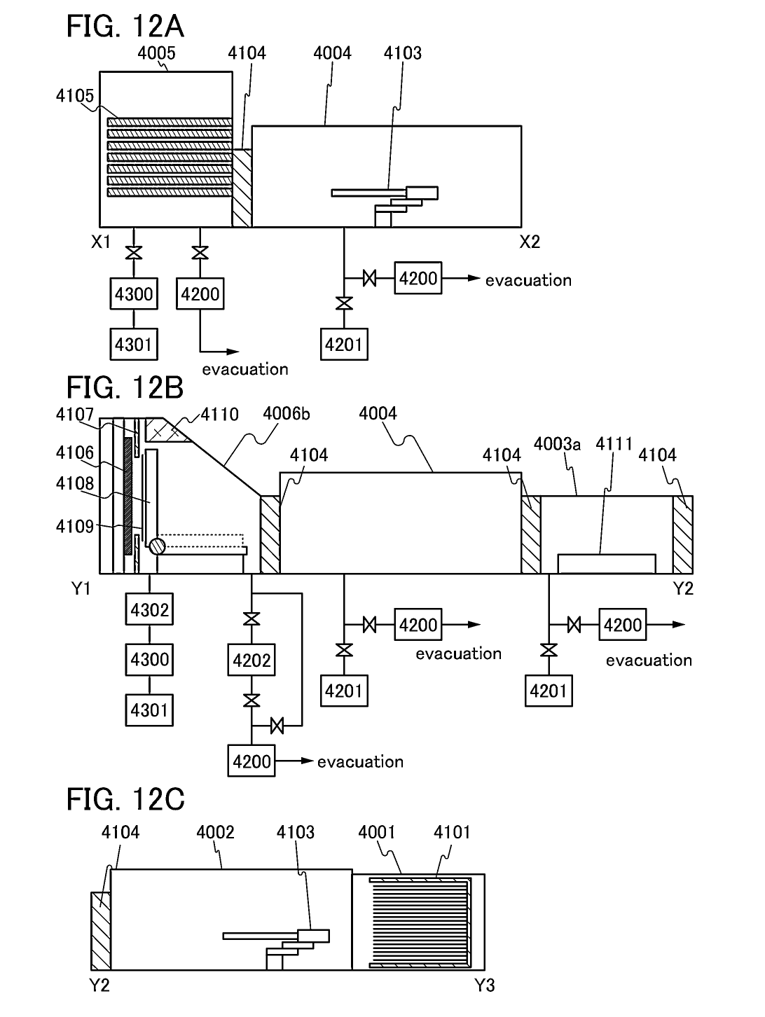

First, a structure of a film formation apparatus which allows the entry of few impurities into a film during film formation is described with reference to FIG. 11 and FIGS. 12A to 12C.

FIG. 11 is a top view schematically illustrating a single wafer multi-chamber film formation apparatus 4000. The film formation apparatus 4000 includes an atmosphere-side substrate supply chamber 4001 including a cassette port 4101 for holding a substrate and an alignment port 4102 for performing alignment of a substrate, an atmosphere-side substrate transfer chamber 4002 through which a substrate is transferred from the atmosphere-side substrate supply chamber 4001, a load lock chamber 4003a where a substrate is carried and the pressure inside the chamber is switched from atmospheric pressure to reduced pressure or from reduced pressure to atmospheric pressure, an unload lock chamber 4003b where a substrate is carried out and the pressure inside the chamber is switched from reduced pressure to atmospheric pressure or from atmospheric pressure to reduced pressure, a transfer chamber 4004 through which a substrate is transferred in a vacuum, a substrate heating chamber 4005 where a substrate is heated, and film formation chambers 4006a, 4006b, and 4006c in each of which a target is placed for film formation.

Note that a plurality of the cassette ports 4101 may be provided as illustrated in FIG. 11 (in FIG. 11, three cassette ports 4101 are provided).

The atmosphere-side substrate transfer chamber 4002 is connected to the load lock chamber 4003a and the unload lock chamber 4003b, the load lock chamber 4003a and the unload lock chamber 4003b are connected to the transfer chamber 4004, and the transfer chamber 4004 is connected to the substrate heating chamber 4005 and the film formation chambers 4006a, 4006b, and 4006c.

Gate valves 4104 are provided for connecting portions between chambers so that each chamber except the atmosphere-side substrate supply chamber 4001 and the atmosphere-side substrate transfer chamber 4002 can be independently kept under vacuum. Moreover, the atmosphere-side substrate transfer chamber 4002 and the transfer chamber 4004 each include a transfer robot 4103, with which a glass substrate can be transferred.

Further, it is preferable that the substrate heating chamber 4005 also serve as a plasma treatment chamber. The film formation apparatus 4000 enables a substrate to transfer without being exposed to the air between treatment and treatment; therefore, adsorption of impurities on the substrate can be suppressed. In addition, the order of treatment such as film formation, heat treatment, or the like can be freely determined Note that the number of the transfer chambers, the number of the film formation chambers, the number of the load lock chambers, the number of the unload lock chambers, and the number of the substrate heating chambers are not limited to the above, and the numbers thereof can be set as appropriate depending on the space for placement or the process conditions.

Next, FIG. 12A, FIG. 12B, and FIG. 12C are a cross-sectional view taken along dashed-dotted line X1-X2, a cross-sectional view taken along dashed-dotted line Y1-Y2, and a cross-sectional view taken along dashed-dotted line Y2-Y3, respectively, in the film formation apparatus 4000 illustrated in FIG. 11.

FIG. 12A is a cross section of the substrate heating chamber 4005 and the transfer chamber 4004, and the substrate heating chamber 4005 includes a plurality of heating stages 4105 which can hold a substrate. Note that although the substrate heating chamber 4005 including the seven heating stages 4105 is illustrated in FIG. 12A, one embodiment of the present invention is not limited to such a structure. The number of heating stages 4105 may be greater than or equal to one and less than seven. Alternatively, the number of heating stages 4105 may be greater than or equal to eight. It is preferable to increase the number of the heating stages 4105 because a plurality of substrates can be subjected to heat treatment at the same time, which leads to an increase in productivity. Further, the substrate heating chamber 4005 is connected to a vacuum pump 4200 through a valve. As the vacuum pump 4200, a dry pump and a mechanical booster pump can be used, for example.

As heating mechanism which can be used for the substrate heating chamber 4005, a resistance heater or the like may be used for heating, for example. Alternatively, heat conduction or heat radiation from a medium such as a heated gas may be used as the heating mechanism. For example, a rapid thermal annealing (RTA) apparatus such as a gas rapid thermal annealing (GRTA) apparatus or a lamp rapid thermal annealing (LRTA) apparatus can be used. The LRTA treatment is treatment for heating an object by radiation of light (an electromagnetic wave) emitted from a lamp, such as a halogen lamp, a metal halide lamp, a xenon arc lamp, a carbon arc lamp, a high-pressure sodium lamp, or a high-pressure mercury lamp. A GRTA apparatus is an apparatus for performing heat treatment using a high-temperature gas. An inert gas is used as a gas.

Moreover, the substrate heating chamber 4005 is connected to a refiner 4301 through a mass flow controller 4300. Note that although the refiner 4301 and the mass flow controller 4300 can be provided for each of a plurality of kinds of gases, only one refiner 4301 and one mass flow controller 4300 are provided for easy understanding. As the gas introduced to the substrate heating chamber 4005, a gas whose dew point is −80° C. or lower, preferably −100° C. or lower can be used; for example, an oxygen gas, a nitrogen gas, and a rare gas (e.g., an argon gas) are used.

The transfer chamber 4004 includes the transfer robot 4103. The transfer robot 4103 includes a plurality of movable portions and an arm for holding a substrate and can transfer a substrate to each chamber. Further, the transfer chamber 4004 is connected to a vacuum pump 4200 and a cryopump 4201 through valves. With such a structure, evacuation can be performed using the vacuum pump 4200 when the pressure inside the transfer chamber 4004 is in the range of atmospheric pressure to low vacuum (approximately 0.1 Pa to several hundred Pa) and then, by switching the valves, evacuation can be performed using the cryopump 4201 when the pressure inside the transfer chamber 4004 is in the range of middle vacuum to ultra-high vacuum (0.1 Pa to 1×10⁻⁷ Pa).

Alternatively, two or more cryopumps 4201 may be connected in parallel to the transfer chamber 4004. With such a structure, even when one of the cryopumps is in regeneration, evacuation can be performed using any of the other cryopumps. Note that the above regeneration refers to treatment for discharging molecules (or atoms) entrapped in the cryopump. When molecules (or atoms) are entrapped too much in a cryopump, the evacuation capability of the cryopump is lowered; therefore, regeneration is performed regularly.

FIG. 12B is a cross section of the film formation chamber 4006b, the transfer chamber 4004, and the load lock chamber 4003a.

Here, the details of the film formation chamber (sputtering chamber) are described with reference to FIG. 12B. The film formation chamber 4006b illustrated in FIG. 12B includes a target 4106, an attachment protection plate 4107, and a substrate stage 4108. Note that here, a substrate 4109 is provided on the substrate stage 4108. Although not illustrated, the substrate stage 4108 may include a substrate holding mechanism which holds the substrate 4109, a rear heater which heats the substrate 4109 from the back surface, or the like.

Note that the substrate stage 4108 is held substantially vertically to a floor during film formation and is held substantially parallel to the floor when the substrate is delivered. In FIG. 12B, the position where the substrate stage 4108 is held when the substrate is delivered is denoted by a dashed line. With such a structure, the probability that dust or a particle which might be mixed into the film formation is attached to the substrate 4109 can be lowered as compared to the case where the substrate stage 4108 is held parallel to the floor. However, there is a possibility that the substrate 4109 falls when the substrate stage 4108 is held vertically (90°) to the floor; therefore, the angle of the substrate stage 4108 to the floor is preferred to be greater than or equal to 80° and lower than 90°.

The attachment protection plate 4107 can suppress deposition of a particle which is sputtered from the target 4106 on a region where deposition is not needed. Moreover, the attachment protection plate 4107 is preferably processed to prevent accumulated sputtered particles from being separated. For example, blasting treatment which increases surface roughness may be performed, or roughness may be formed on the surface of the attachment protection plate 4107.

The film formation chamber 4006b is connected to a mass flow controller 4300 through a gas heating system 4302, and the gas heating system 4302 is connected to a refiner 4301 through the mass flow controller 4300. With the gas heating system 4302, a gas to be introduced to the film formation chamber 4006b can be heated to a temperature higher than or equal to 40° C. and lower than or equal to 400° C., preferably higher than or equal to 50° C. and lower than or equal to 200° C. Note that although the gas heating system 4302, the mass flow controller 4300, and the refiner 4301 can be provided for each of a plurality of kinds of gases, only one gas heating system 4302, one mass flow controller 4300, and one refiner 4301 are provided for easy understanding. As the gas introduced to the film formation chamber 4006b, a gas whose dew point is −80° C. or lower, preferably −100° C. or lower can be used; for example, an oxygen gas, a nitrogen gas, and a rare gas (e.g., an argon gas) are used.

In the case where the refiner is provided just before the gas is introduced, the length of a pipe between the refiner and the film formation chamber 4006b is less than or equal to 10 m, preferably less than or equal to 5 m, further preferably less than or equal to 1 m. When the length of the pipe is less than or equal to 10 m, less than or equal to 5 m, or less than or equal to 1 m, the effect of the release of gas from the pipe can be reduced accordingly. As the pipe of the gas, a metal pipe the inside of which is covered with an iron fluoride, an aluminum oxide, a chromium oxide, or the like can be used. With the above pipe, the amount of released gas containing impurities is made small and the entry of impurities into the gas can be reduced as compared with a SUS316L-EP pipe, for example. Further, a high-performance ultra-compact metal gasket joint (a UPG joint) is preferably used as a joint of the pipe. Further, a high-performance ultra-compact metal gasket joint (UPG joint) may be used as a joint of the pipe. A structure where all the materials of the pipe are metals is preferable because the effect of the generated released gas or the external leakage can be reduced compared with a structure where resin or the like is used.

The film formation chamber 4006b is connected to a turbo molecular pump 4202 and a vacuum pump 4200 through valves.

In addition, the film formation chamber 4006b is provided with a cryotrap 4110.

The cryotrap 4110 is a mechanism which can adsorb a molecule (or an atom) having a relatively high melting point, such as water. The turbo molecular pump 4202 is capable of stably evacuating a large-sized molecule (or atom), needs low frequency of maintenance, and thus enables high productivity, whereas it has a low capability in evacuating hydrogen and water. Hence, the cryotrap 4110 is connected to the film formation chamber 4006b so as to have a high capability in evacuating water or the like. The temperature of a refrigerator of the cryotrap 4110 is set to be lower than or equal to 100 K, preferably lower than or equal to 80 K. In the case where the cryotrap 4110 includes a plurality of refrigerators, it is preferable to set the temperature of each refrigerator at a different temperature because efficient evacuation is possible. For example, the temperatures of a first-stage refrigerator and a second-stage refrigerator may be set at lower than or equal to 100 K and lower than or equal to 20 K, respectively.

Note that the evacuation method of the film formation chamber 4006b is not limited to the above, and a structure similar to that in the evacuation method described in the transfer chamber 4004 (the evacuation method using the cryopump and the vacuum pump) may be employed. Needless to say, the evacuation method of the transfer chamber 4004 may have a structure similar to that of the film formation chamber 4006b (the evacuation method using the turbo molecular pump and the vacuum pump).

Note that in each of the above transfer chamber 4004, the substrate heating chamber 4005, and the film formation chamber 4006b, the back pressure (total pressure) and the partial pressure of each gas molecule (atom) are preferably set as follows. In particular, the back pressure and the partial pressure of each gas molecule (atom) in the film formation chamber 4006b need to be noted because impurities might enter a film to be formed.

In each of the above chambers, the back pressure (total pressure) is less than or equal to 1×10⁻⁴ Pa, preferably less than or equal to 3×10⁻⁵ Pa, further preferably less than or equal to 1×10⁻⁵ Pa. In each of the above chambers, the partial pressure of a gas molecule (atom) having a mass-to-charge ratio (m/z) of 18 is less than or equal to 3×10⁻⁵ Pa, preferably less than or equal to 1×10⁻⁵ Pa, further preferably less than or equal to 3×10⁻⁶ Pa. Further, in each of the above chambers, the partial pressure of a gas molecule (atom) having a mass-to-charge ratio (m/z) of 28 is less than or equal to 3×10⁻⁵ Pa, preferably less than or equal to 1×10⁻⁵ Pa, further preferably less than or equal to 3×10⁻⁶ Pa. Moreover, in each of the above chambers, the partial pressure of a gas molecule (atom) having a mass-to-charge ratio (m/z) of 44 is less than or equal to 3×10⁻⁵ Pa, preferably less than or equal to 1×10⁻⁵ Pa, further preferably less than or equal to 3×10⁻⁶ Pa.

Note that a total pressure and a partial pressure in a vacuum chamber can be measured using a mass analyzer. For example, Qulee CGM-051, a quadrupole mass analyzer (also referred to as Q-mass) manufactured by ULVAC, Inc. may be used.

Moreover, the above transfer chamber 4004, the substrate heating chamber 4005, and the film formation chamber 4006b preferably have a small amount of external leakage or internal leakage.

For example, in each of the above transfer chamber 4004, the substrate heating chamber 4005, and the film formation chamber 4006b, the leakage rate is less than or equal to 3×10⁻⁶ Pa·m³/s, preferably less than or equal to 1×10⁻⁶ Pa·m³/s. The leakage rate of a gas molecule (atom) having a mass-to-charge ratio (m/z) of 18 is less than or equal to 1×10⁻⁷ Pa·m³/s, preferably less than or equal to 3×10⁻⁸ Pa·m³/s. The leakage rate of a gas molecule (atom) having a mass-to-charge ratio (m/z) of 28 is less than or equal to 1×10⁻⁵ Pa·m³/s, preferably less than or equal to 1×10⁻⁶ Pa·m³/s. The leakage rate of a gas molecule (atom) having a mass-to-charge ratio (m/z) of 44 is less than or equal to 3×10⁻⁶ Pa·m³/s, preferably less than or equal to 1×10⁻⁶ Pa·m³/s.

Note that a leakage rate can be derived from the total pressure and partial pressure measured using the mass analyzer.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or due to gas released from an internal member. Measures need to be taken from both aspects of external leakage and internal leakage in order that the leakage rate be lower than or equal to the above value.

For example, an open/close portion of the film formation chamber 4006b can be sealed with a metal gasket. For the metal gasket, metal covered with an iron fluoride, an aluminum oxide, or a chromium oxide is preferably used. The metal gasket realizes higher adhesion than an O-ring, and can reduce the external leakage. Further, with use of the metal covered with an iron fluoride, an aluminum oxide, a chromium oxide, or the like which is in the passive state, the release of gas containing impurities released from the metal gasket is suppressed, so that the internal leakage can be reduced.

For a member of the film formation apparatus 4000, aluminum, chromium, titanium, zirconium, nickel, or vanadium, which releases a smaller amount of gas containing impurities, is used. Alternatively, an alloy containing iron, chromium, nickel, and the like covered with the above member may be used. The alloy containing iron, chromium, nickel, and the like is rigid, resistant to heat, and suitable for processing. Here, when surface unevenness of the member is decreased by polishing or the like to reduce the surface area, the release of gas can be reduced.

Alternatively, the above member of the film formation apparatus 4000 may be covered with an iron fluoride, an aluminum oxide, a chromium oxide, or the like.

The member of the film formation apparatus 4000 is preferably formed with only metal as much as possible. For example, in the case where a viewing window formed with quartz or the like is provided, it is preferable that the surface of the member be thinly covered with an iron fluoride, an aluminum oxide, a chromium oxide, or the like so as to suppress the released gas.

When an adsorbate is present in the film formation chamber, the adsorbate does not affect the pressure in the film formation chamber because it is adsorbed onto an inner wall or the like; however, the adsorbate causes gas to be released when the inside of the film formation chamber is evacuated. Therefore, although there is no correlation between the leakage rate and the evacuation rate, it is important that the adsorbate present in the film formation chamber be desorbed as much as possible and evacuation be performed in advance with use of a pump with high evacuation capability. Note that the film formation chamber may be baked to promote desorption of the adsorbate. By the baking, the rate of desorption of the adsorbate can be increased about tenfold. The baking can be performed at a temperature in the range of 100° C. to 450° C. At this time, when the adsorbate is removed while an inert gas is introduced to the deposition chamber, the desorption rate of water or the like, which is difficult to desorb simply by evacuation, can be further increased. Note that the rate of desorption of the adsorbate can be further increased by heating of the inert gas to be introduced at substantially the same temperature as the temperature of the baking. Here, a rare gas is preferably used as an inert gas. Depending on the kind of a film to be formed, oxygen or the like may be used instead of an inert gas. For example, in the case of depositing an oxide, using oxygen which is the main component of the oxide is preferable in some cases.

Alternatively, treatment for evacuating the inside of the film formation chamber is preferably performed a certain period of time after heated oxygen, a heated inert gas such as a rare gas, or the like is introduced to increase a pressure in the film formation chamber. The introduction of the heated gas can desorb the adsorbate in the film formation chamber, and the impurities present in the film formation chamber can be reduced. Note that an advantageous effect can be achieved when this treatment is repeated more than or equal to twice and less than or equal to 30 times, preferably more than or equal to 5 times and less than or equal to 15 times. Specifically, an inert gas, oxygen, or the like with a temperature higher than or equal to 40° C. and lower than or equal to 400° C., preferably higher than or equal to 50° C. and lower than or equal to 200° C. is introduced to the film formation chamber, so that the pressure therein can be kept to be greater than or equal to 0.1 Pa and less than or equal to 10 kPa, preferably greater than or equal to 1 Pa and less than or equal to 1 kPa, further preferably greater than or equal to 5 Pa and less than or equal to 100 Pa in the time range of 1 minute to 300 minutes, preferably 5 minutes to 120 minutes. After that, the inside of the film formation chamber is evacuated in the time range of 5 minutes to 300 minutes, preferably 10 minutes to 120 minutes.

The rate of desorption of the adsorbate can be further increased also by dummy film formation. The rate of desorption of the adsorbate can be further increased also by dummy film formation. Here, the dummy film formation refers to film formation on a dummy substrate by a sputtering method or the like, in which a film is deposited on the dummy substrate and the inner wall of the film formation chamber so that impurities in the film formation chamber and an adsorbate on the inner wall of the film formation chamber are confined in the film. For a dummy substrate, a substrate which releases a smaller amount of gas is preferably used. By performing dummy film formation, the impurity concentration in a film to be formed later can be reduced. Note that the dummy film formation may be performed at the same time as the baking of the film formation chamber.

Next, the details of the transfer chamber 4004 and the load lock chamber 4003a illustrated in FIG. 12B and the atmosphere-side substrate transfer chamber 4002 and the atmosphere-side substrate supply chamber 4001 illustrated in FIG. 12C are described. Note that FIG. 12C is a cross section of the atmosphere-side substrate transfer chamber 4002 and the atmosphere-side substrate supply chamber 4001.

For the transfer chamber 4004 illustrated in FIG. 12B, the description of the transfer chamber 4004 illustrated in FIG. 12A can be referred to.

The load lock chamber 4003a includes a substrate delivery stage 4111. When a pressure in the load lock chamber 4003a becomes an atmospheric pressure by being increased from a reduced pressure, the substrate delivery stage 4111 receives a substrate from the transfer robot 4103 provided in the atmosphere-side substrate transfer chamber 4002. After that, the load lock chamber 4003a is evacuated into vacuum so that the pressure therein becomes a reduced pressure and then the transfer robot 4103 provided in the transfer chamber 4004 receives the substrate from the substrate delivery stage 4111.

Further, the load lock chamber 4003a is connected to a vacuum pump 4200 and a cryopump 4201 through valves. For a method for connecting evacuation systems such as the vacuum pump 4200 and the cryopump 4201, the description of the method for connecting the transfer chamber 4004 can be referred to, and the description thereof is omitted here. Note that the unload lock chamber 4003b illustrated in FIG. 11 can have a structure similar to that in the load lock chamber 4003a.

The atmosphere-side substrate transfer chamber 4002 includes the transfer robot 4103. The transfer robot 4103 can deliver a substrate from the cassette port 4101 to the load lock chamber 4003a or deliver a substrate from the load lock chamber 4003a to the cassette port 4101. Further, a mechanism for cleaning dust or a particle, such as high efficiency particulate air (HEPA) filter, may be provided above the atmosphere-side substrate transfer chamber 4002 and the atmosphere-side substrate supply chamber 4001.

The atmosphere-side substrate supply chamber 4001 includes a plurality of the cassette ports 4101. The cassette port 4101 can hold a plurality of substrates.

When an oxide film is formed with use of the above film formation apparatus, the entry of impurities into the oxide film can be suppressed. Further, when a film in contact with the oxide film is formed with use of the above film formation apparatus, the entry of impurities into the oxide film from the film in contact therewith can be suppressed.

Next, a method for forming a CAAC-OS film with use of the above film formation apparatus is described.

In order to form the oxide film, the sputtering target described in Embodiment 1 is used.

The surface temperature of the sputtering target is set to be lower than or equal to 100° C., preferably lower than or equal to 50° C., further preferably about room temperature (typically, 25° C.). In a sputtering apparatus for a large substrate, a large sputtering target is often used. However, it is difficult to form a sputtering target for a large substrate without a juncture. In fact, a plurality of sputtering targets are arranged so that there is as little space as possible therebetween to obtain a large shape; however, a slight space is inevitably generated. From such a slight space, Zn or the like is volatilized from and the space might be expanded gradually when the surface temperature of the sputtering target increases, in some cases. When the space expands, a metal of a backing plate or a metal used for adhesion might be sputtered and cause an increase in impurity concentration. Thus, it is preferable that the sputtering target be cooled sufficiently.

Specifically, for the backing plate, a metal having high conductivity and a high heat dissipation property (specifically Cu) is used. The sputtering target can be cooled efficiently by making a sufficient amount of cooling water flow through a water channel which is formed in the backing plate.

The oxide film is formed in an oxygen gas atmosphere with a substrate heating temperature higher than or equal to 100° C. and lower than or equal to 600° C., preferably higher than or equal to 150° C. and lower than or equal to 550° C., further preferably higher than or equal to 200° C. and lower than or equal to 500° C. The thickness of the oxide film is greater than or equal to 1 nm and less than or equal to 40 nm, preferably greater than or equal to 3 nm and less than or equal to 20 nm. As the substrate heating temperature during the film formation is higher, the impurity concentration in the obtained oxide film is lower. Further, migration of sputtered particles on a deposition surface is likely to occur; therefore, the atomic arrangement in the oxide film is ordered and the density thereof is increased, so that a CAAC-OS film with a high degree of crystallinity is formed easily. Furthermore, when the film formation is performed in an oxygen gas atmosphere, plasma damage is alleviated and a surplus atom such as a rare gas atom is not contained in the oxide film, whereby a CAAC-OS film with a high degree of crystallinity is formed easily. Note that the film formation may be performed in a mixed atmosphere including an oxygen gas and a rare gas. In that case, the percentage of an oxygen gas is set to be greater than or equal to 30 vol. %, preferably greater than or equal to 50 vol. %, further preferably greater than or equal to 80 vol. %.

Note that in the case where the sputtering target includes Zn, plasma damage is alleviated by the film formation in an oxygen gas atmosphere; thus, an oxide film in which Zn is unlikely to be volatilized can be obtained.

The oxide film is formed under conditions in which the film formation pressure is less than or equal to 0.8 Pa, preferably less than or equal to 0.4 Pa, and the distance between the sputtering target and a substrate is less than or equal to 100 mm, preferably less than or equal to 40 mm, further preferably less than or equal to 25 mm. When the oxide film is formed under such a condition, the frequency of the collision between a sputtered particle and another sputtered particle, a gas molecule, or an ion can be reduced. That is, depending on the film formation pressure, the distance between the sputtering target and the substrate is made shorter than the mean free path of a sputtered particle, a gas molecule, or an ion, so that the entry of impurities into the film can be reduced.

For example, when the pressure is 0.4 Pa and the temperature is 25° C. (the absolute temperature is 298 K), a hydrogen molecule (H₂) has a mean free path of 48.7 mm, a helium atom (He) has a mean free path of 57.9 mm, a water molecule (H₂O) has a mean free path of 31.3 mm, an ethane molecule (CH₄) has a mean free path of 13.2 mm, a neon atom (Ne) has a mean free path of 42.3 mm, a nitrogen molecule (N₂) has a mean free path of 23.2 mm, a carbon monoxide molecule (CO) has a mean free path of 16.0 mm, an oxygen molecule (O₂) has a mean free path of 26.4 mm, an argon atom (Ar) has a mean free path of 28.3 mm, a carbon dioxide molecule (CO₂) has a mean free path of 10.9 mm, a krypton atom (Kr) has a mean free path of 13.4 mm, and a xenon atom (Xe) has a mean free path of 9.6 mm Note that doubling of the pressure halves a mean free path and doubling of the absolute temperature doubles a mean free path.

The mean free path depends on pressure, temperature, and the diameter of a molecule (atom). In the case where pressure and temperature are constant, as the diameter of a molecule (atom) is larger, the mean free path is shorter. Note that the diameters of the molecules (atoms) are as follows: H₂: 0.218 nm; He: 0.200 nm; H₂O: 0.272 nm; CH₄: 0.419 nm; Ne: 0.234 nm; N₂: 0.316 nm; CO: 0.380 nm; O₂: 0.296 nm; Ar: 0.286 nm; CO₂: 0.460 nm; Kr: 0.415 nm; and Xe: 0.491 nm.

Thus, as the diameter of a molecule (atom) is larger, the mean free path is shorter and the degree of crystallinity is lowered due to the large diameter of the molecule (atom) when the molecule (atom) enters the film. For this reason, it can be said that, for example, a molecule (atom) whose diameter is larger than that of Ar is likely to behave as an impurity.

Next, heat treatment is performed. The heat treatment is performed under reduced pressure or in an inert atmosphere or an oxidation atmosphere. By the heat treatment, the impurity concentration in the oxide film can be reduced.

The heat treatment is preferably performed in a manner such that after heat treatment is performed under reduced pressure or in an inert atmosphere, the atmosphere is switched to an oxidation atmosphere with the temperature maintained and heat treatment is further performed. When the heat treatment is performed under reduced pressure or in an inert atmosphere, the impurity concentration in the oxide film can be reduced; however, oxygen vacancies are caused at the same time. By the heat treatment in an oxidation atmosphere, the caused oxygen vacancies can be reduced.

When heat treatment is performed on the oxide film in addition to the substrate heating during the film formation, the impurity concentration in the film can be reduced.

Specifically, the concentration of hydrogen in the oxide film, which is measured by secondary ion mass spectrometry (SIMS), can be set to be lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³.

The concentration of nitrogen in the oxide film, which is measured by SIMS, can be set to be lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

The concentration of carbon in the oxide film, which is measured by SIMS, can be set to be lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

The amount of each of the following gas molecules (atoms) released from the oxide film can be less than or equal to 1×10¹⁹/cm³, preferably less than or equal to 1×10¹⁸/cm³ or less, which is measured by thermal desorption spectroscopy (TDS) analysis: a gas molecule (atom) having a mass-to-charge ratio (m/z) of 2 (e.g., hydrogen molecule), a gas molecule (atom) having a mass-to-charge ratio (m/z) of 18, a gas molecule (atom) having a mass-to-charge ratio (m/z) of 28, and a gas molecule (atom) having a mass-to-charge ratio (m/z) of 44.

A measurement method of the amount of released oxygen atoms, which is to be described later, is referred to for a measurement method of the release amount using TDS analysis.

In the above manner, an oxide film with a high degree of crystallinity can be formed.

This embodiment can be implemented in appropriate combination with any of the other embodiments.

### Embodiment 4

In this embodiment, a transistor according to one embodiment of the present invention will be described.

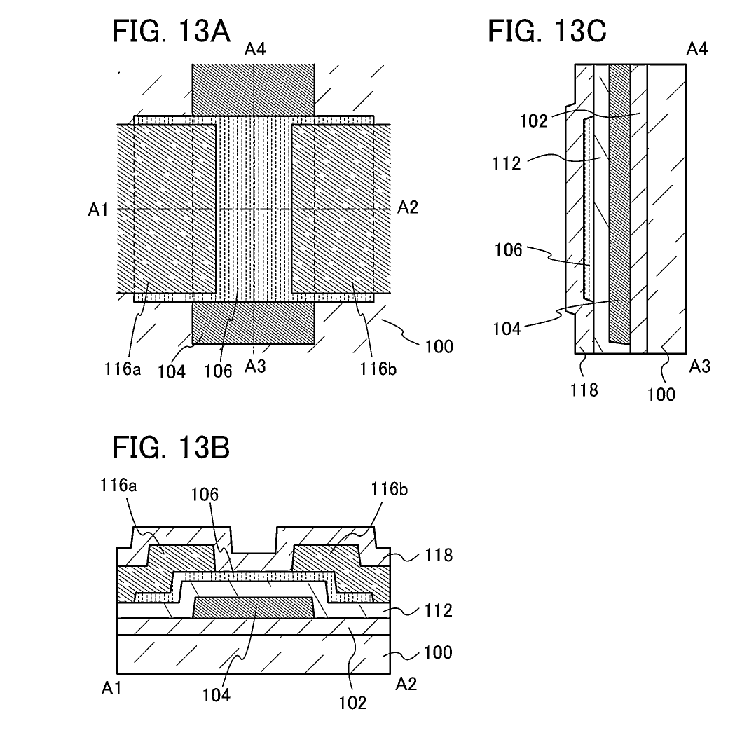

FIG. 13A is a top view of a transistor according to one embodiment of the present invention. FIG. 13B is a cross-sectional view taken along dashed-dotted line A1-A2 in FIG. 13A. FIG. 13C is a cross-sectional view along dashed-dotted line A3-A4 in FIG. 13A. Note that a gate insulating film 112 and the like are not illustrated in FIG. 13A for easy understanding.

FIG. 13B is a cross-sectional view of a transistor including a base insulating film 102 over a substrate 100, a gate electrode 104 over the base insulating film 102, a gate insulating film 112 over the gate electrode 104, an oxide semiconductor film 106 which is over the gate insulating film 112 and overlaps with the gate electrode 104, a source electrode 116a and a drain electrode 116b which are over the oxide semiconductor film 106, and a protective insulating film 118 over the oxide semiconductor film 106, the source electrode 116a, and the drain electrode 116b. Note that FIG. 13B illustrates a structure including the base insulating film 102; however, one embodiment of the present invention is not limited thereto. For example, a structure without the base insulating film 102 may be employed.

Here, the oxide semiconductor film with a high degree of crystallinity which is described in the above embodiment is used as the oxide semiconductor film 106.

The hydrogen concentration in the oxide semiconductor film 106 is set to be lower than or equal to 2×10²⁰ atoms/cm³, preferably lower than or equal to 5×10¹⁹ atoms/cm³, further preferably lower than or equal to 1×10¹⁹ atoms/cm³, sill further preferably, 5×10¹⁸ atoms/cm³. This is because hydrogen included in the oxide semiconductor film 106 sometimes causes generation of unintentional carriers. The generated carriers might be a cause of an increase in the off-state current of the transistor and change in the electrical characteristics of the transistor. Thus, when the hydrogen concentration in the oxide semiconductor film 106 is in the above range, an increase in the off-state current of the transistor and a change in the electric characteristics of the transistor can be suppressed.

By a significant reduction in the concentration of a donor (e.g., hydrogen or an oxygen vacancy) in the oxide semiconductor film 106, the transistor including the oxide semiconductor film 106 can have an extremely low off-state current. Specifically, the off-state current of a transistor with a channel length of 3 μm and a channel width of 1 μm can be lower than or equal to 1×10⁻²¹ A or lower than or equal to 1×10⁻²⁵ A.

There is no particular limitation on the substrate 100. For example, a glass substrate, a ceramic substrate, a quartz substrate, or a sapphire substrate may be used as the substrate 100. Alternatively, a single crystal semiconductor substrate or a polycrystalline semiconductor substrate made of silicon, silicon carbide, or the like, a compound semiconductor substrate made of silicon germanium or the like, a silicon-on-insulator (SOI) substrate, or the like may be used as the substrate 100. Still alternatively, any of these substrates further provided with a semiconductor element may be used as the substrate 100.

In the case where a large glass substrate such as the 5th generation (1000 mm×1200 mm or 1300 mm×1500 mm), the 6th generation (1500 mm×1800 mm), the 7th generation (1870 mm×2200 mm), the 8th generation (2200 mm×2500 mm), the 9th generation (2400 mm×2800 mm), or the 10th generation (2880 mm×3130 mm) is used as the substrate 100, minute processing is sometimes difficult due to shrinkage of the substrate 100 caused by heat treatment or the like in a manufacturing process of a semiconductor device. Therefore, in the case where the above-described large glass substrate is used as the substrate 100, a substrate which is unlikely to shrink through the heat treatment is preferably used. For example, as the substrate 100, it is possible to use a large glass substrate in which the amount of shrinkage after heat treatment which is performed for an hour at 400° C., preferably 450° C., further preferably 500° C. is less than or equal to 10 ppm, preferably less than or equal to 5 ppm, further preferably less than or equal to 3 ppm.

Further alternatively, a flexible substrate may be used as the substrate 100. Note that as a method for forming a transistor over a flexible substrate, there is also a method in which, after a transistor is formed over a non-flexible substrate, the transistor is separated from the non-flexible substrate and transferred to the substrate 100 which is a flexible substrate. In that case, a separation layer is preferably provided between the non-flexible substrate and the transistor.

The base insulating film 102 may be formed of a single layer or a stacked layer using an insulating film containing one or more of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide.

The gate electrode 104 may be formed of a single layer or a stacked layer of a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

The source electrode 116a and the drain electrode 116b may be formed of a single layer or a stacked layer of a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances. Note that the source electrode 116a and the drain electrode 116b may have the same composition or different compositions.

The gate insulating film 112 may be formed of a single layer or a stacked layer using an insulating film containing one or more of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide.

The protective insulating film 118 may be formed of a single layer or a stacked layer using an insulating film containing one or more of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide.

The protective insulating film 118 may be a stacked film including a silicon oxide film and a silicon nitride film. In this case, a silicon oxynitride film may be used instead of the silicon oxide film. As the silicon oxide film, a silicon oxide film with a low defect density is preferably used. Specifically, a silicon oxide film which has a spin density of 3×10¹⁷ spins/cm³ or less, preferably 5×10¹⁶ spins/cm³ or less corresponding to a signal at a g-factor of 2.001 in electron spin resonance (ESR) spectroscopy is used. As the silicon nitride film, a silicon nitride film from which hydrogen and ammonia are less released is used. The amount of released hydrogen and ammonia is preferably measured by thermal desorption spectroscopy (TDS) analysis. Further, a silicon nitride film which oxygen does not penetrates or hardly penetrate is used.

The protective insulating film 118 may be a stacked film including a first silicon oxide film as a first layer, a second silicon oxide film as a second layer, and a silicon nitride film as a third layer. In this case, instead of the first silicon oxide film and/or the second silicon oxide film, a silicon oxynitride film may be used. The first silicon oxide film is preferably a silicon oxide film with a low defect density. Specifically, a silicon oxide film which has a spin density of 3×10¹⁷ spins/cm³ or less, preferably 5×10¹⁶ spins/cm³ or less corresponding to a signal at a g-factor of 2.001 in ESR is used. As the second oxide film, a silicon oxide film containing excess oxygen is used. As the silicon nitride film, a silicon nitride film from which hydrogen and ammonia are less released is used. Further, a silicon nitride film which oxygen does not penetrate or hardly penetrates is used.

The silicon oxide film containing excess oxygen indicates a silicon oxide film from which oxygen can be released by heat treatment or the like. When the silicon oxide film is applied broadly to an insulating film, the thus obtained insulating film containing excess oxygen is an insulating film having a function of releasing oxygen by heat treatment.

A film from which oxygen is released by heat treatment may release oxygen, the amount of which is greater than or equal to 1×10¹⁸ atoms/cm³, greater than or equal to 1×10¹⁹ atoms/cm³, or greater than or equal to 1×10²⁰ atoms/cm³ in TDS analysis (converted into the number of oxygen atoms).

Here, a method of measuring the amount of released oxygen using TDS analysis is described.

The total amount of released gas from a measurement sample in TDS is proportional to the integral value of the ion intensity of the released gas. Then, a comparison with a reference sample is made, whereby the total amount of released gas can be calculated.

For example, the number of released oxygen molecules (N_{O2}) from a measurement sample can be calculated according to Formula (1) using the TDS results of a silicon wafer containing hydrogen at a predetermined density, which is the reference sample, and the TDS results of the measurement sample. Here, all gases having a mass number of 32 which are obtained in the TDS analysis are assumed to originate from an oxygen molecule. CH₃OH, which is given as a gas having a mass number of 32, is not taken into consideration on the assumption that it is unlikely to be present. Further, an oxygen molecule including an oxygen atom having a mass number of 17 or 18 which is an isotope of an oxygen atom is also not taken into consideration because the proportion of such a molecule in the natural world is minimal.

$${N}_{O 2} - \frac{{N}_{H 2}}{{S}_{H 2}} \times {S}_{O 2} \times α \qquad [ FORMULA 1 ]$$

N_{H2} is the value obtained by conversion of the number of hydrogen molecules desorbed from the standard sample into densities. S_{H2} is the integral value of ion intensity when the standard sample is subjected to TDS analysis. Here, the reference value of the standard sample is set to N_{H2}/S_{H2}. S_{O2} is the integral value of ion intensity when the measurement sample is analyzed by TDS. α is a coefficient affecting the ion intensity in the TDS analysis. Refer to Japanese Published Patent Application No. H6-275697 for details of Formula 1. Note that the amount of released oxygen is measured with a thermal desorption spectroscopy apparatus produced by ESCO Ltd., EMD-WA1000S/W using a silicon wafer containing hydrogen atoms at 1×10¹⁶ atoms/cm² as the standard sample.

Further, in the TDS analysis, oxygen is partly detected as an oxygen atom. The ratio between oxygen molecules and oxygen atoms can be calculated from the ionization rate of the oxygen molecules. Note that, since the above α includes the ionization rate of the oxygen molecules, the number of the released oxygen atoms can also be estimated through the examination of the number of the released oxygen molecules.

Note that N_{O2} is the number of the released oxygen molecules. The amount of released oxygen when converted into oxygen atoms is twice the number of the released oxygen molecules.

Further, the film from which oxygen is released by heat treatment may contain a peroxide radical. Specifically, the spin density attributed to a peroxide radical is higher than or equal to 5×10¹⁷ spins/cm³. Note that the film containing a peroxide radical may have an asymmetric signal at a g-factor of around 2.01 generated in ESR.

The insulating film containing excess oxygen may be formed using oxygen-excess silicon oxygen (SiO_{X} (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

At least one of the gate insulating film 112 and the protective insulating film 118 is preferably an insulating film containing excess oxygen.

In the case where at least one of the gate insulating film 112 and the protective insulating film 118 contains excess oxygen, oxygen vacancies in the oxide semiconductor film 106 can be reduced.

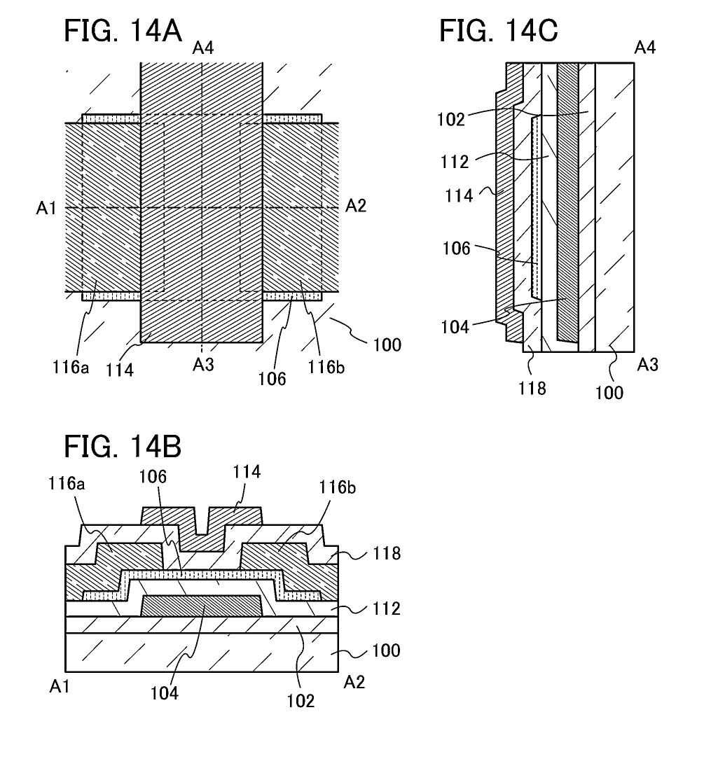

A transistor illustrated in FIGS. 14A to 14C is obtained by additionally providing a back gate electrode 114 in the transistor illustrated in FIGS. 13A to 13C.

FIG. 14A is a top view of a transistor according to one embodiment of the present invention. FIG. 14B is a cross-sectional view taken along dashed-dotted line A1-A2 in FIG. 14A. FIG. 14C is a cross-sectional view taken along dashed-dotted line A3-A4 in FIG. 14A. Note that a gate insulating film 112 and the like are not illustrated in FIG. 14A for easy understanding.

The threshold voltage of the transistor illustrated in FIGS. 14A to 14C can be controlled easily owing to the back gate electrode 114. Moreover, the on-state current of the transistor can be increased by electrically connecting the back gate electrode 114 to the gate electrode 104. Alternatively, the off-state current of the transistor can be reduced by setting the potential of the back gate electrode 114 to a negative potential (a potential which is lower than that of the source of the transistor) or the source potential.

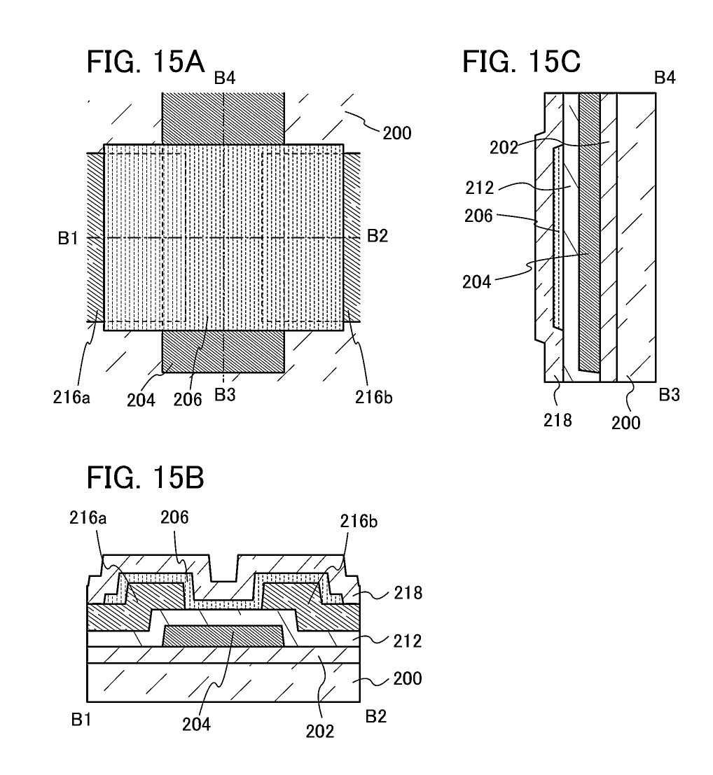

Next, a transistor having a structure different from those in FIGS. 13A to 13C and FIGS. 14A to 14C is described with reference to FIGS. 15A to 15C.

FIG. 15A is a top view of a transistor according to one embodiment of the present invention. FIG. 15B is a cross-sectional view taken along dashed-dotted line B1-B2 in FIG. 15A. FIG. 15C is a cross-sectional view taken along dashed-dotted line B3-B4 in FIG. 15A. Note that a gate insulating film 212 and the like are not illustrated in FIG. 15A for easy understanding.

FIG. 15B is a cross-sectional view of a transistor including a base insulating film 202 over a substrate 200, a gate electrode 204 over the base insulating film 202, the gate insulating film 212 over the gate electrode 204, a source electrode 216a and a drain electrode 216b which are over the gate insulating film 212, an oxide semiconductor film 206 which is over the gate insulating film 212, the source electrode 216a, and the drain electrode 216b and overlaps with the gate electrode 204, and a protective insulating film 218 over the oxide semiconductor film 206, the source electrode 216a, and the drain electrode 216b. Note that FIG. 15B illustrates a structure including the base insulating film 202; however, one embodiment of the present invention is not limited thereto. For example, a structure without the base insulating film 202 may be employed.

The description of the oxide semiconductor film 106 is referred to for the oxide semiconductor film 206.

The description of the substrate 100 is referred to for the substrate 200.

The description of the base insulating film 102 is referred to for the base insulating film 202.

The description of the gate electrode 104 is referred to for the gate electrode 204.

For the gate insulating film 212, an insulating film similar to that for the gate insulating film 112 may be used.

The description of the source electrode 116a and the drain electrode 116b are referred to for the source electrode 216a and the drain electrode 216b.

An insulating film similar to the protective insulating film 118 is used as the protective insulating film 218.

Note that, although not illustrated, a back gate electrode may be provided over the protective insulating film 218 of the transistor illustrated in FIGS. 15A to 15C. The description of the back gate electrode 114 is referred to for the back gate electrode.

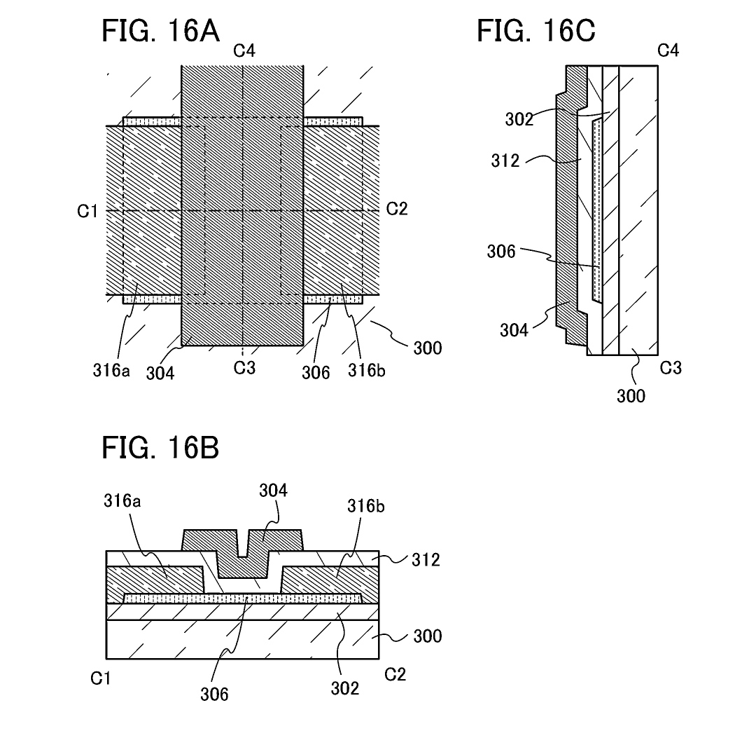

Next, a transistor having a structure different from those in FIGS. 13A to 13C, FIGS. 14A to 14C, and FIGS. 15A to 15C is described with reference to FIGS. 16A to 16C.

FIG. 16A is a top view of the transistor according to one embodiment of the present invention. FIG. 16B is a cross-sectional view taken along dashed-dotted line C1-C2 in FIG. 16A. FIG. 16C is a cross-sectional view taken along dashed-dotted line C3-C4 in FIG. 16A. Note that a gate insulating film 312 and the like are not illustrated in FIG. 16A for easy understanding.

FIG. 16B is a cross-sectional view of a transistor including a base insulating film 302 over a substrate 300, an oxide semiconductor film 306 over the base insulating film 302, a source electrode 316a and a drain electrode 316b which are over the oxide semiconductor film 306, the gate insulating film 312 over the oxide semiconductor film 306, the source electrode 316a, and the drain electrode 316b, and a gate electrode 304 which is over the gate insulating film 312 and overlaps with the oxide semiconductor film 306. Note that FIG. 16B illustrates a structure including the base insulating film 302; however, one embodiment of the present invention is not limited thereto. For example, a structure without the base insulating film 302 may be employed.

The description of the oxide semiconductor film 106 is referred to for the oxide semiconductor film 306.

The description of the substrate 100 is referred to for the substrate 300.

For the base insulating film 302, an insulating film similar to that for the protective insulating film 118 may be used. Note that in the case where the stacked film which is described as an example of the protective insulating film 118 is employed for the base insulating film 302, the order of stacking films may be reversed.

The base insulating film 302 is preferably flat. Specifically, the base insulating film 302 is made to have an average surface roughness (Ra) of 1 nm or less, 0.3 nm or less, or 0.1 nm or less.

Note that Rₐ is obtained by expanding, into three dimensions, the arithmetic mean surface roughness defined by JIS B 0601: 2001 (ISO4287:1997) so that it can be applied to a curved surface, and Rₐ can be expressed as an “average value of the absolute values of deviations from a reference surface to a specific surface” and is defined by Formula 2.

$$Ra = \frac{1}{{S}_{0}} {\int }_{y 1}^{y 2} {\int }_{x 1}^{x 2} \vert f ( x , y ) - {Z}_{0} \vert d x d y \qquad [ Formula 2 ]$$

Here, the specific surface is a surface which is a target of roughness measurement, and is a quadrilateral region which is specified by four points represented by the coordinates (x₁,y₁,f(x₁,y₁)), (x₁,y₂,f(x₁,y₂)), (x₂,y₁,f(x₂,y₁)), and (x₂,y₂,f(x₂,y₂)). S₀ represents the area of a rectangle which is obtained by projecting the specific surface on the x-y plane, and Z₀ represents the height of the reference surface (the average height of the specific surface). Ra can be measured using an atomic force microscope (AFM).

It is preferred that the base insulating film 302 contain excess oxygen.

The description of the source electrode 116a and the drain electrode 116b are referred to for the source electrode 316a and the drain electrode 316b.

For the gate insulating film 312, an insulating film similar to that for the gate insulating film 112 may be used.

The description of the gate electrode 104 is referred to for the gate electrode 304.

Note that, although not illustrated, a back gate electrode may be provided under the base insulating film 302 of the transistor illustrated in FIGS. 16A to 16C. The description of the back gate electrode 114 is referred to for the back gate electrode.

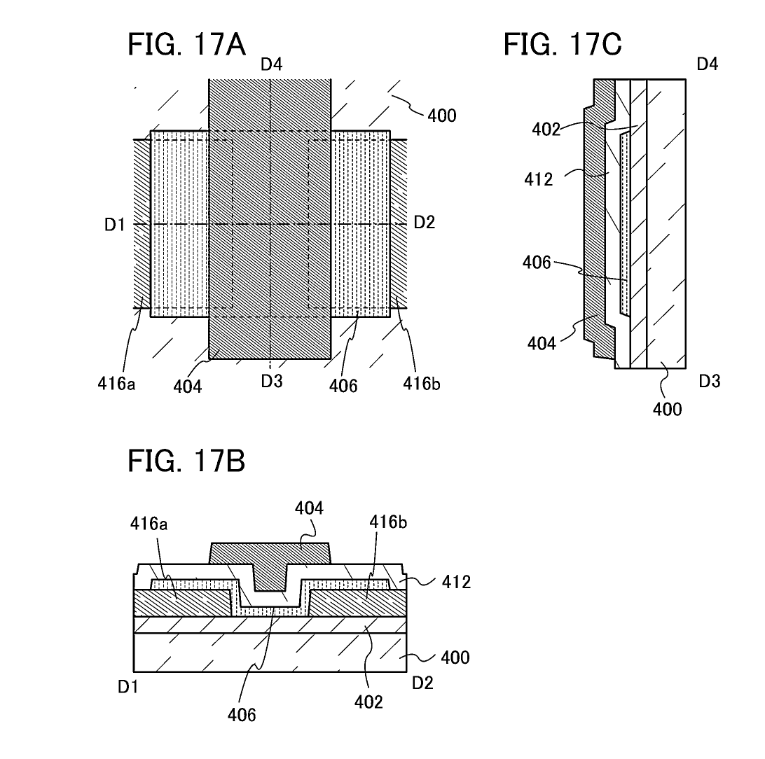

Next, a transistor having a structure different from those of the transistors illustrated in FIGS. 13A to 13C, FIGS. 14A to 14C, FIGS. 15A to 15C, and FIGS. 16A to 16C is described with reference to FIGS. 17A to 17C.

FIG. 17A is a top view of a transistor according to one embodiment of the present invention. FIG. 17B is a cross-sectional view taken along dashed-dotted line D1-D2 in FIG. 17A. FIG. 17C is a cross-sectional view taken along dashed-dotted line D3-D4 in FIG. 17A. Note that a gate insulating film 412 and the like are not illustrated in FIG. 17A for easy understanding.

FIG. 17B is a cross-sectional view of a transistor including a base insulating film 402 over a substrate 400, a source electrode 416a and a drain electrode 416b over the base insulating film 402, an oxide semiconductor film 406 over the base insulating film 402, the source electrode 416a, and the drain electrode 416b, the gate insulating film 412 over the oxide semiconductor film 406, and a gate electrode 404 which is over the gate insulating film 412 and overlaps with the oxide semiconductor film 406. Note that FIG. 17B illustrates a structure including the base insulating film 402; however, one embodiment of the present invention is not limited thereto. For example, a structure without the base insulating film 402 may be employed.

The description of the oxide semiconductor film 106 is referred to for the oxide semiconductor film 406.

The description of the substrate 100 is referred to for the substrate 400.

For the base insulating film 402, an insulating film similar to that for the base insulating film 302 may be used.

The description of the source electrode 116a and the drain electrode 116b are referred to for the source electrode 416a and the drain electrode 416b.

For the gate insulating film 412, an insulating film similar to that for the gate insulating film 112 may be used.

The description of the gate electrode 104 is referred to for the gate electrode 404.

Note that, although not illustrated, a back gate electrode may be provided under the base insulating film 402 of the transistor illustrated in FIGS. 17A to 17C. The description of the back gate electrode 114 is referred to for the back gate electrode.

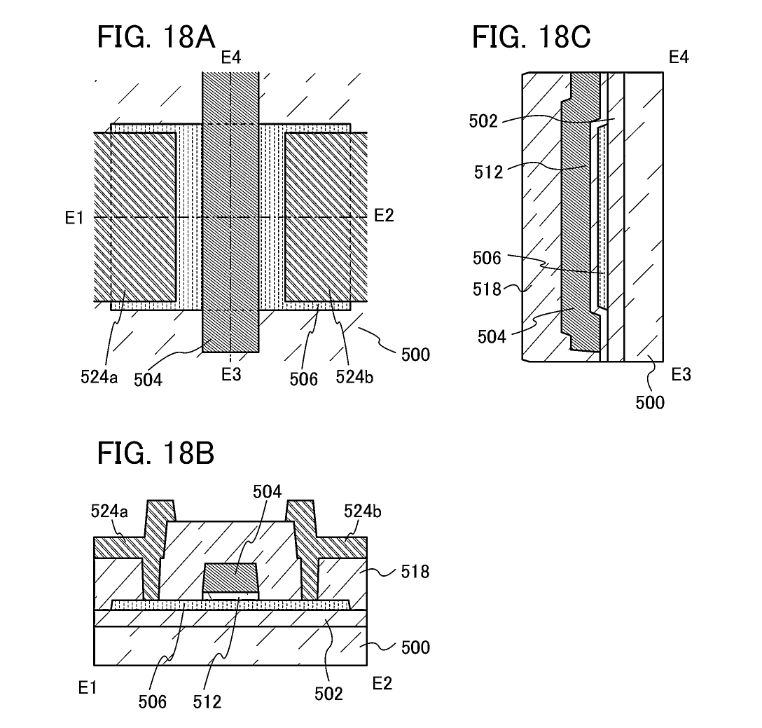

Next, a transistor having a structure different from those of the transistors illustrated in FIGS. 13A to 13C, FIGS. 14A to 14C, FIGS. 15A to 15C, FIGS. 16A to 16C, and FIGS. 17A to 17C is described with reference to FIGS. 18A to 18C.

FIG. 18A is a top view of a transistor according to one embodiment of the present invention. FIG. 18B is a cross-sectional view taken along dashed-dotted line E1-E2 of FIG. 18A. FIG. 18C is a cross-sectional view taken along dashed-dotted line E3-E4 in FIG. 18A. Note that a gate insulating film 512 and the like are not illustrated in FIG. 18A for easy understanding.

FIG. 18B is a cross-sectional view of a transistor including a base insulating film 502 over a substrate 500, an oxide semiconductor film 506 over the base insulating film 502, the gate insulating film 512 over the oxide semiconductor film 506, a gate electrode 504 which is over the gate insulating film 512 and overlaps with the oxide semiconductor film 506, and an interlayer insulating film 518 over the oxide semiconductor film 506 and the gate electrode 504. Note that FIG. 18B illustrates a structure including the base insulating film 502; however, one embodiment of the present invention is not limited thereto. For example, a structure without the base insulating film 502 may be employed.

In the cross-sectional view in FIG. 18B, openings reaching the oxide semiconductor film 506 are formed in the interlayer insulating film 518, and a wiring 524a and a wiring 524b provided over the interlayer insulating film 518 are in contact with the oxide semiconductor film 506 through the openings.

Note that although the gate insulating film 512 is provided only in a region overlapping with the gate electrode 504 in FIG. 18B, one embodiment of the present invention is not limited to this structure. For example, the gate insulating film 512 may be provided so as to cover the oxide semiconductor film 506. Alternatively, a sidewall insulating film may be provided in contact with a side surface of the gate electrode 504.

In the case of providing the sidewall insulating film in contact with the side surface of the gate electrode 504, it is preferred that, in the oxide semiconductor film 506, a region overlapping with the sidewall insulating film have lower resistance than a region overlapping with the gate electrode 504. For example, in the oxide semiconductor film 506, a region not overlapping with the gate electrode 504 may contain an impurity that makes the resistance of the oxide semiconductor film 506 to be reduced. Alternatively, the resistance of the region may be reduced by defects. In the oxide semiconductor film 506, the region overlapping with the sidewall insulating film has lower resistance than the region overlapping with the gate electrode 504; thus, the region serves as a lightly doped drain (LDD) region. With the LDD regions of the transistor, drain induced barrier lowering (DIBL) and hot-carrier degradation can be suppressed. Note that in the oxide semiconductor film 506, the region overlapping with the sidewall insulating film may serve also as an offset region. Also with the offset region of the transistor, DIBL and hot-carrier degradation can be suppressed.

The description of the oxide semiconductor film 106 is referred to for the oxide semiconductor film 506.

The description of the substrate 100 is referred to for the substrate 500.

For the base insulating film 502, an insulating film similar to that for the base insulating film 302 may be used.

An insulating film similar to that for the gate insulating film 112 is used as the gate insulating film 512.

The description of the gate electrode 104 is referred to for the gate electrode 504.

The interlayer insulating film 518 may be formed of a single layer or a stacked layer using an insulating film containing one or more of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide.

The wiring 524a and the wiring 524b can be formed of a single layer or a stacked layer including a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances. Note that the wiring 524a and the wiring 524b may have the same composition or different compositions.

Note that, although not illustrated, a back gate electrode may be provided under the base insulating film 502 of the transistor illustrated in FIGS. 18A to 18C. The description of the back gate electrode 114 is referred to for the back gate electrode.

In the transistor illustrated in FIGS. 18A to 18C, a region where the gate electrode 504 overlaps with another wiring and electrode is small; therefore, parasitic capacitance is unlikely to be generated. Accordingly, the switching characteristics of the transistor can be enhanced. Moreover, the channel length of the transistor is determined by the width of the gate electrode 504; therefore, a miniaturized transistor having a short channel length is manufactured easily.

The transistors illustrated in FIGS. 13A to 13C, FIGS. 14A to 14C, FIGS. 15A to 15C, FIGS. 16A to 16C, FIGS. 17A to 17C, and FIGS. 18A to 18C each include the oxide semiconductor film with a high degree of crystallinity described in the above embodiment. Thus, the transistors have stable electric characteristics.

This embodiment can be used in combination with any of the other embodiments and example, as appropriate.

### Embodiment 5

In this embodiment, a logic circuit which is a semiconductor device according to one embodiment of the present invention is described.

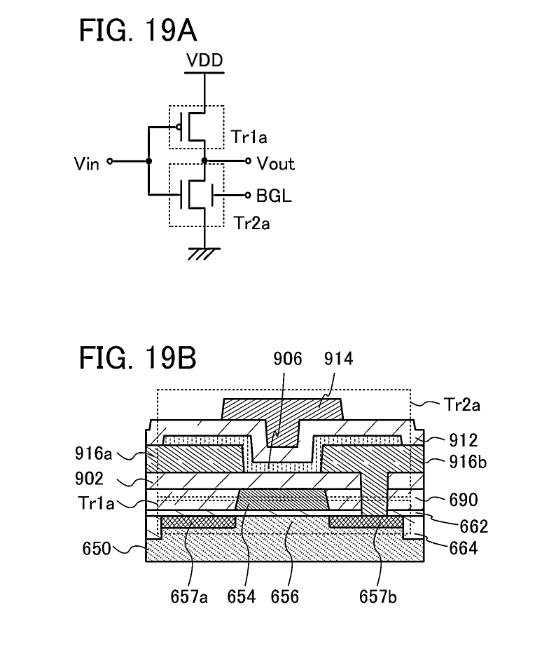

FIG. 19A is a circuit diagram illustrating an example of a NOT circuit (inverter) using a p-channel transistor and an n-channel transistor.

A transistor Tr1a which is a p-channel transistor may be, for example, a transistor using silicon. Note that the transistor Tr1a is not limited to a transistor using silicon. The threshold voltage of the transistor Tr1a is denoted by Vth1a.

A transistor Tr2a which is an n-channel transistor may be, for example, the transistor described in the above embodiment. The threshold voltage of the transistor Tr2a is denoted by Vth2a.

Here, a gate of the transistor Tr1a is connected to an input terminal Vin and a gate of the transistor Tr2a. A source of the transistor Tr1a is electrically connected to a power supply potential (VDD). A drain of the transistor Tr1a is connected to a drain of the transistor Tr2a and an output terminal Vout. A source of the transistor Tr2a is connected to a ground potential (GND). A back gate of the transistor Tr2a is connected to a back-gate line BGL. In this embodiment, the transistor Tr2a has a back gate; however, one embodiment of the present invention is not limited thereto. For example, it is also possible to employ a structure in which the transistor Tr2a does not have a back gate or a structure in which the transistor Tr1a has a back gate.

For example, the threshold voltage Vth1a of the transistor Tr1a is higher than VDD with an inverted polarity and lower than 0 V (−VDD<Vth1a<0 V). Further, the threshold voltage Vth2a of the transistor Tr2a is higher than 0 V and lower than VDD (0 V<Vth2a<VDD). Note that a back gate may be used for control of the threshold voltage of each transistor.

Here, when the potential of the input terminal Vin is VDD, the gate voltage of the transistor Tr1a becomes 0 V so that the transistor Tr1a is turned off. Further, the gate voltage of the transistor Tr2a becomes VDD so that the transistor Tr2a is turned on. Accordingly, the output terminal Vout is electrically connected to GND and supplied with GND.

When the potential of the input terminal Vin is GND, the gate voltage of the transistor Tr1a becomes VDD so that the transistor Tr1a is turned on. Further, the gate voltage of the transistor Tr2a becomes 0 V so that the transistor Tr2a is turned off. Accordingly, the output terminal Vout is electrically connected to VDD and supplied with VDD.

As described above, in the circuit diagram of FIG. 19A, when the potential of the input terminal Vin is VDD, GND is output from the output terminal Vout, and when the potential of the input terminal Vin is GND, VDD is output from the output terminal Vout.

FIG. 19B is an example of a cross-sectional view of a semiconductor device corresponding to FIG. 19A.

FIG. 19B is a cross-sectional view of the semiconductor device including the transistor Tr1a, an insulating film 902 provided over the transistor Tr1a, and the transistor Tr2a provided over the insulating film 902.

The insulating film 902 may be formed of a single layer or a stacked layer using an insulating film containing one or more of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide.

In FIG. 19B, a transistor similar to the transistor illustrated in FIGS. 17A to 17C is used as the transistor Tr2a. Therefore, for components of the transistor Tr2a which are not particularly described below, refer to the description on FIGS. 17A to 17C.

Here, the transistor Tr1a includes a semiconductor substrate 650, a channel region 656, a source region 657a and a drain region 657b which are provided in the semiconductor substrate 650, an element isolation layer 664 which fills a groove portion provided in the semiconductor substrate 650, a gate insulating film 662 provided over the semiconductor substrate 650, and a gate electrode 654 provided over the channel region 656 with the gate insulating film 662 therebetween.

A single crystal semiconductor substrate or a polycrystalline semiconductor substrate of silicon, silicon carbide, or the like or a compound semiconductor substrate of silicon germanium or the like may be used as the semiconductor substrate 650.

In this embodiment, the transistor Tr1a is provided in a semiconductor substrate; however, one embodiment of the present invention is not limited thereto. For example, a structure in which a substrate having an insulating surface is used instead of the semiconductor substrate and a semiconductor film is provided on the insulating surface may be employed. Here, a glass substrate, a ceramic substrate, a quartz substrate, or a sapphire substrate may be used as the substrate having an insulating surface, for example.

The source region 657a and the drain region 657b include an impurity which imparts p-type conductivity to the semiconductor substrate 650.

The element isolation layer 664 may be formed of a single layer or a stacked layer using an insulating film containing one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

The gate insulating film 662 may be formed of a single layer or a stacked layer using an insulating film containing one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

The gate electrode 654 may be formed of a single layer or a stacked layer of a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

The gate electrode 654 functions not only as the gate electrode of the transistor Tr1a, but also as the gate electrode of the transistor Tr2a. Accordingly, the insulating film 902 functions as the gate insulating film of the transistor Tr2a.

The description of the source electrode 416a and the drain electrode 416b is referred to for a source electrode 916a and a drain electrode 916b of the transistor Tr2a.

The description of the oxide semiconductor film 406 is referred to for an oxide semiconductor film 906 of the transistor Tr2a.

The description of the gate insulating film 412 is referred to for a gate insulating film 912 of the transistor Tr2a.

The description of the gate electrode 404 is referred to for a gate electrode 914 of the transistor Tr2a. Note that the gate electrode 914 functions as a back gate electrode of the transistor Tr2a.

In the semiconductor device illustrated in FIG. 19B, an insulating film 690 whose top surface is aligned with the top surface of the gate electrode 654 is provided. Note that a structure without the insulating film 690 may be employed.

The insulating film 690 may be formed of a single layer or a stacked layer using an insulating film containing one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

An opening reaching the drain region 657b of the transistor Tr1a is provided in the insulating film 690, the insulating film 902, and the gate insulating film 662. The drain electrode 916b of the transistor Tr2a is in contact with the drain region 657b of the transistor Tr1a through the opening.

By applying the transistor described in the above embodiment to the transistor Tr2a, a direct path current when the transistor Tr2a is off can be significantly reduced because the transistor Tr2a has an extremely low off-state current. Thus, an inverter with low power consumption is achieved.

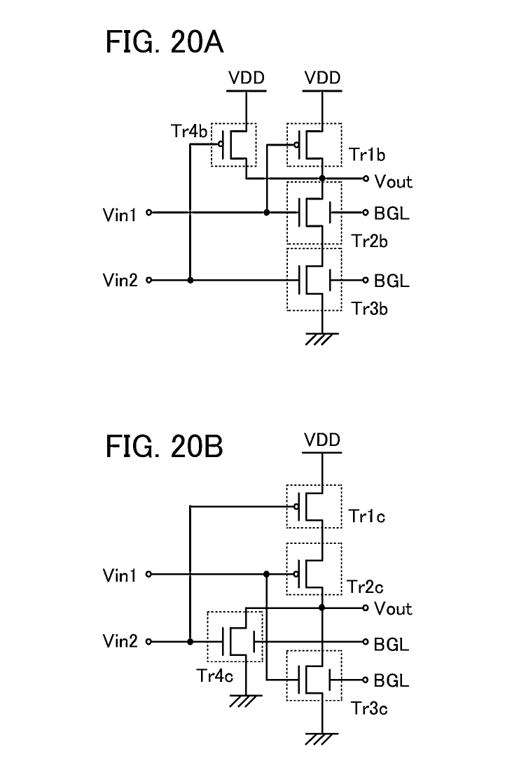

Note that the inverters illustrated in FIG. 19A may be combined to form a NAND circuit illustrated in FIG. 20A. The circuit diagram of FIG. 20A includes a transistor Tr1b and a transistor Tr4b which are p-channel transistors, and a transistor Tr2b and a transistor Tr3b which are n-channel transistors. The transistors Tr1b and Tr4b may each be, for example, a transistor using silicon. The transistors Tr2b and Tr3b may each be the transistor including an oxide semiconductor film described in the above embodiment.

The inverter illustrated in FIG. 19A may be combined to form a NOR circuit illustrated in FIG. 20B. The circuit diagram of FIG. 20B includes a transistor Tr1c and a transistor Tr2c which are p-channel transistors, and a transistor Tr3c and a transistor Tr4c which are n-channel transistors. The transistors Tr1c and Tr2c may each be, for example, a transistor using silicon. The transistors Tr3c and Tr4c may each be the transistor including an oxide semiconductor film described in the above embodiment.

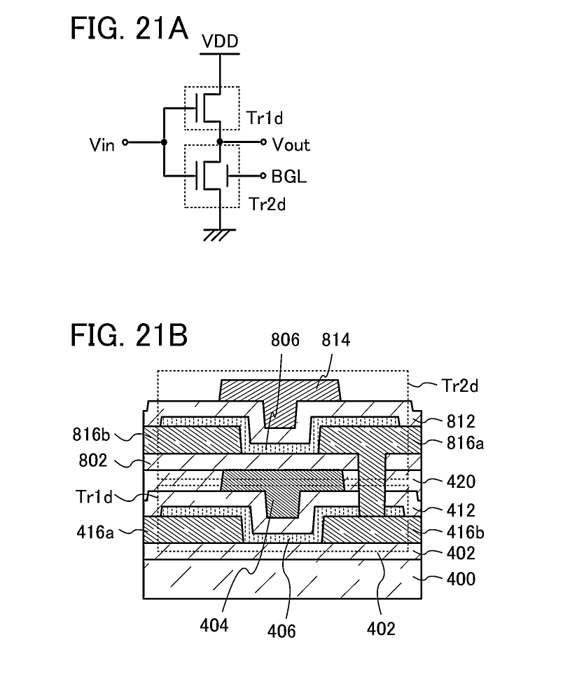

The aforementioned examples of logic circuits are configured with the inverters using p-channel transistors and n-channel transistors; a logic circuit may be configured with an inverter using only n-channel transistors. An example thereof is illustrated in FIG. 21A.

The circuit diagram of FIG. 21A includes a transistor Tr1d which is a depletion transistor and a transistor Tr2d which is an enhancement transistor.

The depletion transistor Tr1d may be, for example, a transistor using an oxide semiconductor film. However, the transistor Tr1d is not limited to the transistor using an oxide semiconductor film. For example, a transistor using silicon may be used. The threshold voltage of the transistor Tr1d is denoted by Vth1d. A resistor with a sufficiently low resistance may be provided instead of the depletion transistor.

The enhancement transistor Tr2d may be, for example, the transistor including an oxide semiconductor film described in the above embodiment. The threshold voltage of the transistor Tr2d is denoted by Vth2d.

Note that the transistor including an oxide semiconductor film described in the above embodiment may be used as the transistor Tr1d. In that case, a transistor other than the transistor including an oxide semiconductor film described in the above embodiment may be used as the transistor Tr2d.

Here, a gate of the transistor Tr1d is connected to an input terminal Vin and a gate of the transistor Tr2d. A drain of the transistor Tr1d is electrically connected to VDD. A source of the transistor Tr1d is connected to a drain of the transistor Tr2d and an output terminal Vout. A source of the transistor Tr2d is connected to GND. A back gate of the transistor Tr2d is connected to a back-gate line BGL. In this embodiment, the transistor Tr2d has a back gate; however, one embodiment of the present invention is not limited thereto. For example, it is also possible to employ a structure in which the transistor Tr2d does not have a back gate or a structure in which the transistor Tr1d has a back gate.

The threshold voltage Vth1d of the transistor Tr1d is, for example, lower than 0 V (Vth1d<0 V). Thus, the transistor Trd1 is in an on state without depending on the gate voltage, which means that the transistor Tr1d functions as a resistor with a sufficiently low resistance. Further, the threshold voltage Vth2d of the transistor Tr2d is higher than 0 V and lower than VDD (0 V<Vth2d<VDD). Note that a back gate may be used for control of the threshold voltage of each transistor. Further, a resistor having a sufficiently low resistance may be provided instead of the transistor Tr1d.

Here, when the potential of the input terminal Vin is VDD, the gate voltage of the transistor Tr2d becomes VDD so that the transistor Tr2d is turned on. Accordingly, the output terminal Vout is electrically connected to GND and supplied with GND.

Further, when the potential of the input terminal Vin is GND, the gate voltage of the transistor Tr2d becomes 0 V so that the transistor Tr2d is turned off. Accordingly, the output terminal Vout is electrically connected to VDD and supplied with VDD. Note that strictly, the potential output from the output terminal Vout is equal to a potential dropped from VDD by the resistance of the transistor Tr1d. However, the effect of the voltage drop can be ignored because the resistance of the transistor Tr1d is sufficiently low.

As described above, in the circuit diagram of FIG. 21A, when the potential of the input terminal Vin is VDD, GND is output from the output terminal Vout, and when the potential of the input terminal Vin is GND, VDD is output from the output terminal Vout.

Note that the transistor Tr1d and the transistor Tr2d may be formed in the same plane. At this time, a back gate is preferably provided in at least one of the transistors Tr1d and Tr2d. In the case where the formed transistors are depletion transistors, the threshold voltage Vth2d may be set within the above range with the back gate of the transistor Tr2d. In the case where the formed transistors are enhancement transistors, the threshold voltage Vth1d may be set within the above range with the back gate of the transistor Tr1d. Note that the threshold voltages of the transistors Tr1d and Tr2d may be controlled with different back gates.

Alternatively, the transistor Tr1d and the transistor Tr2d may be overlapped with each other, in which case the inverter can be reduced in area.

FIG. 21B is an example of a cross-sectional view of a semiconductor device in which the transistor Tr1d and the transistor Tr2d are overlapped with each other.

The description of the transistor illustrated in FIGS. 17A to 17C is referred to for the transistor Tr1d in FIG. 21B. Further, a transistor similar to the transistor illustrated in FIGS. 17A to 17C is used as the transistor Tr2d. Therefore, for components of the transistor Tr2d which are not particularly described below, refer to the description on FIGS. 17A to 17C.

Note that the transistor Tr1d includes the base insulating film 402 over the substrate 400, the source electrode 416a and the drain electrode 416b over the base insulating film 402, the oxide semiconductor film 406 over the base insulating film 402, the source electrode 416a, and the drain electrode 416b, the gate insulating film 412 over the oxide semiconductor film 406, and the gate electrode 404 which is over the gate insulating film 412 and overlaps with the oxide semiconductor film 406.

The gate electrode 404 functions not only as the gate electrode of the transistor Tr1d, but also as the gate electrode of the transistor Tr2d. Accordingly, the insulating film 802 functions as the gate insulating film of the transistor Tr2d.

The description of the source electrode 416a and the drain electrode 416b is referred to for a source electrode 816a and a drain electrode 816b of the transistor Tr2d.

The description of the oxide semiconductor film 406 is referred to for an oxide semiconductor film 806 of the transistor Tr2d.

The description of the gate insulating film 412 is referred to for a gate insulating film 812 of the transistor Tr2d.

The description of the gate electrode 404 is referred to for a gate electrode 814 of the transistor Tr2d. Note that the gate electrode 814 functions as a back gate electrode of the transistor Tr2d.

In the semiconductor device illustrated in FIG. 21B, an insulating film 420 whose top surface is aligned with the top surface of the gate electrode 404 is provided. Note that a structure without the insulating film 420 may be employed.

The insulating film 420 may be formed of a single layer or a stacked layer using an insulating film containing one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

An opening reaching the drain electrode 416b of the transistor Tr1d is provided in the insulating film 420, the insulating film 802, the gate insulating film 412, and the oxide semiconductor film 406. The source electrode 816a of the transistor Tr2d is in contact with the drain electrode 416b of the transistor Tr1d through the opening.

By applying the transistor described in the above embodiment to the transistor Tr2d, a direct path current when the transistor Tr2d is off can be significantly reduced because the transistor Tr2d has an extremely low off-state current. Thus, an inverter with low power consumption is achieved.

This embodiment can be implemented in appropriate combination with any of the other embodiments and example.

### Embodiment 6

In this embodiment, a static random access memory (SRAM) which is a semiconductor device including a flip-flop obtained by applying the inverter circuit shown in Embodiment 5 will be described.

In the SRAM, data is retained using a flip-flop; therefore, unlike in a dynamic random access memory (DRAM), refresh operation is not necessary so that data can be retained with less power. In addition, the SRAM does not use a capacitor and thus is suitable for application requiring high-speed operation.

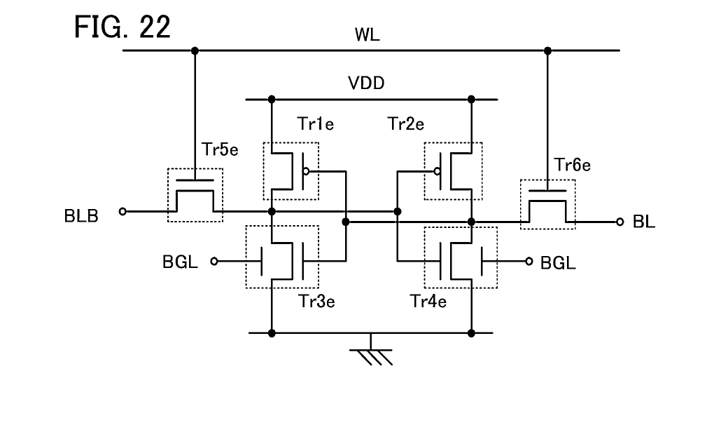

FIG. 22 is a circuit diagram equivalent to a memory cell of an SRAM of one embodiment of the present invention. Although only one memory cell is illustrated in FIG. 22, one embodiment of the present invention may be applied to a memory cell array including a plurality of the memory cells.

The memory cell illustrated in FIG. 22 includes a transistor Tr1e, a transistor Tr2e, a transistor Tr3e, a transistor Tr4e, a transistor Tr5e, and a transistor Tr6e. The transistors Tr1e and Tr2e are p-channel transistors, and the transistors Tr3e and Tr4e are n-channel transistors. A gate of the transistor Tr1e is electrically connected to a drain of the transistor Tr2e, a gate of the transistor Tr3e, a drain of the transistor Tr4e, and one of a source and a drain of the transistor Tr6e. A source of the transistor Tr1e is electrically connected to VDD. A drain of the transistor Tr1e is electrically connected to a gate of the transistor Tr2e, a gate of the transistor Tr4e, a drain of the transistor Tr3e, and one of a source and a drain of the transistor Tr5e. A source of the transistor Tr2e is electrically connected to VDD. A source of the transistor Tr3e is electrically connected to GND. A back gate of the transistor Tr3e is electrically connected to a back gate line BGL. A source of the transistor Tr4e is electrically connected to GND. A back gate of the transistor Tr4e is electrically connected to a back gate line BGL. A gate of the transistor Tr5e is electrically connected to the word line WL. The other of the source and the drain of the transistor Tr5e is electrically connected to a bit line BLB. A gate of the transistor Tr6e is electrically connected to the word line WL. The other of the source and the drain of the transistor Tr6e is electrically connected to a bit line BL.

Note that this embodiment shows an example where n-channel transistors are used as the transistors Tr5e and Tr6e. However, the transistors Tr5e and Tr6e are not limited to n-channel transistors and may be p-channel transistors. In that case, writing, retaining, and reading methods described below may be changed as appropriate.

A flip-flop is thus configured in such a manner that an inverter including the transistors Tr1e and Tr3e and an inverter including the transistors Tr2e and Tr4e are connected in a ring.

The p-channel transistors may each be a transistor using silicon may be used, for example. However, the p-channel transistor is not limited to a transistor using silicon. The n-channel transistors may each be the transistor including an oxide semiconductor film described in the above embodiment.

In this embodiment, the transistors Tr3e and Tr4e may each be the transistor including an oxide semiconductor film described in the above embodiment. In addition, with an extremely low off-state current, the transistor has an extremely low direct path current.

Note that instead of the p-channel transistors, n-channel transistors may be applied to the transistors Tr1e and Tr2e. In the case where n-channel transistors are used as the transistors Tr1e and Tr2e, depletion transistors may be employed as described with reference to FIGS. 21A and 21B.

Writing, retaining, and reading operation of the memory cell illustrated in FIG. 22 will be described below.

In writing, first, a potential corresponding to data 0 or data 1 is applied to the bit line BL and the bit line BLB.

For example, in the case where data 1 is to be written, the VDD is applied to the bit line BL and the GND is applied to the bit line BLB. Then, a potential (VH) higher than or equal to the sum of the VDD and the threshold voltage of the transistors Tr5e and Tr6e is applied to the word line WL.

Next, the potential of the word line WL is set to be lower than the threshold voltage of the transistors Tr5e and Tr6e, whereby the data 1 written to the flip-flop is retained. In the case of the SRAM, a current flowing in retaining data is only the leakage current of the transistors. Here, any of the transistors including an oxide semiconductor film described in the above embodiment, which has an extremely low off-state current, is applied to some of the transistors in the SRAM, resulting in a reduction in stand-by power for retaining data because leakage current due to the transistor is extremely low.

In reading, the VDD is applied to the bit line BL and the bit line BLB in advance. Then, the VH is applied to the word line WL, so that the potential of the bit line BLB is discharged through the transistors Tr5e and Tr3e to be equal to the GND while the potential of the bit line BL is kept at VDD. The potential difference between the bit line BL and the bit line BLB is amplified by a sense amplifier (not illustrated), whereby the retained data 1 can be read.

In the case where data 0 is to be written, the GND is applied to the bit line BL and the VDD is applied to the bit line BLB; then, the VH is applied to the word line WL. Next, the potential of the word line WL is set to be lower than the threshold voltage of the transistors Tr5e and Tr6e, whereby the data 0 written to the flip-flop is retained. In reading, the VDD is applied to the bit line BL and the bit line BLB in advance. Then, the VH is applied to the word line WL, so that the potential of the bit line BL is discharged through the transistors Tr6e and Tr4e to be equal to the GND while the potential of the bit line BLB is kept at VDD. The potential difference between the bit line BL and the bit line BLB is amplified by the sense amplifier, whereby the retained data 0 can be read.

According to this embodiment, an SRAM with low stand-by power can be provided.

This embodiment can be implemented in appropriate combination with any of the other embodiments and example.

### Embodiment 7

The transistors each including an oxide semiconductor film described in the above embodiment can have extremely low off-state current. That is, the transistor has electrical characteristics in which leakage of charge through the transistor is unlikely to occur.

A semiconductor device including the transistor having such electrical characteristics and having a memory element which is functionally superior to a known memory element will be described below.

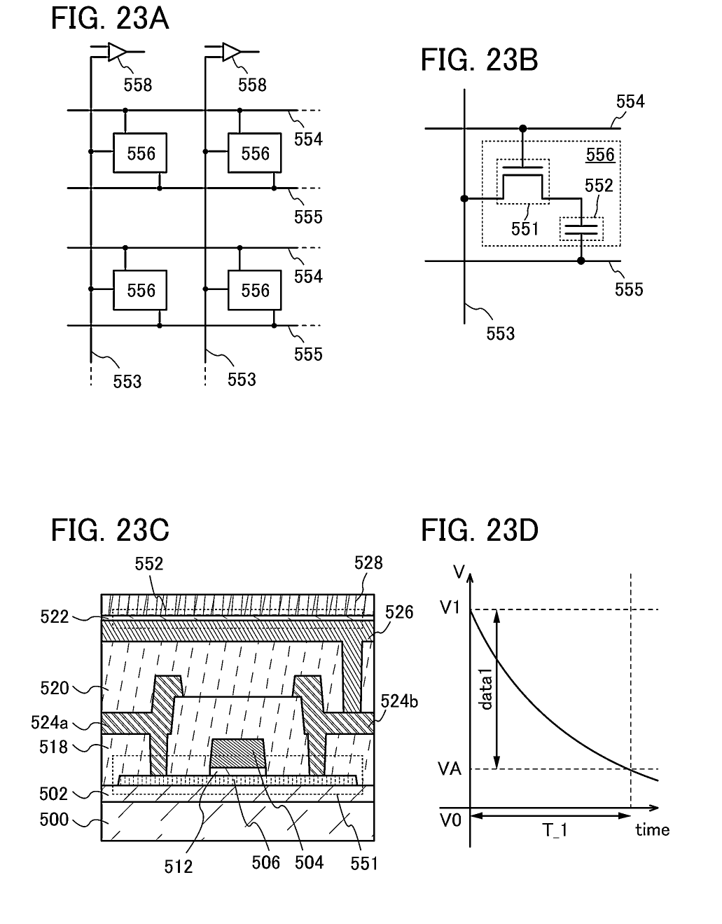

First, the semiconductor device is specifically described with reference to FIGS. 23A to 23D. Note that FIG. 23A is a circuit diagram illustrating a memory cell array in the semiconductor device. FIG. 23B is a circuit diagram of the memory cell. FIG. 23C shows an example of a cross-sectional structure corresponding to the memory cell in FIG. 23B. FIG. 23D is a graph showing electric characteristics of the memory cell in FIG. 23B.

The memory cell array in FIG. 23A includes a plurality of memory cells 556, a plurality of bit lines 553, a plurality of word lines 554, a plurality of capacitor lines 555, and a plurality of sense amplifiers 558.

Note that the bit lines 553 and the word lines 554 are arranged in grid patterns, and each memory cell 556 is provided at an intersection of the bit line 553 and the word line 554. The bit lines 553 are connected to the respective sense amplifiers 558. The sense amplifiers 558 have a function of reading the potentials of the bit lines 553 as data.

It is seen from FIG. 23B that the memory cell 556 includes a transistor 551 and a capacitor 552. A gate of the transistor 551 is electrically connected to the word line 554. A source of the transistor 551 is electrically connected to the bit line 553. A drain of the transistor 551 is electrically connected to one terminal of the capacitor 552. The other termimal of the capacitor 552 is electrically connected to a capacitor line 555.

FIG. 23C illustrates an example of a cross-sectional structure of the memory cell. FIG. 23C is a cross-sectional view of the semiconductor device including the transistor 551, the wirings 524a and 524b connected to the transistor 551, an insulating film 520 over the transistor 551 and the wirings 524a and 524b, and the capacitor 552 over the insulating film 520.

Note that in FIG. 23C, the transistor illustrated in FIGS. 18A to 18C is used as a transistor 551. Therefore, for components of the transistor 551, which are not particularly mentioned below, the description in the above embodiments is referred to.

The description of the interlayer insulating film 518 is referred to for the insulating film 520. Alternatively, a resin film of a polyimide resin, an acrylic resin, an epoxy resin, a silicone resin, or the like may be used as the insulating film 520.

The capacitor 552 includes an electrode 526 in contact with the wiring 524b, an electrode 528 overlapping with the electrode 526, and an insulating film 522 provided between the electrode 526 and the electrode 528.

The electrode 526 may be formed of a single layer or a stacked layer of a simple substance selected from aluminum, titanium, chromium, cobalt, nickel, copper, yttrium, zirconium, molybdenum, silver, tantalum, and tungsten; a nitride containing one or more kinds of the above substances; an oxide containing one or more kinds of the above substances; or an alloy containing one or more kinds of the above substances.

The electrode 528 may be formed of a single layer or a stacked layer of a simple substance selected from aluminum, titanium, chromium, cobalt, nickel, copper, yttrium, zirconium, molybdenum, silver, tantalum, and tungsten; a nitride containing one or more kinds of the above substances; an oxide containing one or more kinds of the above substances; or an alloy containing one or more kinds of the above substances.

The insulating film 522 may be formed of a single layer or a stacked layer using an insulating film containing one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

Note that although FIG. 23C shows an example where the transistor 551 and the capacitor 552 are provided in different layers, one embodiment of the present invention is not limited to this structure. For example, the transistor 551 and the capacitor 552 may be provided in the same plane. With such a structure, memory cells having similar structures can be disposed so as to overlap with each other, in which case, a large number of memory cells can be integrated in an area for one memory cell. Accordingly, the degree of integration of the semiconductor device can be increased. Note that in this specification, “A overlaps with B” means that A and B are provided such that at least part of A overlaps with at least part of B.

Here, the wiring 524a in FIG. 23C is electrically connected to the bit line 553 in FIG. 23B. The gate electrode 504 in FIG. 23C is electrically connected to the word line 554 in FIG. 23B. Further, the electrode 528 in FIG. 23C is electrically connected to the capacitor line 555 in FIG. 23B.

As shown in FIG. 23D, voltage held in the capacitor 552 is gradually decreased over time due to leakage through the transistor 551. After a certain period of time, the voltage originally charged from V0 to V1 is decreased to VA which is a limit for reading data 1. This period is called a holding period T_1. In the case of a two-level memory cell, refresh needs to be performed within the holding period T_1.

For example, in the case where the amount of off-state current of the transistor 551 is not small enough, a voltage held in the capacitor 552 over time changes significantly; therefore, the holding period T_1 becomes short. Thus, refresh operation needs to be performed frequently. When the frequency of refresh operation is increased, power consumption is increased.

In this embodiment, the amount of off-state current of the transistor 551 is extremely small; therefore, the holding period T_1 can be made extremely long. Further, the frequency of refresh operation can be reduced; thus, power consumption can be reduced. For example, when a memory cell includes the transistor 551 having an off-state current of 1×10⁻²¹ A to 1×10⁻²⁵ A, data can be held for several days to several decades without supply of power.

As described above, according to one embodiment of the present invention, a semiconductor device with high degree of integration and low power consumption can be obtained.

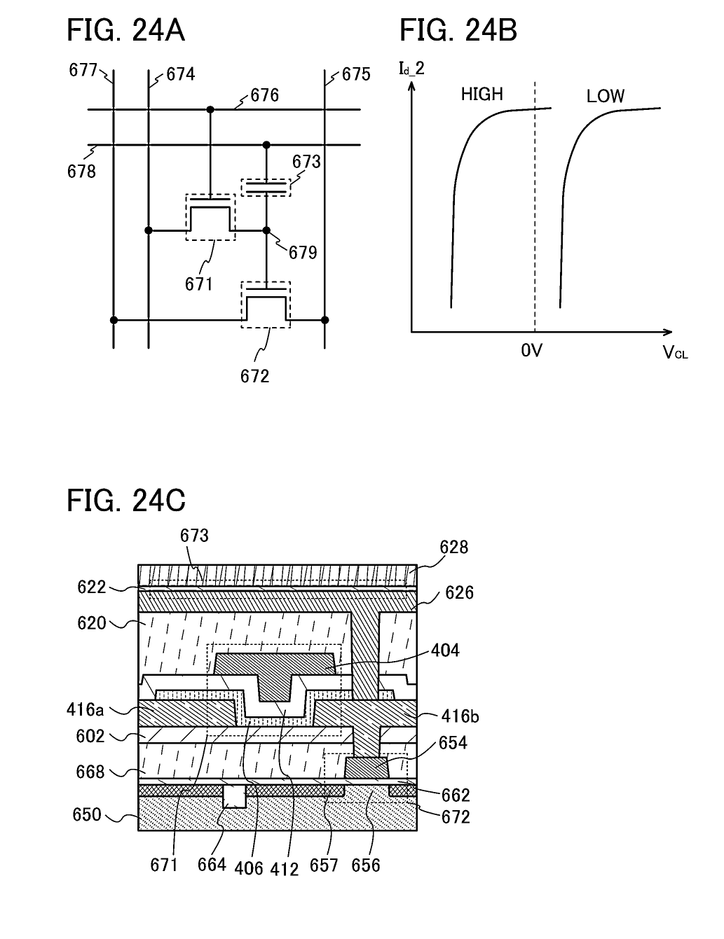

Next, a semiconductor device having a structure different from that of the semiconductor device in FIGS. 23A to 23D is described with reference to FIGS. 24A to 24C. Note that FIG. 24A is a circuit diagram of a memory cell and wirings included in the semiconductor device. FIG. 24B is a graph showing electrical characteristics of the memory cell in FIG. 24A. FIG. 24C is an example of a cross-sectional view corresponding to the memory cell in FIG. 24A.

As shown in FIG. 24A, the memory cell includes a transistor 671, a transistor 672, and a capacitor 673. Here, a gate of the transistor 671 is electrically connected to a word line 676. A source of the transistor 671 is electrically connected to a source line 674. A drain of the transistor 671 is electrically connected to a gate of the transistor 672 and one terminal of the capacitor 673, and this connection portion is referred to as a node 679. A source of the transistor 672 is electrically connected to a source line 675. A drain of the transistor 672 is electrically connected to a drain line 677. The other terminal of the capacitor 673 is electrically connected to a capacitor line 678.

The semiconductor device illustrated in FIGS. 24A to 24C utilizes variation in the apparent threshold voltage of the transistor 672, which depends on the potential of the node 679. For example, FIG. 24B shows a relation between a voltage V_{CL} of the capacitor line 678 and a drain current I_{d}_{_{—}}2 flowing through the transistor 672.

The potential of the node 679 can be controlled through the transistor 671. For example, the potential of the source line 674 is set to a power supply potential VDD. In this case, when the potential of the word line 676 is set to be higher than or equal to a potential obtained by adding the power supply potential VDD to the threshold voltage Vth of the transistor 671, the potential of the node 679 can be HIGH. Further, when the potential of the word line 676 is set to be lower than or equal to the threshold voltage Vth of the transistor 671, the potential of the node 679 can be LOW.

Thus, the electrical characteristics of the transistor 672 is either a V_{CL}-I_{d}_{_{—}}2 curve denoted as LOW or a V_{CL}-I_{d}_{_{—}}2 curve denoted as HIGH. That is, when the potential of the node 679 is LOW, I_{d}_{_{—}}2 is small at a V_{CL} of 0 V; accordingly, data 0 is stored. Further, when the potential of the node 679 is HIGH, I_{d}_{_{—}}2 is large at a V_{CL} of 0 V; accordingly, data 1 is stored. In this manner, data can be stored.

FIG. 24C illustrates an example of a cross-sectional structure of the memory cell. FIG. 24C is a cross-sectional view of the semiconductor device including the transistor 672, an insulating film 668 over the transistor 672, the transistor 671 over the insulating film 668, an insulating film 620 over the transistor 671, and the capacitor 673 over the insulating film 620.

The description of the protective insulating film 118 is referred to for the insulating film 620. Alternatively, a resin film of a polyimide resin, an acrylic resin, an epoxy resin, a silicone resin, or the like may be used as the insulating film 620.

Note that in FIG. 24C, the transistor illustrated in FIGS. 17A to 17C is used as a transistor 671. Therefore, for components of the transistor 671, which are not particularly mentioned below, the description in the above embodiments is referred to.

The transistor including crystalline silicon has an advantage over the transistor including an oxide semiconductor film in that on-state characteristics can be easily improved. Thus, it can be said that the transistor including crystalline silicon is suitable for the transistor 672 for which excellent on-state characteristics are required.

Here, the transistor 672 includes the channel region 656 and impurity regions 657 which are provided in the semiconductor substrate 650, the element isolation layer 664 which fills a groove portion provided in the semiconductor substrate 650, the gate insulating film 662 provided over the semiconductor substrate 650, and the gate electrode 654 provided over the channel region 656 with the gate insulating film 662 provided therebetween.

A single crystal semiconductor substrate or a polycrystalline semiconductor substrate of silicon, silicon carbide, or the like or a compound semiconductor substrate of silicon germanium or the like may be used as the semiconductor substrate 650.

In this embodiment, the transistor 672 is provided in a semiconductor substrate; however, one embodiment of the present invention is not limited thereto. For example, a structure in which a substrate having an insulating surface is used instead of the semiconductor substrate and a semiconductor film is provided on the insulating surface may be employed. Here, a glass substrate, a ceramic substrate, a quartz substrate, or a sapphire substrate may be used as the substrate having an insulating surface, for example. Further, any of the transistors including an oxide semiconductor film described in the above embodiment may be used as the transistor 672.

The impurity regions 657 include an impurity which imparts one conductivity type to the semiconductor substrate 650.

The element isolation layer 664 may be formed of a single layer or a stacked layer using an insulating film containing one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

The gate insulating film 662 may be formed of a single layer or a stacked layer using an insulating film containing one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

The description of the gate electrode 104 is referred to for the gate electrode 654.

The description of the protective insulating film 118 is referred to for the insulating film 668. Alternatively, a resin film of a polyimide resin, an acrylic resin, an epoxy resin, a silicone resin, or the like may be used as the insulating film 668.

The insulating film 668 and the base insulating film 602 include an opening reaching the gate electrode 654 of the transistor 672. The drain electrode 416b of the transistor 671 is in contact with the gate electrode 654 of the transistor 672 through the opening.

The capacitor 673 includes an electrode 626 in contact with the drain electrode 416b, an electrode 628 overlapping with the electrode 626, and an insulating film 622 provided between the electrode 626 and the electrode 628.

The description of the electrode 526 is referred to for the electrode 626.

The description of the electrode 528 is referred to for the electrode 628.

Here, the source electrode 416a in FIG. 24C is electrically connected to the source line 674 in FIG. 24A. The gate electrode 404 in FIG. 24C is electrically connected to the word line 676 in FIG. 24A. Further, the electrode 628 in FIG. 24C is electrically connected to the capacitor line 678 in FIG. 24A.

In the example of FIG. 24C, the transistor 671 and the capacitor 673 are provided in different layers so as to overlap with each other; however, one embodiment of the present invention is not limited to this structure. For example, the transistor 671 and the capacitor 673 may be provided in the same plane. With such a structure, memory cells having similar structures can be disposed so as to overlap with each other, in which case, a large number of memory cells can be integrated in an area for one memory cell. Accordingly, the degree of integration of the semiconductor device can be improved.

Here, with use of the transistor including an oxide semiconductor film in the above embodiment as the transistor 671, a charge accumulated in the node 679 can be prevented from leaking through the transistor 671 because the amount of off-state current of the transistor is extremely small. Therefore, data can be held for a long period. Further, high voltage is not needed in data writing; therefore, power consumption can be made small and operation speed can be made high compared to a flash memory.

As described above, according to one embodiment of the present invention, a semiconductor device with high degree of integration and low power consumption can be obtained.

This embodiment can be implemented in appropriate combination with any of the other embodiments and example.

### Embodiment 8

A central processing unit (CPU) can be formed with use of any of the transistors including an oxide semiconductor film described in the above embodiment or any of the semiconductor devices including a memory element described in the above embodiment for at least part of the CPU.

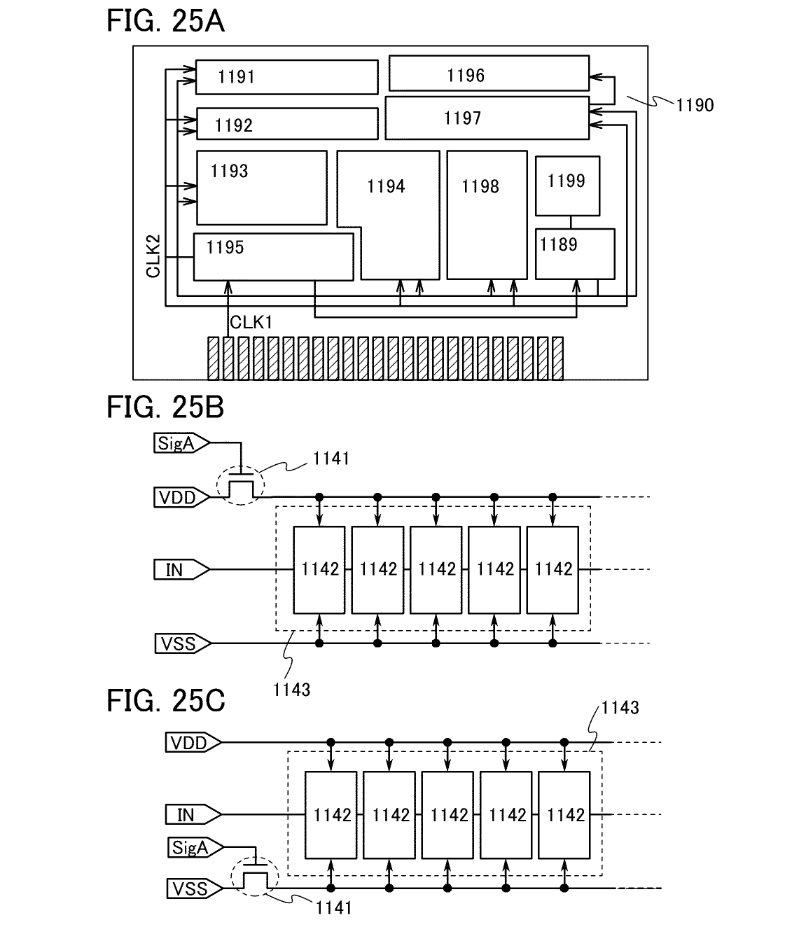

FIG. 25A is a block diagram illustrating a specific structure of a CPU. The CPU illustrated in FIG. 25A includes an arithmetic logic unit (ALU) 1191, an ALU controller 1192, an instruction decoder 1193, an interrupt controller 1194, a timing controller 1195, a register 1196, a register controller 1197, a bus interface (Bus I/F) 1198, a rewritable ROM 1199, and an ROM interface (ROM I/F) 1189 over a substrate 1190. A semiconductor substrate, an SOI substrate, a glass substrate, or the like is used as the substrate 1190. The ROM 1199 and the ROM interface 1189 may be provided over a separate chip. Obviously, the CPU illustrated in FIG. 25A is only an example in which the structure is simplified, and an actual CPU may have various structures depending on the application.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the clock signal CLK2 to the above circuits.

In the CPU illustrated in FIG. 25A, a memory element is provided in the register 1196. For the register 1196, any of the semiconductor devices including a memory element described in the above embodiment can be used.

In the CPU illustrated in FIG. 25A, the register controller 1197 selects operation of retaining data in the register 1196 in accordance with an instruction from the ALU 1191. That is, the register controller 1197 selects whether data is retained by a flip flop or a capacitor in the memory element included in the register 1196. When data is retained by the flip flop, a power supply voltage is supplied to the memory element in the register 1196. When data is retained by the capacitor, the data in the capacitor is rewritten, and supply of the power supply voltage to the memory element in the register 1196 can be stopped.

The power supply can be stopped by providing a switching element between a memory element group and a node to which a power supply potential VDD or a power supply potential VSS is supplied, as illustrated in FIG. 25B or FIG. 25C. Circuits illustrated in FIGS. 25B and 25C will be described below.

FIGS. 25B and 25C each illustrate an example of a structure including any of the transistors including an oxide semiconductor film described in the above embodiment as a switching element for controlling supply of a power supply potential to a memory element.

The memory device illustrated in FIG. 25B includes a switching element 1141 and a memory element group 1143 including a plurality of memory elements 1142. Specifically, as each of the memory elements 1142, any of the semiconductor devices including a memory element described in the above embodiment can be used. Each of the memory elements 1142 included in the memory element group 1143 is supplied with the high-level power supply potential VDD through the switching element 1141. Further, each of the memory elements 1142 included in the memory element group 1143 is supplied with a potential of a signal IN and a potential of the low-level power supply potential VSS.

In FIG. 25B, as the switching element 1141, any of the transistors including an oxide semiconductor film described in the above embodiment is used. The transistors can have extremely low off-state current. The switching of the transistor is controlled by a signal SigA input to the gate thereof.

Note that FIG. 25B illustrates the structure in which the switching element 1141 includes only one transistor; however, one embodiment of the present invention is not limited thereto, and the switching element 1141 may include a plurality of transistors. In the case where the switching element 1141 includes a plurality of transistors which serves as switching elements, the plurality of transistors may be connected to each other in parallel, in series, or in combination of parallel connection and series connection.

In FIG. 25C, an example of a memory device in which each of the memory elements 1142 included in the memory element group 1143 is supplied with the low-level power supply potential VSS through the switching element 1141 is illustrated. The supply of the low-level power supply potential VSS to each of the memory elements 1142 included in the memory element group 1143 can be controlled by the switching element 1141.

When a switching element is provided between a memory element group and a node to which the power supply potential VDD or the power supply potential VSS is supplied, data can be held even in the case where an operation of a CPU is temporarily stopped and the supply of the power supply voltage is stopped; accordingly, power consumption can be reduced. Specifically, for example, while a user of a personal computer does not input data to an input device such as a keyboard, the operation of the CPU can be stopped, so that the power consumption can be reduced.

Although the CPU is given as an example, the transistor can also be applied to an LSI such as a digital signal processor (DSP), a custom LSI, or a field programmable gate array (FPGA).

This embodiment can be implemented in appropriate combination with any of the other embodiments and example.

### Embodiment 9

In this embodiment, a display device to which any of the transistors described in the above embodiments is applied will be described.

As a display element provided in the display device, a liquid crystal element (also referred to as a liquid crystal display element), a light-emitting element (also referred to as a light-emitting display element) or the like can be used. A light-emitting element includes, in its category, an element whose luminance is controlled by current or voltage, and specifically an inorganic electroluminescent (EL) element, an organic EL element, and the like. Furthermore, a display medium whose contrast is changed by an electric effect, such as electronic ink, can be used as the display element. In this embodiment, a display device including an EL element and a display device including a liquid crystal element will be described as examples of the display device.

Note that the display device of the present embodiment includes in its category a panel in which a display element is sealed, and a module in which an IC such as a controller or the like is mounted on the panel.

Additionally, the display device in this embodiment refers to an image display device, a display device, or a light source (including a lighting device). The display device includes any of the following modules in its category: a module provided with a connector such as an FPC or TCP; a module in which a printed wiring board is provided at the end of TCP; and a module in which an integrated circuit (IC) is mounted directly on a display element by a COG method.

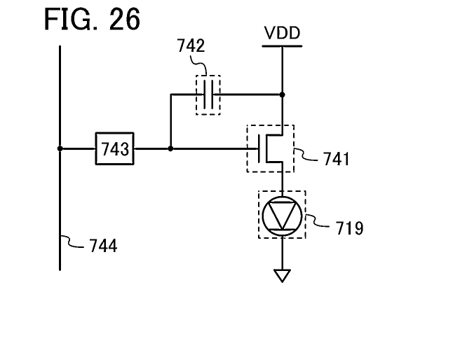

FIG. 26 illustrates an example of a circuit diagram of a pixel in a display device using an EL element.

The display device in FIG. 26 includes a switching element 743, a transistor 741, a capacitor 742, and a light-emitting element 719.

A gate of the transistor 741 is electrically connected to one terminal of the switching element 743 and one terminal of the capacitor 742. A source of the transistor 741 is electrically connected to one terminal of the light-emitting element 719. A drain of the transistor 741 is electrically connected to the other terminal of the capacitor 742 and is supplied with a power supply potential VDD. The other terminal of the switching element 743 is electrically connected to a signal line 744. The other terminal of the light-emitting element 719 is supplied with a fixed potential. Note that the fixed potential is a ground potential GND or lower.

As the transistor 741, any of the transistors including an oxide semiconductor film described in the above embodiment is used. The transistor has stable electrical characteristics. Accordingly, a display device having high display quality can be formed.

As the switching element 743, it is preferred to use a transistor. With a transistor, the area of a pixel can be reduced, so that a display device having a high resolution can be obtained. Moreover, as the switching element 743, any of the transistors including an oxide semiconductor film described in the above embodiment may be used. With use of the transistor as the switching element 743, the switching element 743 can be formed in the same process as the transistor 741; thus, the productivity of the display device can be improved.

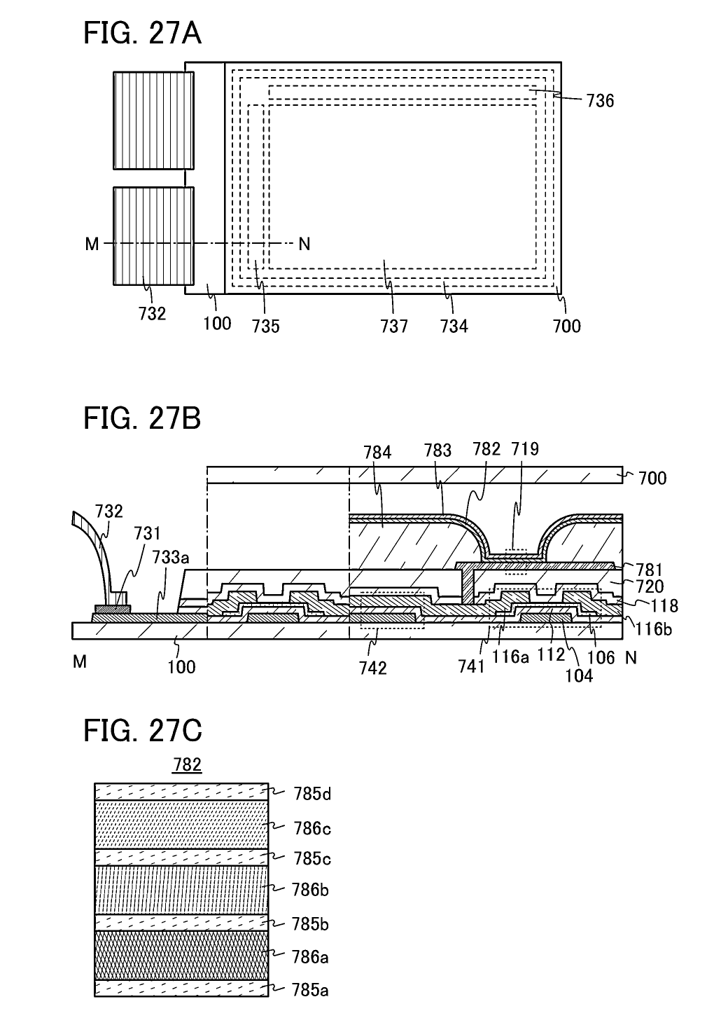

FIG. 27A is a top view of a display device using an EL element. The display device using an EL element includes a substrate 100, a substrate 700, a sealant 734, a driver circuit 735, a driver circuit 736, a pixel 737, and an FPC 732. The sealant 734 is provided between the substrate 100 and the substrate 700 so as to surround the pixel 737, the driver circuit 735 and the driver circuit 736. Note that the driver circuit 735 and/or the driver circuit 736 may be provided outside the sealant 734.

FIG. 27B is a cross-sectional view of the display device using an EL element taken along dashed-dotted line M-N in FIG. 27A. The FPC 732 is connected to a wiring 733a via a terminal 731. Note that the wiring 733a is formed in the same layer as the gate electrode 104.

Note that FIG. 27B shows an example where the transistor 741 and the capacitor 742 are provided in the same plane. With such a structure, the capacitor 742 can be formed in the same plane as that of a gate electrode, a gate insulating film, and a source electrode (drain electrode), which are included in the transistor 741. When the transistor 741 and the capacitor 742 are provided in the same plane in this manner, the number of manufacturing steps of the display device can be reduced; thus, the productivity can be increased.

In the example of FIG. 27B, the transistor illustrated in FIGS. 13A to 13C is used as the transistor 741. Therefore, for components of the transistor 741, which are not particularly mentioned below, the description in the above embodiments is referred to.

An insulating film 720 is provided over the transistor 741 and the capacitor 742.

Here, an opening reaching the source electrode 116a of the transistor 741 is provided in the insulating film 720 and the protective insulating film 118.

An electrode 781 is provided over the insulating film 720. The electrode 781 is connected to the source electrode 116a of the transistor 741 through the opening provided in the insulating film 720 and the protective insulating film 118.

A partition 784 having an opening reaching the electrode 781 is provided over the electrode 781.

A light-emitting layer 782 in contact with the electrode 781 through the opening provided in the partition 784 is provided over the partition 784.

An electrode 783 is provided over the light-emitting layer 782.

A region where the electrode 781, the light-emitting layer 782, and the electrode 783 overlap with one another serves as the light-emitting element 719.

Note that description of the protective insulating film 118 is referred to for the insulating film 720. Alternatively, a resin film of a polyimide resin, an acrylic resin, an epoxy resin, a silicone resin, or the like may be used.

The light-emitting layer 782 is not limited to a single layer, and may be a stack of plural kinds of light-emitting layers and the like. For example, a structure illustrated in FIG. 27C may be employed. FIG. 27C illustrates a structure in which an intermediate layer 785a, a light-emitting layer 786a, an intermediate layer 785b, a light-emitting layer 786b, an intermediate layer 785c, a light-emitting layer 786c, and an intermediate layer 785d are stacked in this order. In that case, when light-emitting layers emitting light of appropriate colors are used as the light-emitting layer 786a, the light-emitting layer 786b, and the light-emitting layer 786c, the light-emitting element 719 with a high color rendering property or higher emission efficiency can be formed.

White light may be obtained by stacking plural kinds of light-emitting layers. Although not illustrated in FIG. 27B, white light may be extracted through coloring layers.

Although the structure in which three light-emitting layers and four intermediate layers are provided is shown here, the structure is not limited thereto. The number of light-emitting layers and the number of intermediate layers can be changed as appropriate. For example, the light-emitting layer 782 can be formed with only the intermediate layer 785a, the light-emitting layer 786a, the intermediate layer 785b, the light-emitting layer 786b, and the intermediate layer 785c. Alternatively, the light-emitting layer 782 may be formed with the intermediate layer 785a, the light-emitting layer 786a, the intermediate layer 785b, the light-emitting layer 786b, the light-emitting layer 786c, and the intermediate layer 785d; the intermediate layer 785c may be omitted.

In addition, the intermediate layer can be formed using a stacked-layer structure of a hole-injection layer, a hole-transport layer, an electron-transport layer, an electron-injection layer, or the like. Note that not all of these layers need to be provided as the intermediate layer. Any of these layers may be selected as appropriate to form the intermediate layer. Note that a plurality of layers having similar functions may be provided. Further, an electron-relay layer or the like may be added as appropriate as the intermediate layer, in addition to a carrier generation layer.

The electrode 781 can be formed using a conductive film having a transmitting property with respect to visible light. The phrase “having a transmitting property with respect to visible light” means that the average transmittance of light in a visible light region (for example, a wavelength range from 400 nm to 800 nm) is higher than or equal to 70%, particularly higher than or equal to 80%.

As the electrode 781, for example, an oxide film such as an In—Zn—W oxide film, an In—Sn oxide film, an In—Zn oxide film, an In oxide film, a Zn oxide film, or a Sn oxide film can be used. The above oxide film may contain a minute amount of Al, Ga, Sb, F, or the like. Further, a metal thin film having a thickness which enables light to be transmitted (preferably, approximately 5 nm to 30 nm) can also be used. For example, an Ag film, an Mg film, or an Ag—Mg alloy film with a thickness of 5 nm may be used.

The electrode 781 is preferred to be a film which efficiently reflects visible light. For example, a film containing lithium, aluminum, titanium, magnesium, lanthanum, silver, silicon, or nickel can be used as the electrode 781.

The electrode 783 can be formed using any of the films for the electrode 781. Note that when the electrode 781 has a transmitting property with respect to visible light, it is preferred that the electrode 783 efficiently reflects visible light. When the electrode 781 efficiently reflects visible light, it is preferred that the electrode 783 has a transmitting property with respect to visible light.

Positions of the electrode 781 and the electrode 783 are not limited to the structure illustrated in FIG. 27B, and the electrode 781 and the electrode 783 may be replaced with each other. It is preferred to use a conductive film having a high work function for the electrode which serves as an anode and a conductive film having a low work function for the electrode which serves as a cathode. Note that in the case where a carrier generation layer is provided in contact with the anode, a variety of conductive films can be used for the anode regardless of their work functions.

Note that description of the protective insulating film 118 is referred to for the partition 784. Alternatively, a resin film of a polyimide resin, an acrylic resin, an epoxy resin, a silicone resin, or the like may be used.

The transistor 741 connected to the light-emitting element 719 has stable electrical characteristics. Therefore, a display device having high display quality can be provided.

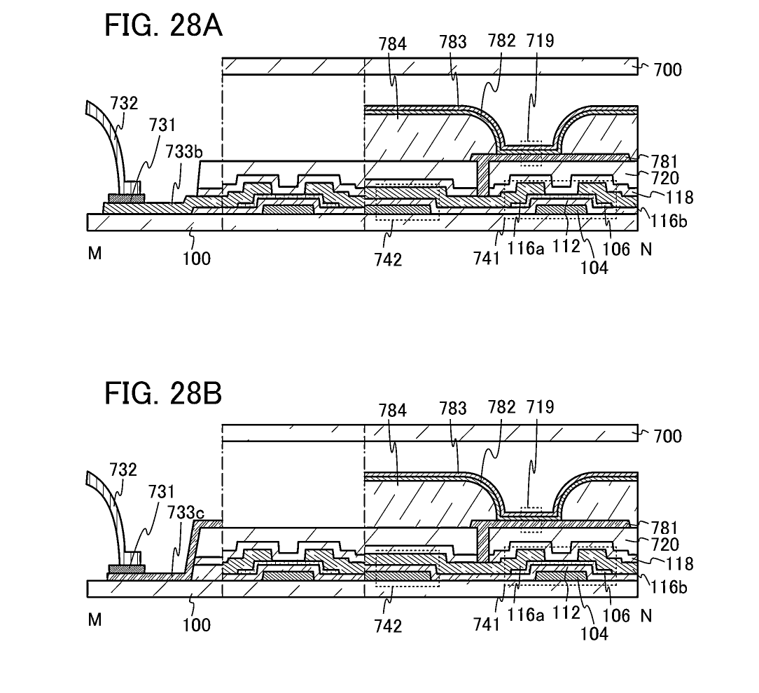

FIGS. 28A and 28B each illustrate an example of a cross section of a display device using an EL element, which is partly different from that in FIG. 27B. Specifically, there is a difference in a wiring connected to the FPC 732. In FIG. 28A, a wiring 733b is connected to the FPC 732 via the terminal 731. The wiring 733b is formed in the same layer as the source electrode 116a and the drain electrode 116b. In FIG. 28B, a wiring 733c is connected to the FPC 732 via the terminal 731. The wiring 733c is formed in the same layer as the electrode 781.

Next, the display device including a liquid crystal element is described.

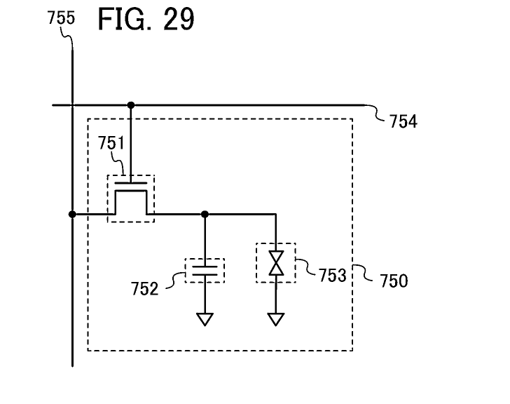

FIG. 29 is a circuit diagram illustrating a structure example of a pixel of a display device using a liquid crystal element. A pixel 750 illustrated in FIG. 29 includes a transistor 751, a capacitor 752, and an element in which liquid crystal is injected between a pair of electrodes (hereinafter also referred to as a liquid crystal element) 753.

One of a source and a drain of the transistor 751 is electrically connected to a signal line 755, and a gate of the transistor 751 is electrically connected to a scan line 754.

One of electrodes of the capacitor 752 is electrically connected to the other of the source and the drain of the transistor 751, and the other of the electrodes of the capacitor 752 is electrically connected to a wiring for supplying a common potential.

One of electrodes of the liquid crystal element 753 is electrically connected to the other of the source and the drain of the transistor 751, and the other of the electrodes of the liquid crystal element 753 is electrically connected to a wiring for supplying a common potential. Note that the common potential supplied to the other of the electrodes of the liquid crystal element 753 may be different from the common potential supplied to the wiring electrically connected to the other of the electrodes of the capacitor 752.

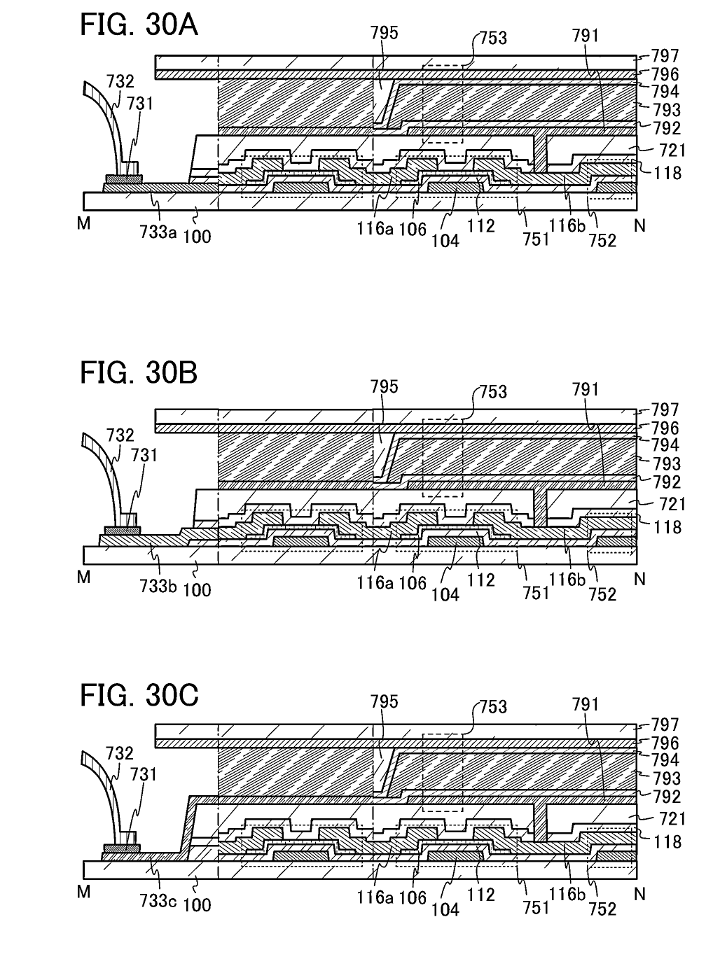

Note that a top view of the display device using a liquid crystal element is substantially same as that of the display device using an EL element. FIG. 30A is a cross-sectional view of the display device using a liquid crystal element taken along dashed-dotted line M-N in FIG. 27A. In FIG. 30A, the FPC 732 is connected to the wiring 733a via the terminal 731. Note that the wiring 733a is formed in the same layer as the gate electrode 104.

Note that FIG. 30A illustrates an example where the transistor 751 and the capacitor 752 are provided in the same plane. With such a structure, the capacitor 752 can be formed in the same plane as a gate electrode, a gate insulating film, and a source electrode (drain electrode), which are included in the transistor 751. When the transistor 751 and the capacitor 752 are provided in the same plane in this manner, the number of manufacturing steps of the display device can be reduced; thus, the productivity can be increased.

Note that, as the transistor 751, any of the transistors described in the above embodiments can be used. In the example of FIG. 30A, the transistor illustrated in FIGS. 13A to 13C is used. Therefore, for components of the transistor 751, which are not particularly mentioned below, the description in the above embodiments is referred to.

Note that the transistor 751 can be a transistor having extremely low off-state current. Thus, the charge held in the capacitor 752 is unlikely to be leaked and a voltage applied to the liquid crystal element 753 can be retained for a long time. Accordingly, when a motion image with less movement or a still image is displayed, a power for operating the transistor 751 is not needed by turning off the transistor 751, whereby a display device with low power consumption can be obtained.

An insulating film 721 is provided over the transistor 751 and the capacitor 752.

Here, an opening reaching the drain electrode 116b of the transistor 751 is provided in the insulating film 721 and the protective insulating film 118.

An electrode 791 is provided over the insulating film 721. The electrode 791 is in contact with the drain electrode 116b of the transistor 751 through the opening provided in the insulating film 721 and the protective insulating film 118.

An insulating film 792 serving as an alignment film is provided over the electrode 791.

A liquid crystal layer 793 is provided over the insulating film 792.

An insulating film 794 serving as an alignment film is provided over the liquid crystal layer 793.

A spacer 795 is provided over the insulating film 794.

An electrode 796 is provided over the spacer 795 and the insulating film 794.

A substrate 797 is provided over the electrode 796.

Note that description of the protective insulating film 118 is referred to for the insulating film 721. Alternatively, a resin film of a polyimide resin, an acrylic resin, an epoxy resin, a silicone resin, or the like may be used.

For the liquid crystal layer 793, a thermotropic liquid crystal, a low-molecular liquid crystal, a polymer liquid crystal, a polymer-dispersed liquid crystal, a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

Note that as the liquid crystal layer 793, a liquid crystal exhibiting a blue phase may be used. In that case, the insulating films 792 and 794 serving as an alignment film are not necessarily provided.

The electrode 791 can be formed using a conductive film having a transmitting property with respect to visible light.

As the electrode 791, for example, an oxide film such as an In—Zn—W oxide film, an In—Sn oxide film, an In—Zn oxide film, an In oxide film, a Zn oxide film, or a Sn oxide film can be used. The above oxide film may contain a minute amount of Al, Ga, Sb, F, or the like. Further, a metal thin film having a thickness which enables light to be transmitted (preferably, approximately 5 nm to 30 nm) can also be used.

Alternatively, the electrode 791 is preferred to be a film which efficiently reflects visible light. For example, a film containing aluminum, titanium, chromium, copper, molybdenum, silver, tantalum, or tungsten can be used as the electrode 791.

The electrode 796 can be formed using any of the films for the electrode 791. Note that when the electrode 791 has a transmitting property with respect to visible light, it is preferable that the electrode 796 efficiently reflect visible light. When the electrode 791 efficiently reflects visible light, it is in some cases preferred that the electrode 796 has a transmitting property with respect to visible light.

Positions of the electrode 791 and the electrode 796 are not limited to the structure illustrated in FIG. 30A, and the electrode 791 and the electrode 796 may be replaced with each other.

Each of the insulating films 792 and 794 may be formed using an organic compound or an inorganic compound.

The spacer 795 may be formed using an organic compound or an inorganic compound. Note that the spacer 795 can have a variety of shapes such as a columnar shape and a spherical shape.

A region where the electrode 791, the insulating film 792, the liquid crystal layer 793, the insulating film 794, and the electrode 796 overlap with one another serves as the liquid crystal element 753.

For the substrate 797, a glass substrate, a resin substrate, a metal substrate, or the like can be used. The substrate 797 may have flexibility.

FIGS. 30B and 30C each illustrate an example of a cross section of a display device using a liquid crystal element, which is partly different from that in FIG. 30A. Specifically, there is a difference in a wiring connected to the FPC 732. In FIG. 30B, the wiring 733b is connected to the FPC 732 via the terminal 731. The wiring 733b is formed in the same layer as the source electrode 116a and the drain electrode 116b. In FIG. 30C, the wiring 733c is connected to the FPC 732 via the terminal 731. The wiring 733c is formed in the same layer as the electrode 791.

The transistor 751 connected to the liquid crystal element 753 has stable electrical characteristics. Therefore, a display device having high display quality can be provided. Since the transistor 751 can have extremely low off-state current, a display device with low power consumption can be provided.

This embodiment can be implemented in appropriate combination with any of the other embodiments and example.

### Embodiment 10

In this embodiment, examples of electronic devices including any of the semiconductor devices described in the above embodiment will be described.

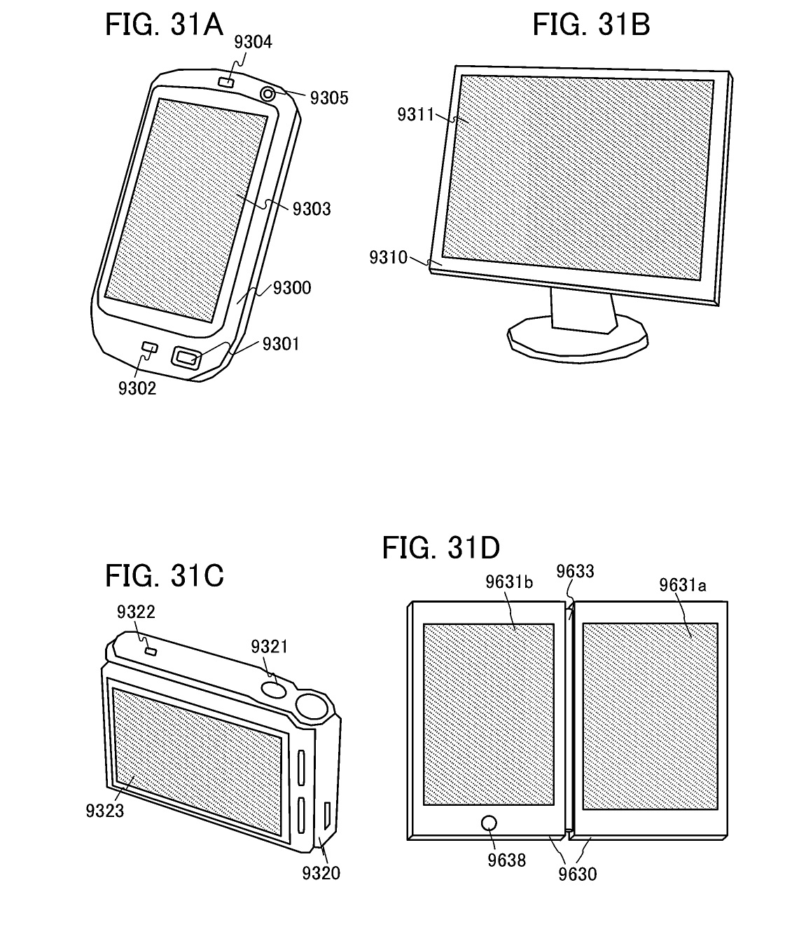

FIG. 31A illustrates a portable information terminal. The portable information terminal illustrated in FIG. 31A includes a housing 9300, a button 9301, a microphone 9302, a display portion 9303, a speaker 9304, and a camera 9305, and has a function as a mobile phone. One embodiment of the present invention can be applied to an arithmetic unit, a wireless circuit, or a memory circuit in a main body. Alternatively, one embodiment of the present invention can be applied to the display portion 9303.

FIG. 31B illustrates a display. The display illustrated in FIG. 31B includes a housing 9310 and a display portion 9311. One embodiment of the present invention can be applied to an arithmetic unit, a wireless circuit, or a memory circuit in a main body. Alternatively, one embodiment of the present invention can be applied to the display portion 9311.

FIG. 31C illustrates a digital still camera. The digital still camera illustrated in FIG. 31C includes a housing 9320, a button 9321, a microphone 9322, and a display portion 9323. One embodiment of the present invention can be applied to an arithmetic unit, a wireless circuit, or a memory circuit in a main body. Alternatively, one embodiment of the present invention can be applied to the display portion 9323.

FIG. 31D illustrates a double-foldable portable information terminal. The double-foldable portable information terminal illustrated in FIG. 31D includes a housing 9630, a display portion 9631a, a display portion 9631b, a hinge 9633, and an operation switch 9638. One embodiment of the present invention can be applied to an arithmetic unit, a wireless circuit, or a memory circuit in a main body. Alternatively, one embodiment of the present invention can be applied to the display portion 9631a and the display portion 9631b.

Part or whole of the display portion 9631a and/or the display portion 9631b can function as a touch panel. By touching an operation key displayed on the touch panel, a user can input data, for example.

With use of a semiconductor device according to one embodiment of the present invention, an electronic device with high performance and low power consumption can be provided.

This embodiment can be implemented in appropriate combination with any of the other embodiments and example.

### Example 1

In this example, results of examination which was conducted on crystal states of a sputtering target including a polycrystalline oxide and an oxide film will be described.

The sputtering targets were formed by the method described in Embodiment 1. In this example, a sample in which the mixture ratio of a In₂O₃ powder to a Ga₂O₃ powder and a ZnO powder is 1:1:1 [molar ratio] is Sample 1, a sample in which the mixture ratio thereof is 1:1:2 [molar ratio] is Sample 2, and a sample in which the mixture ratio thereof is 3:1:4 [molar ratio] is Sample 3.

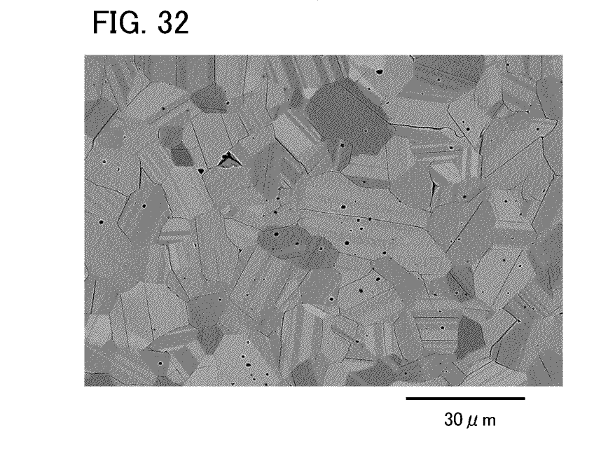

First, examination with EBSD was performed. FIG. 32 shows a backscattered electron image of Sample 1. As seen in FIG. 32, Sample 1 is a polycrystal and has grain boundaries.

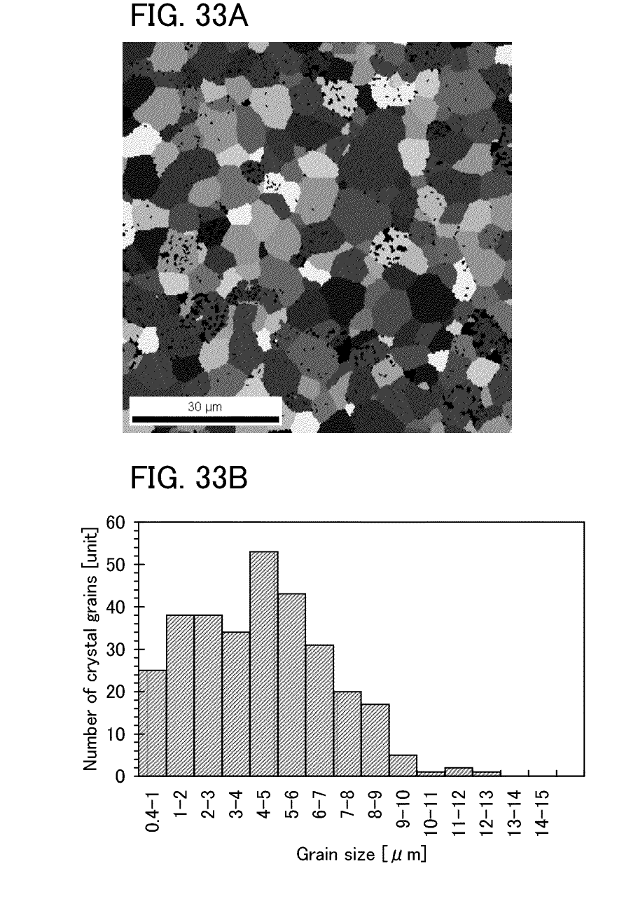

FIG. 33A shows a crystal grain map of Sample 1, and FIG. 33B shows a histogram of grain sizes thereof. A square region of 80 μm×80 μm was measured, and the step was 0.3 μm. Under the above conditions, crystal grains whose sizes are approximately less than 0.4 μm cannot be counted as crystal grains. Thus, a crystal grain which is measured to be less than or equal to 1 μm is practically a crystal grain whose size is greater than or equal to 0.4 μm and less than or equal to 1 μm.

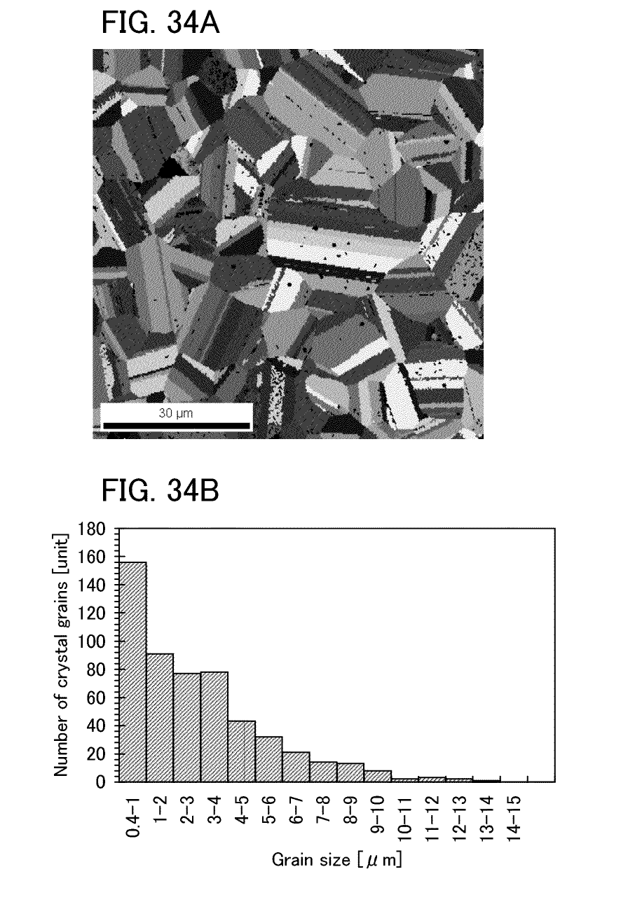

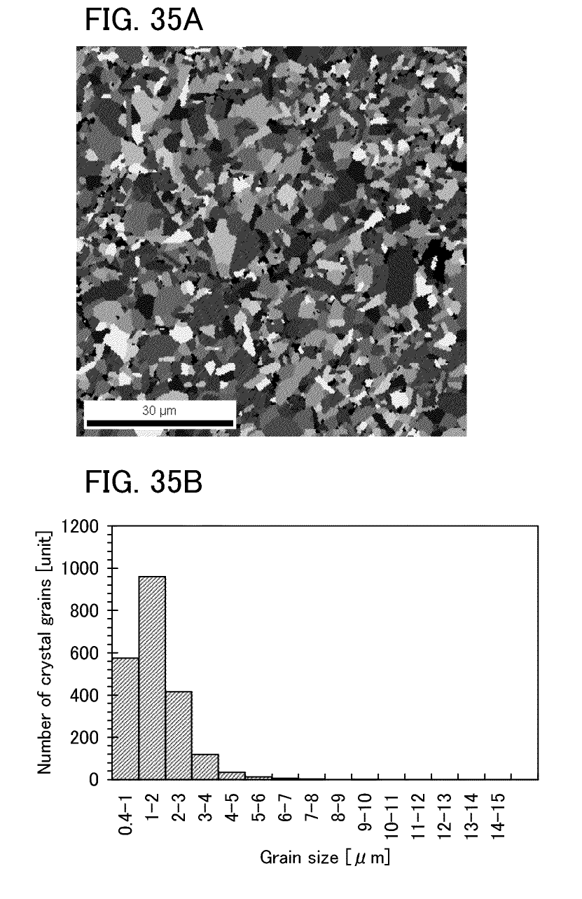

Similarly, FIG. 34A shows a crystal grain map of Sample 2, and FIG. 34B shows a histogram of grain sizes thereof. Further, FIG. 35A shows a crystal grain map of Sample 3, and FIG. 35B shows a histogram of grain sizes thereof.

Table 1 shows the grain sizes of crystal grains of Sample 1 to Sample 3 obtained by EBSD and the number thereof.

TABLE 1

| Grain Size | Number of Crystal Grains | | |
|---|---|---|---|
| [μm] | Sample 1 | Sample 2 | Sample 3 |
| 0.4-1 | 25 | 156 | 574 |
| 1-2 | 38 | 91 | 960 |
| 2-3 | 38 | 77 | 415 |
| 3-4 | 34 | 78 | 118 |
| 4-5 | 53 | 43 | 34 |
| 5-6 | 43 | 32 | 12 |
| 6-7 | 31 | 21 | 6 |
| 7-8 | 20 | 14 | 3 |
| 8-9 | 17 | 13 | 0 |
| 9-10 | 5 | 8 | 1 |
| 10-11 | 1 | 2 | 0 |
| 11-12 | 2 | 3 | 0 |
| 12-13 | 1 | 2 | 0 |
| 13-14 | 0 | 1 | 0 |
| 14-15 | 0 | 0 | 0 |
| 16 or more | 0 | 0 | 0 |

Note that the average grain size of Sample 1 was 4.38 μm, that of Sample 2 was 2.93 μm, and that of Sample 3 was 1.66 μm. Further, the proportions of crystal grains which were greater than or equal to 0.4 μm and less than or equal to 1 μm in each sample was 8.1% (Sample 1), 28.8% (Sample 2), and 27.0% (Sample 3).

Next, oxide films were formed with use of Sample 1 and Sample 2 as sputtering targets.

Each of the oxide films was formed to a thickness of 300 nm over a glass substrate. For each film formation, a DC magnetron sputtering method was employed. The other film formation conditions were as follows: the substrate heating temperature was 300° C.; the DC power was 0.5 kW; the flow rate of an argon gas and an oxygen gas were 30 sccm and 15 sccm, respectively; and the pressure was 0.4 Pa.

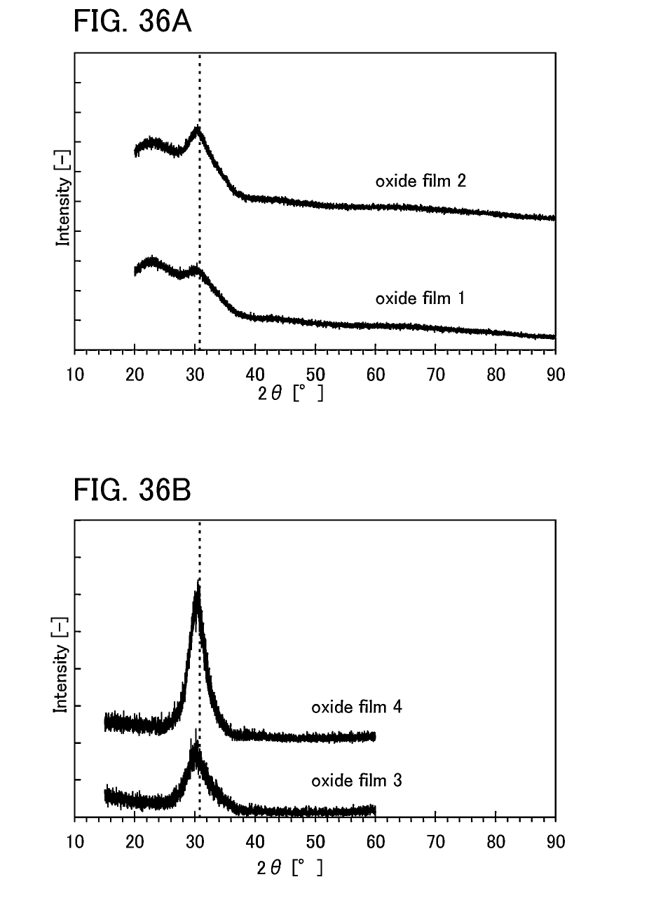

Next, crystal states of the oxide films formed using Sample 1 and Sample 2 (the oxide films are referred to as an oxide film 1 and an oxide film 2) were examined with an X-ray diffraction (XRD) apparatus. The measurement was conducted by an out-of-plane method (2θ/ω scan). FIG. 36A shows the measurement result.

According to FIG. 36A, there is a peak around 30.8° in each of the oxide film 1 and the oxide film 2. Note that between 20° to 25°, peaks attributed to the glass substrate appear. The peak around 30.8° indicates diffraction of a (009) plane of InGaZnO₄, for example. In other words, it is found that the oxide films formed with use of Sample 1 and Sample 2 have a high proportion of crystals with surface structures of planes parallel to an a-b plane.

In addition, with use of Sample 2 and Sample 3 as sputtering targets, oxide films were formed to a thickness of 100 nm over a silicon wafer. For each film formation, a DC magnetron sputtering method was employed. The other film formation conditions were as follows: the substrate heating temperature was 300° C.; the DC power was 0.5 kW; the flow rate of an argon gas and an oxygen gas were 30 sccm and 15 sccm, respectively; and the pressure was 0.4 Pa.

Next, crystal states of the oxide films formed using Sample 2 and Sample 3 (the oxide films are referred to as an oxide film 3 and an oxide film 4) were examined with an XRD apparatus. The measurement was conducted by an out-of-plane method (2θ/ω scan). FIG. 36B shows the measurement result.

According to FIG. 36B, there is a peak around 30.8° in each of the oxide film 3 and the oxide film 4. The peak around 30.8° indicates diffraction of a (009) plane of InGaZnO₄, for example. In other words, it is found that the oxide films formed with use of Sample 2 and Sample 3 have a high proportion of crystals with surface structures of planes parallel to an a-b plane.

Next, silicon oxide films were formed to a thickness of 100 nm over a silicon wafer by a thermal oxidation method, and then, oxide films were formed to a thickness of 100 nm with use of Sample 2 and Sample 3 as sputtering targets. For each film formation, a DC magnetron sputtering method was employed. The other film formation conditions were as follows: the substrate heating temperature was 400° C.; the DC power was 0.5 kW; the flow rate of an argon gas and an oxygen gas were 30 sccm and 15 sccm, respectively; and the pressure was 0.4 Pa.

Next, cross sections of atomic arrangement in the oxide films formed with use of Sample 2 and Sample 3 (the oxide films are referred to as an oxide film 5 and an oxide film 6) were observed. For observation of atomic arrangement, a high-angle annular dark field scanning transmission electron microscopy (HAADF-STEM) was used. A Hitachi scanning transmission electron microscope HD-2700 was used as HAADF-STEM, and the acceleration voltage was set to 200 kV.

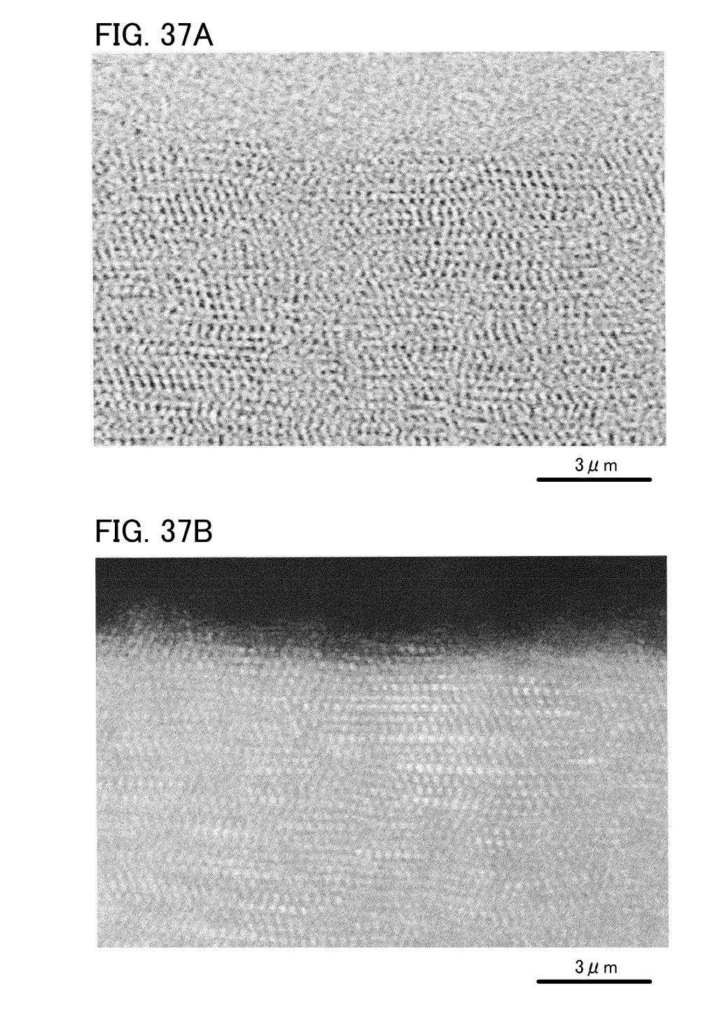

FIG. 37A is a bright-filed image of the oxide film 5, which was obtained with a scanning transmission electron microscope (STEM). FIG. 37B is an HAADF-STEM image of the same portion as that in FIG. 37A. Note that observation shown in FIGS. 37A and 37B includes a top surface of the oxide film 5.

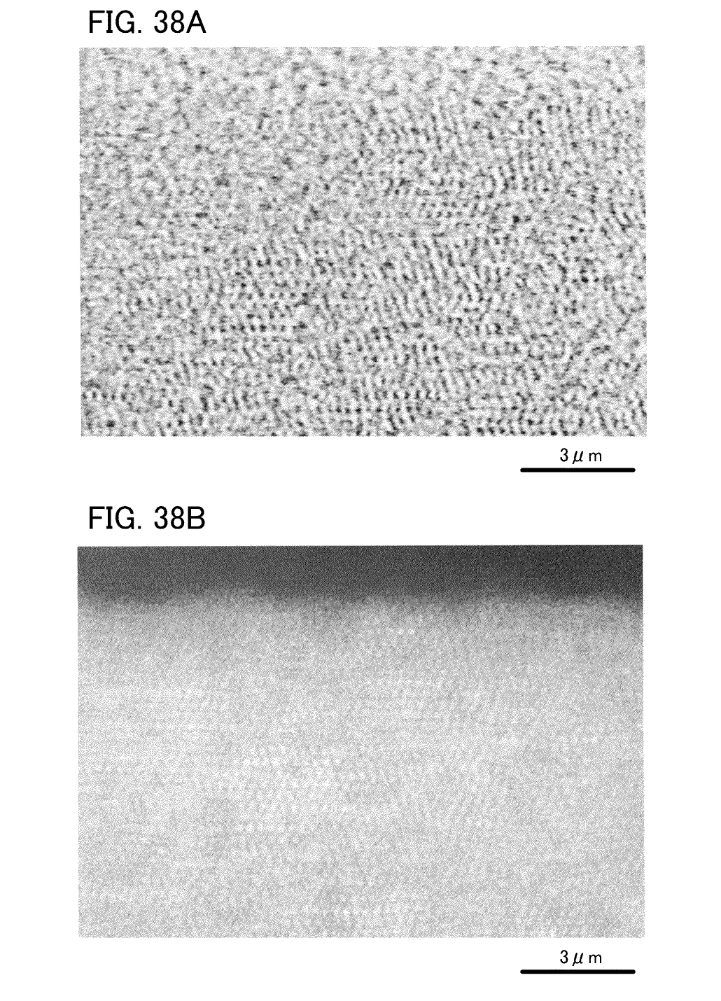

FIG. 38A is a bright-filed image of the oxide film 6, which was obtained with an STEM. FIG. 38B is a HAADF-STEM image of the same portion as that in FIG. 38A. Note that observation shown in FIGS. 38A and 38B includes a top surface of the oxide film 6.

According to FIG. 37B and FIG. 38B, in each of the oxide film 5 and the oxide film 6, metal atoms are arranged in parallel to the top surface, and the oxide film 5 and the oxide film 6 have c-axis alignment.

According to this example, when the average grain size of the crystal grains contained in a sputtering target is small, an oxide film formed with use of the sputtering target has a high degree of crystallinity.

### EXPLANATION OF REFERENCE

100: substrate, 102: base insulating film, 104: gate electrode, 106: oxide semiconductor film, 112: gate insulating film, 114: back gate electrode, 116a: source electrode, 116b: drain electrode, 118: protective insulating film, 200: substrate, 202: base insulating film, 204: gate electrode, 206: oxide semiconductor film, 212: gate insulating film, 216a: source electrode, 216b: drain electrode, 218: protective insulating film, 300: substrate, 302: base insulating film, 304: gate electrode, 306: oxide semiconductor film, 312: gate insulating film, 316a: source electrode, 316b: drain electrode, 400: substrate, 402: base insulating film, 404: gate electrode, 406: oxide semiconductor film, 412: gate insulating film, 416a: source electrode, 416b: drain electrode, 420: insulating film, 500: substrate, 502: base insulating film, 504: gate electrode, 506: oxide semiconductor film, 512: gate insulating film, 518: interlayer insulating film, 520: insulating film, 522: insulating film, 524a: wiring, 524b: wiring, 526: electrode, 528: electrode, 551: transistor, 552: capacitor, 553: bit line, 554: word line, 555: capacitor line, 556: memory cell, 558: sense amplifier, 602: base insulating film, 620: insulating film, 622: insulating film, 626: electrode, 628: electrode, 650: semiconductor substrate, 654: gate electrode, 656: channel region, 657: impurity region, 657a: source region, 657b: drain region, 662: gate insulating film, 664: element isolation layer, 668: insulating film, 671: transistor, 672: transistor, 673: capacitor, 674: source line, 675: source line, 676: word line, 677: drain line, 678: capacitor line, 679: node, 700: substrate, 719: light-emitting element, 720: insulating film, 721: insulating film, 731: terminal, 732: FPC, 733a: wiring, 733b: wiring, 733c: wiring, 734: sealant, 735: driver circuit, 736: driver circuit, 737: pixel, 741: transistor, 742: capacitor, 743: switching element, 744: signal line, 750: pixel, 751: transistor, 752: capacitor, 753: liquid crystal element, 754: scan line, 755: signal line, 781: electrode, 782: light-emitting layer, 783: electrode, 784: partition, 785a: intermediate layer, 785b: intermediate layer, 785c: intermediate layer, 785d: intermediate layer, 786a: light-emitting layer, 786b: light-emitting layer, 786c: light-emitting layer, 791: electrode, 792: insulating film, 793: liquid crystal layer, 794: insulating film, 795: spacer, 796: electrode, 797: substrate, 802: insulating film, 806: oxide semiconductor film, 812: gate insulating film, 814: gate electrode, 816a: source electrode, 816b: drain electrode, 902: insulating film, 906: oxide semiconductor film, 912: gate insulating film, 914: gate electrode, 916a: source electrode, 916b: drain electrode, 1000: sputtering target, 1001: ion, 1002: sputtered particle, 1003: deposition surface, 1141: switching element, 1142: memory element, 1143: memory element group, 1189: ROM interface, 1190: substrate, 1191: ALU, 1192: ALU controller, 1193: instruction decoder, 1194: interrupt controller, 1195: timing controller, 1196: register, 1197: register controller, 1198: bus interface, 1199: ROM, 4000: film formation apparatus, 4001: atmosphere-side substrate supply chamber, 4002: atmosphere-side substrate transfer chamber, 4003a: load lock chamber, 4003b: unload lock chamber, 4004: transfer chamber, 4005: substrate heating chamber, 4006a: film formation chamber, 4006b: film formation chamber, 4006c: film formation chamber, 4101: cassette port, 4102: alignment port, 4103: transfer robot, 4104: gate valve, 4105: heating stage, 4106: target, 4107: attachment protection plate, 4108: substrate stage, 4109: substrate, 4110: cryotrap, 4111: stage, 4200: vacuum pump, 4201: cryopump, 4202: turbo molecular pump, 4300: mass flow controller, 4301: refiner, 4302: gas heating system, 9300: housing, 9301: button, 9302: microphone, 9303: display portion, 9304: speaker, 9305: camera, 9310: housing, 9311: display portion, 9320: housing, 9321: button, 9322: microphone, 9323: display portion, 9630: housing, 9631a: display portion, 9631b: display portion, 9633: hinge, 9638: operation switch, 5101: step, 5102: step, S103: step, S104: step, S111: step, S112: step, S113: step, S114: step

This application is based on Japanese Patent Application serial no. 2012-141451 filed with Japan Patent Office on Jun. 22, 2012, the entire contents of which are hereby incorporated by reference.

1. A sputtering target comprising:
a polycrystalline oxide comprising a plurality of crystal grains,
wherein an average grain size of the plurality of crystal grains is 3 μm or less.

2. The sputtering target according to claim 1,
wherein a proportion of crystal grains having a grain size of 0.4 μm to 1 μm is 8% or higher in the plurality of crystal grains.

3. The sputtering target according to claim 1,
wherein the plurality of crystal grains are hexagonal crystals.

4. The sputtering target according to claim 1,
wherein the polycrystalline oxide comprises indium and zinc.

5. The sputtering target according to claim 4,
wherein the polycrystalline oxide further comprises at least one element selected from Ga, Sn, Hf, Al, La, Ce, Pr, Nd, Sm, Eu, Gd, Tb, Dy, Ho, Er, Tm, Yb, and Lu.

6. The sputtering target according to claim 1,
wherein the plurality of crystal grains include a cleavage plane.

7. A method for using a sputtering target comprising the steps of:
forming sputtered particles by cleaving the sputtering target comprising a polycrystalline oxide; and
depositing the sputtered particles over a substrate,
wherein the polycrystalline oxide comprises a plurality of crystal grains, and
wherein an average grain size of the plurality of crystal grains is 3 μm or less.

8. The method for using a sputtering target according to claim 7,
wherein a proportion of crystal grains having a grain size of 0.4 μm to 1 μm is 8% or higher in the plurality of crystal grains.

9. The method for using a sputtering target according to claim 8,
wherein the grain size is measured by electron backscatter diffraction.

10. The method for using a sputtering target according to claim 7,
wherein the sputtered particles have a hexagonal cylinder shape.

11. The method for using a sputtering target according to claim 7,
wherein the polycrystalline oxide comprises indium and zinc.

12. The method for using a sputtering target according to claim 11,
wherein the polycrystalline oxide further comprises at least one element selected from Ga, Sn, Hf, Al, La, Ce, Pr, Nd, Sm, Eu, Gd, Tb, Dy, Ho, Er, Tm, Yb, and Lu.

13. A method for manufacturing an oxide film comprising the steps of:
cleaving a sputtering target comprising a polycrystalline oxide by an ion collision with a target surface, thereby separating sputtered particles; and
depositing the sputtered particles on the oxide film,
wherein the polycrystalline oxide comprises a plurality of crystal grains, and
wherein an average grain size of the plurality of crystal grains is 3 μm or less.

14. The method for manufacturing an oxide film according to claim 13,
wherein the oxide film is a CAAC-OS film.

15. The method for manufacturing an oxide film according to claim 13,
wherein a proportion of crystal grains having a grain size of 0.4 μm to 1 μm is 8% or higher in the plurality of crystal grains.

16. The method for manufacturing an oxide film according to claim 13,
wherein the sputtered particles have a hexagonal cylinder shape.

17. The method for manufacturing an oxide film according to claim 13,
wherein the polycrystalline oxide comprises indium and zinc.

18. The method for manufacturing an oxide film according to claim 17,
wherein the polycrystalline oxide further comprises at least one element selected from Ga, Sn, Hf, Al, La, Ce, Pr, Nd, Sm, Eu, Gd, Tb, Dy, Ho, Er, Tm, Yb, and Lu.
